(19) United States
(12) Patent Application Publication
(10) Pub. No.: US 2025/0169180 A1
(43) Pub. Date: May 22, 2025

(54) SEMICONDUCTOR DEVICE AND METHOD FOR FABRICATING SEMICONDUCTOR DEVICE

(71) Applicant: Semiconductor Energy Laboratory Co., Ltd., Atsugi-shi, Kanagawa-ken (JP)

(72) Inventors: Yasuharu HOSAKA, Tochigi (JP); Masami JINTYOU, Shimotsuga (JP); Takahiro IGUCHI, Nikko (JP); Chieko MISAWA, Utsunomiya (JP); Ami SATO, Tochigi (JP); Masayoshi DOBASHI, Shimotsuga (JP)

(21) Appl. No.: 18/839,759

(22) PCT Filed: Mar. 6, 2023
(86) PCT No.: PCT/IB2023/052054

§ 371 Date: Aug. 20, 2024

(30) Foreign Application Priority Data
Mar. 18, 2022 (JP) 2022-044034

(51) Int. Cl. H10D 86/40; H10D 30/67; H10D 86/01; H10D 86/60

(52) U.S. Cl. CPC H10D 86/471; H10D 30/6728; H10D 86/0221; H10D 86/0251; H10D 86/423; H10D 86/451; H10D 86/60

(57) ABSTRACT

A semiconductor device having a high degree of integration is provided. The semiconductor device includes a first and a second transistor, and an insulating layer. The first transistor includes a source electrode, a drain electrode over the insulating layer over the source electrode, a first semiconductor layer in contact with a top surface of the source electrode, an inner wall of an opening provided in the insulating layer, and a top surface of the drain electrode, a first gate insulating layer in contact with a top surface and a side surface of the first semiconductor layer, and a first gate electrode over the first gate insulating layer that includes a region overlapping with the inner wall of the opening. The second transistor includes a second semiconductor layer over the insulating layer, the source electrode in contact with one of a top surface and a side surface of the second semiconductor layer, the drain electrode in contact with the other of the top surface and the side surface of the second semiconductor layer, a second gate insulating layer in contact with the top surface of the second semiconductor layer, a top surface and a side surface of the source electrode, and a top surface and a side surface of the drain electrode, and a second gate electrode over the second gate insulating layer. The first semiconductor layer is in contact with the second gate electrode.

### TECHNICAL FIELD

One embodiment of the present invention relates to a semiconductor device, a display apparatus, a display module, and an electronic device. One embodiment of the present invention relates to a method for fabricating a semiconductor device and a method for fabricating a display apparatus.

Note that one embodiment of the present invention is not limited to the above technical field. Examples of the technical field of one embodiment of the present invention include a semiconductor device, a display apparatus, a light-emitting apparatus, a power storage device, a memory device, an electronic device, a lighting device, an input device (e.g., a touch sensor), and an input/output device (e.g., a touch panel), an electronic device including any of them, a driving method of any of them, and a manufacturing method of any of them.

### BACKGROUND ART

Semiconductor devices including transistors have been widely used in display apparatuses and electronic devices, and required to achieve increasingly high integration and high-speed operation. Highly integrated semiconductor devices are required for application to high-resolution display apparatuses, for example. One way of increasing the degree of integration of transistors is the recent development of miniaturized transistors.

In recent years, there has been a need for display apparatuses applicable to virtual reality (VR), augmented reality (AR), substitutional reality (SR), or mixed reality (MR). VR, AR, SR, and MR are collectively referred to as extended reality (XR). Display apparatuses for XR have been expected to have higher resolution and higher color reproducibility such that realistic feeling and the sense of immersion can be enhanced. Examples of the apparatuses that can be used as such display apparatuses include a liquid crystal display apparatus and a light-emitting apparatus including a light-emitting device (also referred to as a light-emitting element) such as an organic electro luminescent (EL) element or a light-emitting diode (LED).

Patent Document 1 discloses a display apparatus using an organic EL device (also referred to as organic EL element) for VR.

### REFERENCE

### Patent Document

[Patent Document 1] International Publication No. WO2018/087625

### SUMMARY OF THE INVENTION

### Problems to be Solved by the Invention

An object of one embodiment of the present invention is to provide a semiconductor device including a miniaturized transistor and a fabrication method thereof. Another object of one embodiment of the present invention is to provide a semiconductor device in which transistors are arranged with high density and a fabrication method thereof. Another object of one embodiment of the present invention is to provide a semiconductor device including a transistor with high on-state current and a fabrication method thereof. Another object of one embodiment of the present invention is to provide a semiconductor device having a high degree of integration and a fabrication method thereof. Another object of one embodiment of the present invention is to provide a semiconductor device having favorable electrical characteristics and a fabrication method thereof. Another object of one embodiment of the present invention is to provide a semiconductor device with high reliability and a fabrication method thereof. Another object of one embodiment of the present invention is to provide a method for fabricating a semiconductor device with high productivity. Another object of one embodiment of the present invention is to provide a novel semiconductor device and a fabrication method thereof.

Note that the description of these objects does not preclude the presence of other objects. One embodiment of the present invention does not necessarily achieve all the objects listed above. Note that other objects will be apparent from the description of the specification, the drawings, the claims, and the like, and other objects can be derived from the description of the specification, the drawings, the claims, and the like.

### Means for Solving the Problems

One embodiment of the present invention is a semiconductor device including a first transistor, a second transistor, and an insulating layer. The first transistor includes a first conductive layer, a second conductive layer, a first semiconductor layer, a first gate insulating layer, and a first gate electrode. The second transistor includes a third conductive layer, a fourth conductive layer, a second semiconductor layer, a second gate insulating layer, and the second conductive layer. The insulating layer is in contact with a top surface of the first conductive layer, a side surface of the first semiconductor layer, and a bottom surface of the second semiconductor layer, and includes an opening reaching the first conductive layer. The first conductive layer has a function of one of a source electrode and a drain electrode of the first transistor. The second conductive layer has a function of the other of the source electrode and the drain electrode of the first transistor and a function of a second gate electrode of the second transistor. The third conductive layer has a function of one of a source electrode and a drain electrode of the second transistor. The fourth conductive layer has a function of the other of the source electrode and the drain electrode of the second transistor. The first semiconductor layer is in contact with the top surface of the first conductive layer, an inner wall of the opening, and a side surface and a top surface of the second conductive layer. The first gate electrode is provided to include a region overlapping with the inner wall of the opening with the first gate insulating layer therebetween over the first semiconductor layer. The second conductive layer is provided over the second semiconductor layer with the second gate insulating layer therebetween and is in contact with a bottom surface of the first semiconductor layer. The third conductive layer is in contact with a side surface and a top surface of one side end portion of the second semiconductor layer. The fourth conductive layer is in contact with a side surface and a top surface of the other side end portion of the second semiconductor layer.

In the above, the first semiconductor layer and the second semiconductor layer each preferably include an oxide semiconductor.

Another embodiment of the present invention is a semiconductor device including a first transistor, a second transistor, and an insulating layer. The first transistor includes a first conductive layer, a second conductive layer, a first semiconductor layer, a gate insulating layer, and a first gate electrode. The second transistor includes the second conductive layer, a third conductive layer, a second semiconductor layer, the gate insulating layer, and a second gate electrode. The insulating layer is in contact with a top surface of the first conductive layer, a side surface of the first semiconductor layer, and a bottom surface of the second semiconductor layer, and includes an opening reaching the first conductive layer. The first semiconductor layer is in contact with the top surface of the first conductive layer, an inner wall of the opening, and a side surface and a top surface of one of the source electrode and the drain electrode of the second transistor. The first conductive layer has a function of one of a source electrode and a drain electrode of the first transistor. The second conductive layer has a function of the other of the source electrode and the drain electrode of the first transistor and a function of the one of the source electrode and the drain electrode of the second transistor. The third conductive layer has a function of the other of the source electrode and the drain electrode of the second transistor. The first gate electrode is provided to include a region overlapping with the inner wall of the opening with the gate insulating layer therebetween over the first semiconductor layer. The second conductive layer is in contact with a side surface and a top surface of one side end portion of the second semiconductor layer. The third conductive layer is in contact with a side surface and a top surface of the other side end portion of the second semiconductor layer. The second gate electrode is provided over the second semiconductor layer with the gate insulating layer therebetween.

In the above, the first semiconductor layer and the second semiconductor layer each preferably include an oxide semiconductor.

Another embodiment of the present invention is a method for fabricating a semiconductor device, including the following steps: forming a first conductive film; forming a first conductive layer by processing the first conductive film; forming a first insulating layer over the first conductive layer; forming a first metal oxide film over the first insulating layer; forming a first semiconductor layer by processing the first metal oxide film; forming a second conductive film over the first semiconductor layer; forming a second conductive layer and a third conductive layer each covering a side surface and part of a top surface of the first semiconductor layer by processing the second conductive film; forming a second insulating layer over the first semiconductor layer, the second conductive layer, the third conductive layer, and the first insulating layer; forming a third conductive film over the second insulating layer; forming an opening in the third conductive film, the second insulating layer, and the first insulating layer by processing the third conductive film, the second insulating layer, and the first insulating layer; forming a fourth conductive layer by processing the third conductive film; forming a second metal oxide film to cover a top surface of the first conductive layer, an inner wall of the opening, a top surface of the fourth conductive layer, and part of a top surface of the second insulating layer; forming a second semiconductor layer by processing the second metal oxide film to include a region overlapping with the inner wall of the opening; forming a third insulating layer over the second semiconductor layer, the fourth conductive layer, and the second insulating layer; forming a fourth conductive film over the third insulating layer; and to forming a fifth conductive layer by processing the fourth conductive film to include a region overlapping with the opening.

In the above, treatment for supplying oxygen to the first insulating layer is preferably performed after the step of forming the first insulating layer.

### Effect of the Invention

An embodiment of the present invention can provide a semiconductor device including a miniaturized transistor and a fabrication method thereof. Another embodiment of the present invention can provide a semiconductor device in which transistors are arranged with high density and a fabrication method thereof. Another embodiment of the present invention can provide a semiconductor device including a transistor with high on-state current and a fabrication method thereof. Another embodiment of the present invention can provide a semiconductor device having a high degree of integration and a fabrication method thereof. Another embodiment of the present invention can provide a semiconductor device having favorable electrical characteristics and a fabrication method thereof. Another embodiment of the present invention can provide a semiconductor device with high reliability and a fabrication method thereof. Another embodiment of the present invention can provide a method for fabricating a semiconductor device with high productivity. Another embodiment of the present invention can provide a novel semiconductor device and a fabrication method thereof.

Note that the description of these effects does not preclude the existence of other effects. One embodiment of the present invention does not necessarily have all these effects. Note that other effects will be apparent from the description of the specification, the drawings, the claims, and the like, and other effects can be derived from the description of the specification, the drawings, the claims, and the like.

### BRIEF DESCRIPTION OF THE DRAWINGS

FIG. 1A is a plan view illustrating an example of a semiconductor device. FIG. 1B is a cross-sectional view illustrating the example of the semiconductor device.

FIG. 2A is a plan view illustrating an example of a semiconductor device. FIG. 2B is a cross-sectional view illustrating the example of the semiconductor device.

FIG. 3A is a plan view illustrating an example of a semiconductor device. FIG. 3B is a cross-sectional view illustrating the example of the semiconductor device.

FIG. 4A is a plan view illustrating an example of a semiconductor device. FIG. 4B is a cross-sectional view illustrating the example of the semiconductor device.

FIG. 5A is a plan view illustrating an example of a semiconductor device. FIG. 5B is a cross-sectional view illustrating the example of the semiconductor device.

FIG. 6A is a plan view illustrating an example of a semiconductor device. FIG. 6B is a cross-sectional view illustrating the example of the semiconductor device.

FIG. 7A to FIG. 7C are cross-sectional views each illustrating an example of a semiconductor device.

FIG. 8A to FIG. 8C are cross-sectional views each illustrating an example of a semiconductor device.

FIG. 9A to FIG. 9C are cross-sectional views illustrating an example of a method for fabricating a semiconductor device.

FIG. 10A to FIG. 10C are cross-sectional views illustrating an example of a method for fabricating a semiconductor device.

FIG. 11A to FIG. 11C are cross-sectional views illustrating an example of a method for fabricating a semiconductor device.

FIG. 12A to FIG. 12C are cross-sectional views illustrating an example of a method for fabricating a semiconductor device.

FIG. 13A to FIG. 13C are cross-sectional views illustrating an example of a method for fabricating a semiconductor device.

FIG. 14A to FIG. 14D are circuit diagrams of a pixel circuit.

FIG. 15A to FIG. 15D are circuit diagrams of a pixel circuit.

FIG. 16 is a perspective view illustrating an example of a display apparatus.

FIG. 17 is a cross-sectional view illustrating an example of a display apparatus.

FIG. 18 is a cross-sectional view illustrating an example of a display apparatus.

FIG. 19 is a cross-sectional view illustrating an example of a display apparatus.

FIG. 20 is a cross-sectional view illustrating an example of a display apparatus.

FIG. 21 is a cross-sectional view illustrating an example of a display apparatus.

FIG. 22 is a cross-sectional view illustrating an example of a display apparatus.

FIG. 23A to FIG. 23H are diagrams each illustrating an example of a pixel.

FIG. 24A to FIG. 24K are diagrams each illustrating an example of a pixel.

FIG. 25A to FIG. 25F are diagrams each illustrating a structure example of a light-emitting device.

FIG. 26A to FIG. 26C are diagrams each illustrating a structure example of a light-emitting device.

FIG. 27A and FIG. 27B are diagrams each illustrating a structure example of a light-receiving device. FIG. 27C to FIG. 27E are diagrams each illustrating a structure example of a display apparatus.

FIG. 28A to FIG. 28D are diagrams each illustrating an example of an electronic device.

FIG. 29A to FIG. 29F are diagrams each illustrating an example of an electronic device.

FIG. 30A to FIG. 30G are diagrams each illustrating an example of an electronic device.

FIG. 31 is a cross-sectional view illustrating an example of a semiconductor device.

FIG. 32 is a cross-sectional STEM image of a semiconductor device.

FIG. 33A and FIG. 33B show Id-Vg characteristics of transistors.

### MODE FOR CARRYING OUT THE INVENTION

Embodiments will be described in detail with reference to the drawings. Note that the present invention is not limited to the following description, and it will be readily appreciated by those skilled in the art that modes and details of the present invention can be modified in various ways without departing from the spirit and scope of the present invention. Therefore, the present invention should not be construed as being limited to the description in the following embodiments.

Note that in structures of the invention described below, the same portions or portions having similar functions are denoted by the same reference numerals in different drawings, and the description thereof is not repeated. The same hatching pattern is used for portions having similar functions, and the portions are not denoted by specific reference numerals in some cases.

The position, size, range, or the like of each component illustrated in drawings does not represent the actual position, size, range, or the like in some cases for easy understanding. Therefore, the disclosed invention is not necessarily limited to the position, size, range, or the like disclosed in the drawings.

Note that the terms “film” and “layer” can be used interchangeably depending on the case or the circumstances. For example, the term “conductive layer” can be replaced with the term “conductive film”. As another example, the term “insulating film” can be replaced with the term “insulating layer”.

In this specification and the like, a device formed using a metal mask or a fine metal mask (FMM) may be referred to as a device having a metal mask (MM) structure. In this specification and the like, a device formed without using a metal mask or an FMM may be referred to as a device having a metal maskless (MML) structure.

In this specification and the like, a structure in which at least light-emitting layers of light-emitting devices having different emission wavelengths are separately formed may be referred to as a side-by-side (SBS) structure. The SBS structure can optimize materials and structures of light-emitting devices and thus can extend freedom of choice of materials and structures, whereby the luminance and the reliability can be easily improved.

In this specification and the like, a hole or an electron is sometimes referred to as a carrier. Specifically, a hole-injection layer or an electron-injection layer may be referred to as a carrier-injection layer, a hole-transport layer or an electron-transport layer may be referred to as a carrier-transport layer, and a hole-blocking layer or an electron-blocking layer may be referred to as a carrier-blocking layer. Note that the above-described carrier-injection layer, carrier-transport layer, and carrier-blocking layer cannot be distinguished from each other on the basis of the cross-sectional shape or properties in some cases. One layer may have two or three functions of the carrier-injection layer, the carrier-transport layer, and the carrier-blocking layer in some cases.

In this specification and the like, a light-emitting device includes an EL layer between a pair of electrodes. The EL layer includes at least a light-emitting layer. Examples of layers (also referred to as functional layers) in the EL layer include a light-emitting layer, carrier-injection layers (a hole-injection layer and an electron-injection layer), carrier-transport layers (a hole-transport layer and an electron-transport layer), and carrier-blocking layers (a hole-blocking layer and an electron-blocking layer).

In this specification and the like, a light-receiving device (also referred to as a light-receiving element) includes at least an active layer functioning as a photoelectric conversion layer between a pair of electrodes.

In this specification and the like, the term “island shape” refers to a state where two or more layers formed using the same material in the same step are physically separated from each other. For example, “island-shaped light-emitting layer” means a state where the light-emitting layer and its adjacent light-emitting layer are physically separated from each other.

In this specification and the like, a tapered shape refers to a shape such that at least part of the side surface of a component is inclined with respect to the substrate surface or the formation surface. For example, a tapered shape refers to a shape including a region where the angle between the inclined side surface and the substrate surface or the formation surface (such an angle is also referred to as a taper angle) is less than 90°. Note that the side surface of the component, the substrate plane, and the formation surface are not necessarily completely flat and may be substantially flat with a slight curvature or with slight unevenness.

In this specification and the like, a mask layer (also referred to as a sacrificial layer) refers to a layer that is positioned above at least a light-emitting layer (specifically, a layer processed into an island shape among layers included in an EL layer) and has a function of protecting the light-emitting layer in the manufacturing process.

In this specification and the like, step disconnection refers to a phenomenon in which a layer, a film, or an electrode is split because of the shape of the formation surface (e.g., a step).

In this specification and the like, the expression “having substantially the same planar shape” means that at least outlines of stacked layers partly overlap each other. For example, the case of processing an upper layer and a lower layer with the use of the same mask pattern or mask patterns that are partly the same is included. Note that in some cases, the outlines do not exactly overlap with each other and the upper layer is positioned inward from the lower layer or the upper layer is positioned outward from the lower layer; such cases are also represented by the expression “having substantially the same planar shape”.

### Embodiment 1

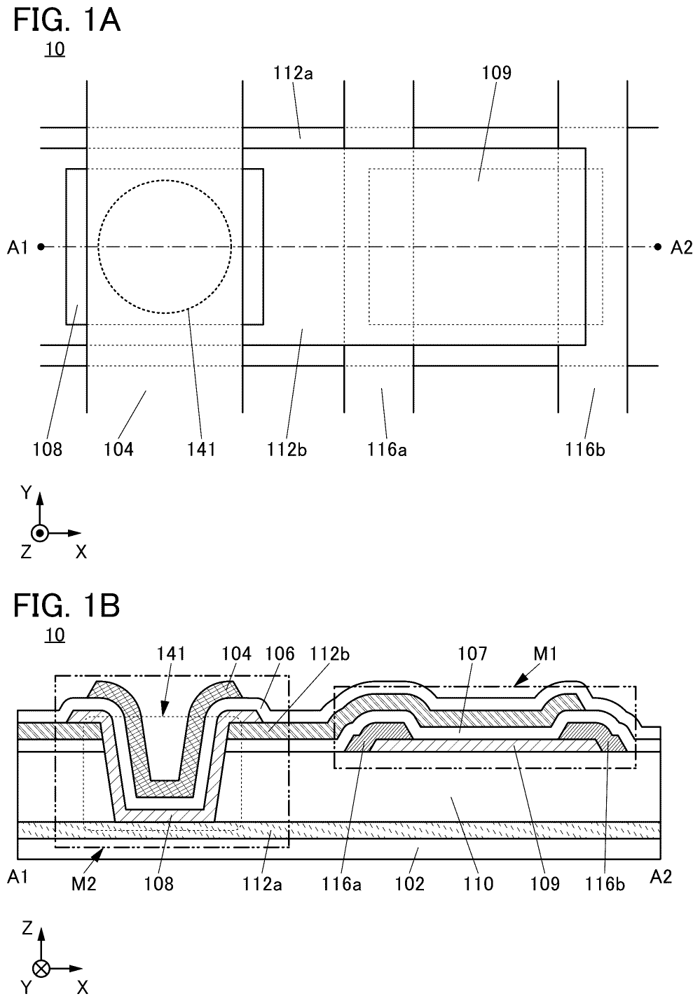

One embodiment of the present invention is a semiconductor device including one lateral channel transistor (described later) and one vertical channel transistor (described later). Any one of a source electrode, a drain electrode, and a gate electrode of the lateral channel transistor is electrically connected to any one of a source electrode, a drain electrode, and a gate electrode of the vertical channel transistor in the semiconductor device. The area in a substrate plane occupied by the semiconductor device can be smaller than that occupied by a semiconductor device including two lateral channel transistors. In this embodiment, a semiconductor device of one embodiment of the present invention, a fabrication method thereof, and the like will be described with reference to FIG. 1A to FIG. 15D.

### Structure Example

A semiconductor device 10 of one embodiment of the present invention is described. FIG. 1A is a plan view (also referred to as a top view) of the semiconductor device 10. FIG. 1B shows a cross-sectional view taken along a dashed-dotted line A1-A2 in FIG. 1A. Note that in FIG. 1A, some components of the semiconductor device 10 are not illustrated. Some components are not illustrated in plan views of semiconductor devices in the following drawings, as in FIG. 1A.

The semiconductor device 10 includes a transistor M1 and a transistor M2 over a substrate 102.

The transistor M1 includes the following components: a semiconductor layer 109 provided over a conductive layer 112a and an insulating layer 110 which are stacked over the substrate 102; a conductive layer 116a in contact with a side surface and the top surface of one side end portion of the semiconductor layer 109 and a part of the top surface of the insulating layer 110; a conductive layer 116b in contact with a side surface and the top surface of the other side end portion of the semiconductor layer 109 and another part of the top surface of the insulating layer 110; an insulating layer 107 including regions in contact with the top surface of the semiconductor layer 109, the top surface and the side surface of the conductive layer 116a, the top surface and the side surface of the conductive layer 116b, and another part of the top surface of the insulating layer 110; and a conductive layer 112b over the insulating layer 107.

In the transistor M1, the semiconductor layer 109 functions as a semiconductor layer where a channel is formed. The conductive layer 116a functions as one of a source electrode and a drain electrode and the conductive layer 116b functions as the other of the source electrode and the drain electrode. The insulating layer 107 functions as a gate insulating layer. The conductive layer 112b functions as a gate electrode.

The transistor M2 includes the following components: the conductive layer 112a over the substrate 102; the conductive layer 112b provided over the insulating layer 110 and the insulating layer 107 which are stacked over the conductive layer 112a; a semiconductor layer 108 in contact with part of a top surface of the conductive layer 112b and an inner wall (part of the top surface of the conductive layer 112a, a side surface of the insulating layer 110, a side surface of the insulating layer 107, and a side surface of the conductive layer 112b) of an opening 141 provided in the insulating layer 110 and the like; an insulating layer 106 including regions in contact with the top surface and a side surface of the semiconductor layer 108 and the top surface of the conductive layer 112b; and a conductive layer 104 provided over the insulating layer 106 to include a region overlapping with the inner wall of the opening 141.

In the transistor M2, the conductive layer 112a functions as one of a source electrode and a drain electrode and the conductive layer 112b functions as the other of the source electrode and the drain electrode. The semiconductor layer 108 functions as a semiconductor layer where a channel is formed. The insulating layer 106 functions as a gate insulating layer. The conductive layer 104 functions as a gate electrode.

In the transistor M2, the region of the semiconductor layer 108, which functions as a channel formation region, overlaps with the conductive layer 104 with the insulating layer 106 sandwiched therebetween and is positioned above the top surface of the conductive layer 112a and below the bottom surface of the conductive layer 112b in a cross-sectional view (see FIG. 1B). That is, the length of this region is the channel length of the transistor M2. Hence, the channel length of the transistor M2 can be determined by adjusting the thickness of the insulating layers (the insulating layer 110 and the insulating layer 107) which is provided between the conductive layer 112a and the conductive layer 112b. Thus, a transistor with a short channel length can be fabricated with high accuracy. When a plurality of transistors M2 are fabricated, variation in characteristics among the transistors M2 can be reduced.

In the transistor M2, since the semiconductor layer 108 is provided in the region overlapping with the opening 141 in a plan view (see FIG. 1A), the outer circumferential length of the opening 141, which is more properly the outer circumferential length of the channel formation region of the transistor M2 in the opening 141, is the channel width of the transistor M2. Note that in FIG. 1B, the opening 141 has a width in the X-direction that is narrowed toward the conductive layer 112a and widened toward the conductive layer 112b. In this structure, the outer circumferential length of the channel formation region in a portion with the smallest width in the X-direction of the opening 141 may be defined as the channel width of the transistor M2; meanwhile, the outer circumferential length of the channel formation region in a portion with the largest width in the X-direction of the opening 141 may be defined as the channel width of the transistor M2. Alternatively, the intermediate value of both of the cases may be defined as the channel width of the transistor M2.

As described above, the conductive layer 112b functions as the gate electrode of the transistor M1 and as the other of the source electrode and the drain electrode of the transistor M2. In other words, the gate electrode of the transistor M1 is electrically connected to the other of the source electrode and the drain electrode of the transistor M2. Thus, the semiconductor device 10 of one embodiment of the present invention includes two transistors (the transistor M1 and the transistor M2) electrically connected to each other.

In the transistor M1, a drain current flows in the region of the semiconductor layer 109, which is positioned between the conductive layer 116a and the conductive layer 116b; in the transistor M2, a drain current flows in the region of the semiconductor layer 108, which is positioned between the conductive layer 112a and the conductive layer 112b. Specifically, the direction in which the drain current flows in the transistor M1 is substantially parallel to the substrate plane; the direction in which the drain current flows in the transistor M2 is substantially perpendicular to the substrate plane.

Like the transistor M1, a transistor in which the source electrode and the drain electrode are placed in the lateral direction (the X-direction or the Y-direction in FIG. 1A and FIG. 1B) and the drain current flows in the lateral direction is referred to as a “lateral channel transistor”. On the other hand, like the transistor M2, a transistor in which the source electrode and the drain electrode are placed in the vertical direction (the Z-direction in FIG. 1A and FIG. 1B) and the drain current flows in the vertical direction is referred to as a “vertical channel transistor”.

In the vertical channel transistor, since both the source electrode and the drain electrode are placed in the Z-direction, the area in the substrate plane occupied by the transistor can be significantly smaller than that occupied by the lateral channel transistor. In the semiconductor device 10 of one embodiment of the present invention, one (transistor M2) of the two transistors included in the semiconductor device is a vertical channel transistor. Thus, in the semiconductor device 10 of one embodiment of the present invention, the area in the substrate plane occupied by the semiconductor device can be smaller than that occupied by the semiconductor device including two lateral channel transistors placed in the lateral direction. In addition, in the semiconductor device 10 of one embodiment of the present invention, one (transistor M1) of the two transistors included in the semiconductor device is a lateral channel transistor. Thus, some transistor components such as the source electrode and the drain electrode can be formed on the same plane at a time. Accordingly, the number of formation steps can be smaller than that of the vertical channel transistor. As described above, according to one embodiment of the present invention, a semiconductor device in which transistors are arranged with high density can be provided. A semiconductor device having a high degree of integration can be provided. For example, the semiconductor device 10 of one embodiment of the present invention is used for a pixel circuit of a display apparatus (described later), whereby the display apparatus can have high resolution.

Materials that can be used for the semiconductor device 10 of one embodiment of the present invention are described below.

### [Substrate 102]

There is no great limitation on a material used for the substrate 102. The material is determined by the purpose in consideration of whether it has a light-transmitting property, heat resistance high enough to withstand heat treatment, and the like. For example, a glass substrate of barium borosilicate glass and aluminoborosilicate glass, or the like, a ceramic substrate, a quartz substrate, a sapphire substrate, or the like can be used. Alternatively, a semiconductor substrate, a flexible substrate, an attachment film, a base film, or the like may be used.

Examples of the semiconductor substrate include a semiconductor substrate containing a material such as silicon or germanium and a compound semiconductor substrate containing a material such as silicon carbide, silicon germanium, gallium arsenide, indium phosphide, zinc oxide, or gallium oxide. The semiconductor substrate may be a single crystal semiconductor or a polycrystalline semiconductor.

When the semiconductor device 10 of one embodiment of the present invention is used for a display apparatus, a large-sized glass substrate of the 6th generation (1500 mm′1850 mm), the 7th generation (1870 mm′2200 mm), the 8th generation (2200 mm′2400 mm), the 9th generation (2400 mm′2800 mm), or the 10th generation (2950 mm′3400 mm), for example, can be used as the substrate 102. Thus, a large-sized display apparatus can be fabricated. When the size of the substrate is increased, a larger number of display apparatuses can be produced from one substrate, which leads to a reduction in production cost.

Note that to increase the flexibility of the semiconductor device, a flexible substrate, an attachment film, a base film, or the like may be used as the substrate 102.

For the material of the flexible substrate, the attachment film, the base film, or the like, a polyester resin such as polyethylene terephthalate (PET) or polyethylene naphthalate (PEN), a polyacrylonitrile resin, an acrylic resin, a polyimide resin, a polymethyl methacrylate resin, a polycarbonate (PC) resin, a polyethersulfone (PES) resin, a polyamide resin (e.g., nylon or aramid), a polysiloxane resin, a cycloolefin resin, a polystyrene resin, a polyamide-imide resin, a polyurethane resin, a polyvinyl chloride resin, a polyvinylidene chloride resin, a polypropylene resin, a polytetrafluoroethylene (PTFE) resin, an ABS resin, or cellulose nanofiber can be used, for example.

When the above-described material is used for the substrate 102, a lightweight semiconductor device can be provided. Furthermore, when the above-described material is used for the substrate 102, a shock-resistant semiconductor device can be provided. When the above-described material is used for the substrate 102, a semiconductor device that is less likely to be broken can be provided.

When a flexible substrate is used as the substrate 102, the flexible substrate preferably has a lower coefficient of linear expansion because deformation due to an environment is suppressed. The flexible substrate used as the substrate 102 may be formed using, for example, a material whose coefficient of linear expansion is lower than or equal to 1×10⁻³/K, lower than or equal to 5×10⁻⁵/K, or lower than or equal to 1×10⁻⁵/K. In particular, aramid is suitable for the flexible substrate used as the substrate 102 because of its low coefficient of linear expansion.

[Conductive Layer 104, Conductive Layer 112a, Conductive Layer 112b, Conductive Layer 116a, and Conductive Layer 116b]

Examples of the conductive material that can be used for conductive layers such as various wirings and electrodes included in the semiconductor device 10 of one embodiment of the present invention, in addition to the conductive layers (conductive layer 116a and conductive layer 116b) functioning as the source electrode and the drain electrode of the transistor M1, the conductive layer (conductive layer 112b) functioning as the gate electrode of the transistor M1, the conductive layers (conductive layer 112a and conductive layer 112b) functioning as the source electrode and the drain electrode of the transistor M2, and the conductive layer (conductive layer 104) functioning as the gate electrode of the transistor M2 include a metal element selected from aluminum (Al), chromium (Cr), copper (Cu), silver (Ag), gold (Au), platinum (Pt), tantalum (Ta), nickel (Ni), titanium (Ti), molybdenum (Mo), tungsten (W), hafnium (Hf), vanadium (V), niobium (Nb), manganese (Mn), magnesium (Mg), zirconium (Zr), beryllium (Be), and the like, an alloy including any of the metal elements, an alloy including any of the metal elements in combination, and the like. Furthermore, a semiconductor typified by polycrystalline silicon containing an impurity element such as phosphorus, or silicide such as nickel silicide may be used. There is no particular limitation on the formation method of the conductive material, and a variety of formation methods such as an evaporation method, a chemical vapor deposition (CVD) method, a sputtering method, and a spin coating method can be employed.

A Cu—X alloy (X is Mn, Ni, Cr, Fe, Co, Mo, Ta, or Ti) may be used for the conductive material. The layer formed with a Cu—X alloy enables fabrication costs to be reduced because processing can be performed by a wet etching process. An aluminum alloy containing one or more of the elements selected from titanium, tantalum, tungsten, molybdenum, chromium, neodymium, and scandium may be used for the conductive material.

As the conductive material that can be used for the conductive layer, a conductive material containing oxygen, such as indium tin oxide, indium oxide containing tungsten oxide, indium zinc oxide containing tungsten oxide, indium oxide containing titanium oxide, indium tin oxide containing titanium oxide, indium zinc oxide, or indium tin oxide to which silicon oxide is added can also be used. Furthermore, a conductive material containing nitrogen, such as titanium nitride, tantalum nitride, or tungsten nitride, can be used. The conductive layer can have a stacked-layer structure with an appropriate combination of a conductive material containing oxygen, a conductive material containing nitrogen, and a material containing the above-described metal element.

For example, the conductive layer can have a single-layer structure of an aluminum layer including silicon, a two-layer structure in which a titanium layer is stacked over an aluminum layer, a two-layer structure in which a titanium layer is stacked over a titanium nitride layer, a two-layer structure in which a tungsten layer is stacked over a titanium nitride layer, a two-layer structure in which a tungsten layer is stacked over a tantalum nitride layer, or a three-layer structure of a titanium layer, an aluminum layer stacked over the titanium layer, and a titanium layer further stacked thereover.

Furthermore, a plurality of conductive layers formed with the above conductive materials may be stacked and used. For example, the conductive layer may have a stacked-layer structure combining a material containing the above metal element and a conductive material containing oxygen. The conductive layer can also have a stacked-layer structure combining a material containing the above metal element and a conductive material containing nitrogen. The conductive layer may also have a stacked-layer structure combining a material containing the above metal element, a conductive material containing oxygen, and a conductive material containing nitrogen.

For example, the conductive layer can have a three-layer structure in which a conductive layer containing copper is stacked over a conductive layer containing oxygen and at least one of indium and zinc, and a conductive layer containing oxygen and at least one of indium and zinc further stacked thereover. In this case, the side surface of the conductive layer containing copper is preferably covered with the conductive layer containing oxygen and at least one of indium and zinc. In addition, for example, a plurality of conductive layers containing oxygen and at least one of indium and zinc may be stacked and used.

When an oxide semiconductor is used for the semiconductor layer 108 and the semiconductor layer 109, for example, a conductive material that makes the oxide semiconductor an n-type is preferably used as each of the conductive layer 112a and the conductive layer 112b in contact with the semiconductor layer 108 and the conductive layer 116a and the conductive layer 116b in contact with the semiconductor layer 109. For example, a conductive material containing nitrogen may be used. For example, a conductive material containing nitrogen and titanium or tantalum may be used. Another conductive material may be provided so as to overlap with the conductive material containing nitrogen.

### [Insulating Layer 106, Insulating Layer 107, and Insulating Layer 110]

In addition to the insulating layer functioning as the gate insulating layer of the transistor M1 (insulating layer 107), the insulating layer functioning as the gate insulating layer of the transistor M2 (insulating layer 106), and the insulating layer 110 functioning as an interlayer film, the insulating layers included in the semiconductor device 10 of one embodiment of the present invention can be formed with a single layer or stacked layers of a material selected from aluminum nitride, aluminum oxide, aluminum nitride oxide, aluminum oxynitride, magnesium oxide, silicon nitride, silicon oxide, silicon nitride oxide, silicon oxynitride, gallium oxide, germanium oxide, yttrium oxide, zirconium oxide, lanthanum oxide, neodymium oxide, hafnium oxide, tantalum oxide, aluminum silicate, and the like. Furthermore, a material in which a plurality of materials selected from an oxide material, a nitride material, an oxynitride material, and a nitride oxide material are mixed may be used.

Note that in this specification and the like, oxynitride refers to a material that contains more oxygen than nitrogen. Nitride oxide refers to a material that contains more nitrogen than oxygen. The content of each element can be measured by a Rutherford backscattering spectrometry (RBS) method or the like, for example.

When an oxide semiconductor is used for the semiconductor layer 108 and the semiconductor layer 109, for example, an insulating material in which oxygen is contained and hydrogen is reduced is preferably used for the insulating layer 106, the insulating layer 107, and the insulating layer 110. For example, silicon oxide is preferably used for each of the insulating layer 106, the insulating layer 107, and the insulating layer 110. When silicon oxide is used for each of the insulating layer 106, the insulating layer 107, and the insulating layer 110, the semiconductor layer 108 and the semiconductor layer 109 each including a region in contact with any of these insulating layers are less likely to have n-type conductivity. In addition, oxygen can be efficiently supplied from these insulating layers to the semiconductor layer 108 and the semiconductor layer 109. Thus, oxygen vacancies (Vo) in the semiconductor layer 108 and the semiconductor layer 109 are reduced, whereby both the electrical characteristics and reliability of the transistor M1 and the transistor M2 can be improved.

For the insulating layer (not illustrated) above or below the transistor M1 and the transistor M2, an insulating material that is relatively impermeable to impurities is preferably used, for example. For example, a single layer or a stacked layer of an insulating material containing boron, carbon, nitrogen, oxygen, fluorine, magnesium, aluminum, silicon, phosphorus, chlorine, argon, gallium, germanium, yttrium, zirconium, lanthanum, neodymium, hafnium, or tantalum is used. As examples of an insulating material that does not allow impurities to permeate easily, aluminum oxide, aluminum nitride, aluminum oxynitride, aluminum nitride oxide, gallium oxide, germanium oxide, yttrium oxide, zirconium oxide, lanthanum oxide, neodymium oxide, hafnium oxide, tantalum oxide, and silicon nitride can be given.

When an insulating material that is relatively impermeable to impurities is used for the insulating layer above or below the transistor M1 and the transistor M2, diffusion of impurities into the transistor M1 and the transistor M2 from above and below can be prevented, whereby the reliability of the semiconductor device 10 can be improved.

As the insulating layer above or below the transistor M1 and the transistor M2, an insulating layer that can function as a planarization layer may be used. As an insulating layer that can serve as a planarization layer, a heat-resistant organic material such as polyimide, acrylic resin, benzocyclobutene resin, polyamide, or epoxy resin can be used. Other than the above-described organic materials, it is also possible to use a low-dielectric constant material (a low-k material), a siloxane-based resin, PSG (phosphosilicate glass), BPSG (borophosphosilicate glass), or the like. Note that a plurality of insulating layers formed of these materials may be stacked.

Note that the siloxane resin corresponds to a resin including a Si—O—Si bond formed using a siloxane-based material as a starting material. The siloxane resin may include an organic group (e.g., an alkyl group or an aryl group) or a fluoro group as a substituent. The organic group may include a fluoro group.

A surface of the insulating layer that can function as a planarization layer may be subjected to chemical mechanical polishing (CMP) treatment. By performing the CMP treatment, unevenness of a sample surface can be reduced, so that coverage with an insulating layer and a conductive layer to be formed later can be increased.

### [Semiconductor Layer 108 and Semiconductor Layer 109]

For the semiconductor layer 109 functioning as the semiconductor layer where the channel of the transistor M1 is formed and the semiconductor layer 108 functioning as the semiconductor layer where the channel of the transistor M2 is formed, a single crystal semiconductor, a polycrystalline semiconductor, a microcrystalline semiconductor, an amorphous semiconductor, or the like can be used alone or can be used in combination. As a semiconductor material, silicon and germanium can be used, for example. Alternatively, a compound semiconductor such as silicon germanium, silicon carbide, gallium arsenide, or a nitride semiconductor can be used. As a compound semiconductor, an organic substance having semiconductor characteristics or a metal oxide having semiconductor characteristics (also referred to as an oxide semiconductor) can be used. Note that these semiconductor materials may contain an impurity as a dopant.

In particular, since an oxide semiconductor has a band gap of 2 eV or more, a transistor with an oxide semiconductor, which is a kind of metal oxide, used as a semiconductor layer where the channel is formed (also referred to as an “OS transistor”) has an extremely lower off-state current than a transistor with any other material. Accordingly, the power consumption of the semiconductor device 10 can be reduced. In addition, an OS transistor operates stably even in a high-temperature environment and has small fluctuation in characteristics. For example, the off-state current hardly increases even in a high-temperature environment. Specifically, the off-state current hardly increases even at an environment temperature higher than or equal to room temperature and lower than or equal to 200° C. In addition, the on-state current of an OS transistor is unlikely to decrease even in a high-temperature environment. Accordingly, a semiconductor device including an OS transistor achieves stable operation and high reliability even in a high temperature environment.

Examples of silicon that can be used for the semiconductor layer where the channel is formed include single crystal silicon, polycrystalline silicon, microcrystalline silicon, and amorphous silicon. An example of polycrystalline silicon is low-temperature polysilicon (LTPS).

A transistor including amorphous silicon in the semiconductor layer where the channel is formed can be formed over a large-sized glass substrate; thereby being fabricated at a low cost. A transistor including polycrystalline silicon in the semiconductor layer where the channel is formed has high field-effect mobility and enables high-speed operation. A transistor including microcrystalline silicon in the semiconductor layer where the channel is formed has higher field-effect mobility and enables higher speed operation than the transistor including amorphous silicon.

In this embodiment, an OS transistor is used for both the transistor M1 and the transistor M2. In other words, an oxide semiconductor is used for both the semiconductor layer 108 and the semiconductor layer 109. Since an OS transistor has a high breakdown voltage between the source and the drain, the channel length can be shortened. Accordingly, the on-state current of the transistor can be increased.

Examples of a metal oxide that can be used for a semiconductor layer where a channel of an OS transistor is formed include indium oxide, gallium oxide, and zinc oxide. The metal oxide preferably contains at least indium (In) or zinc (Zn). The metal oxide preferably contains two or three selected from indium, an element M, and zinc. The element M is one or more of gallium, aluminum, silicon, boron, yttrium, tin, copper, vanadium, beryllium, titanium, iron, nickel, germanium, zirconium, molybdenum, lanthanum, cerium, neodymium, hafnium, tantalum, tungsten, cobalt, and magnesium. Specifically, the element M is preferably one or more of aluminum, gallium, yttrium, and tin.

Examples of the metal oxide that can be used include indium oxide, indium zinc oxide (In—Zn oxide), indium tin oxide (In—Sn oxide), indium titanium oxide (In—Ti oxide), indium aluminum zinc oxide (In—Al—Zn oxide, also referred to as IAZO), indium tin zinc oxide (In—Sn—Zn oxide), indium titanium zinc oxide (In—Ti—Zn oxide), indium gallium zinc oxide (In—Ga—Zn oxide, also referred to as IGZO), indium gallium tin zinc oxide (In—Ga—Sn—Zn oxide), and indium gallium aluminum zinc oxide (In—Ga—Al—Zn oxide, also referred to as IGAZO or IAGZO). Alternatively, indium tin oxide containing silicon or the like can be used.

The element M is preferably one or more selected from gallium, aluminum, yttrium, and tin. In particular, the element M is preferably gallium.

The composition of the metal oxide used for the semiconductor layer where the channel is formed significantly affects the electrical characteristics and reliability of the OS transistor. For example, a metal oxide with a higher indium content enables the transistor to have a higher on-state current.

As the In—Zn oxide used for the semiconductor layer where the channel of the OS transistor is formed, a metal oxide in which the atomic ratio of indium is higher than or equal to that of zinc is preferably used. For example, a metal oxide with metal elements in any of the following atomic ratios can be used: In:Zn=1:1, In:Zn=2:1, In:Zn=3:1, In:Zn=4:1, In:Zn=5:1, In:Zn=7:1, or In:Zn=10:1, or the vicinity thereof.

In the case where an In—Sn oxide is used for the semiconductor layer where the channel of the OS transistor is formed, a metal oxide in which the atomic ratio of indium is higher than or equal to that of tin is preferably used. For example, a metal oxide with metal elements in any of the following atomic ratios can be used: In:Sn=1:1, In:Sn=2:1, In:Sn=3:1, In:Sn=4:1, In:Sn=5:1, In:Sn=7:1, or In:Sn=10:1, or the vicinity thereof.

In the case where an In—Sn—Zn oxide is used for the semiconductor layer where the channel of the OS transistor is formed, a metal oxide in which the atomic ratio of indium is higher than that of tin is preferably used. Moreover, it is preferable to use a metal oxide in which the atomic ratio of zinc is higher than that of tin. For example, a metal oxide with metal elements in any of the following atomic ratios can be used: In:Sn:Zn=2:1:3, In:Sn:Zn=3:1:2, In:Sn:Zn=4:2:3, In:Sn:Zn=4:2:4.1, In:Sn:Zn=5:1:3, In:Sn:Zn=5:1:6, In:Sn:Zn=5:1:7, In:Sn:Zn=5:1:8, In:Sn:Zn=6:1:6, In:Sn:Zn=10:1:3, In:Sn:Zn=10:1:6, In:Sn:Zn=10:1:7, In:Sn:Zn=10:1:8, In:Sn:Zn=5:2:5, In:Sn:Zn=10:1:10, In:Sn:Zn=20:1:10, In:Sn:Zn=40:1:10, or the vicinity thereof.

In the case where an In—Al—Zn oxide is used for the semiconductor layer where the channel of the OS transistor is formed, a metal oxide in which the atomic ratio of indium is higher than that of aluminum is preferably used. Moreover, it is preferable to use a metal oxide in which the atomic ratio of zinc is higher than that of Al. For example, a metal oxide with metal elements in any of the following atomic ratios can be used: In:Al:Zn=2:1:3, In:Al:Zn=3:1:2, In:Al:Zn=4:2:3, In:Al:Zn=4:2:4.1, In:Al:Zn=5:1:3, In:Al:Zn=5:1:6, In:Al:Zn=5:1:7, In:Al:Zn=5:1:8, In:Al:Zn=6:1:6, In:Al:Zn=10:1:3, In:Al:Zn=10:1:6, In:Al:Zn=10:1:7, In:Al:Zn=10:1:8, In:Al:Zn=5:2:5, In:Al:Zn=10:1:10, In:Al:Zn=20:1:10, In:Al:Zn=40:1:10, or the vicinity thereof.

In the case where an In—Ga—Zn oxide is used for the semiconductor layer where the channel of the OS transistor is formed, a metal oxide in which the atomic ratio of indium is higher than that of gallium is preferably used. It is further preferable to use a metal oxide in which the atomic ratio of zinc is higher than that of gallium. For example, a metal oxide with metal elements in any of the following atomic ratios can be used for the semiconductor layer: In:Ga:Zn=2:1:3, In:Ga:Zn=3:1:2, In:Ga:Zn=4:2:3, In:Ga:Zn=4:2:4.1, In:Ga:Zn=5:1:3, In:Ga:Zn=5:1:6, In:Ga:Zn=5:1:7, In:Ga:Zn=5:1:8, In:Ga:Zn=6:1:6, In:Ga:Zn=10:1:3, In:Ga:Zn=10:1:6, In:Ga:Zn=10:1:7, In:Ga:Zn=10:1:8, In:Ga:Zn=5:2:5, In:Ga:Zn=10:1:10, In:Ga:Zn=20:1:10, In:Ga:Zn=40:1:10, or the vicinity thereof.

In the case where an In-M-Zn oxide is used for the semiconductor layer where the channel of the OS transistor is formed, a metal oxide in which the atomic ratio of indium to the metal elements is higher than that of the element M can be used. It is further preferable to use a metal oxide in which the atomic ratio of zinc is higher than that of the element M. For example, a metal oxide with metal elements in any of the following atomic ratios can be used for the semiconductor layer: In:M:Zn=2:1:3, In:M:Zn=3:1:2, In:M:Zn=4:2:3, In:M:Zn=4:2:4.1, In:M:Zn=5:1:3, In:M:Zn=5:1:6, In:M:Zn=5:1:7, In:M:Zn=5:1:8, In:M:Zn=6:1:6, In:M:Zn=10:1:3, In:M:Zn=10:1:6, In:M:Zn=10:1:7, In:M:Zn=10:1:8, In:M:Zn=5:2:5, In:M:Zn=10:1:10, In:M:Zn=20:1:10, In:M:Zn=40:1:10, or the vicinity thereof.

In the case where a plurality of metal elements are contained as the element M, the sum of the atomic ratios of the metal elements can be the atomic ratio of the element M. In In—Ga—Al—Zn oxide where gallium and aluminum are contained as the element M, for example, the sum of the atomic ratio of gallium and the atomic ratio of aluminum can be the atomic ratio of the element M. The atomic ratio of indium to the element M and zinc is preferably within the range given above.

It is preferable to use a metal oxide in which the proportion of the number of indium atoms to the number of atoms of the metal elements contained in the metal oxide is higher than or equal to 30 atomic % and lower than or equal to 100 atomic %, preferably higher than or equal to 30 atomic % and lower than or equal to 95 atomic %, further preferably higher than or equal to 35 atomic % and lower than or equal to 95 atomic %, further preferably higher than or equal to 35 atomic % and lower than or equal to 90 atomic %, further preferably higher than or equal to 40 atomic % and lower than or equal to 90 atomic %, further preferably higher than or equal to 45 atomic % and lower than or equal to 90 atomic %, further preferably higher than or equal to 50 atomic % and lower than or equal to 80 atomic %, further preferably higher than or equal to 60 atomic % and lower than or equal to 80 atomic %, further preferably higher than or equal to 70 atomic % and lower than or equal to 80 atomic %. For example, when an In—Ga—Zn oxide is used for the semiconductor layer, the atomic ratio of indium to the total number of the atoms of indium, the element M, and zinc is preferably within the ranges given above.

In this specification and the like, the proportion of the number of indium atoms to the number of atoms of the metal elements contained is sometimes referred to as indium content. The same applies to other metal elements.

Higher indium content in the metal oxide enables the transistor to have high on-state current. With the use of such a transistor, a circuit capable of high-speed operation can be fabricated. Furthermore, the area occupied by the circuit can be reduced. For example, when the transistor is used in a large display apparatus or a high-definition display apparatus, signal delay in wirings can be reduced and display unevenness can be inhibited even when the number of wirings is increased. In addition, since the area occupied by the circuit can be reduced, the bezel of the display apparatus can be narrowed.

As an analysis method of the composition of a metal oxide, for example, energy dispersive X-ray spectroscopy (EDX), X-ray photoelectron spectroscopy (XPS), inductively coupled plasma-mass spectrometry (ICP-MS), inductively coupled plasma-atomic emission spectroscopy (ICP-AES), or the like can be used. Alternatively, any of these methods may be combined with each other for the analysis. As for an element whose content is low, the actual content may be different from the content obtained by analysis because of the influence of the analysis accuracy. In the case where the content of the element M is low, for example, the content of the element M obtained by analysis may be lower than the actual content.

In this specification and the like, a composition in the vicinity includes ±30% of an intended atomic ratio. For example, in the case of describing an atomic ratio of In:M:Zn=4:2:3 or a composition in the vicinity thereof, the case is included in which with the atomic ratio of indium being 4, the atomic ratio of M is higher than or equal to 1 and lower than or equal to 3 and the atomic ratio of zinc is higher than or equal to 2 and lower than or equal to 4. In the case of describing an atomic ratio of In:M:Zn=5:1:6 or a composition in the vicinity thereof, the case is included in which with the atomic ratio of indium being 5, the atomic ratio of M is higher than 0.1 and lower than or equal to 2 and the atomic ratio of zinc is higher than or equal to 5 and lower than or equal to 7. In the case of describing an atomic ratio of In:M:Zn=1:1:1 or a composition in the vicinity thereof, the case is included in which with the atomic ratio of indium being 1, the atomic ratio of M is higher than 0.1 and lower than or equal to 2 and the atomic ratio of zinc is higher than 0.1 and lower than or equal to 2.

For the formation of a metal oxide, a sputtering method or an atomic layer deposition (ALD) method can be suitably used. Note that in the case where the metal oxide is formed by a sputtering method, the atomic ratio in a target may be different from the atomic ratio in the metal oxide. In particular, the atomic ratio of zinc in the metal oxide may be smaller than the atomic ratio of zinc in the target. Specifically, the metal oxide may have an atomic ratio of zinc of 40% to 90% of the atomic ratio of zinc in the target.

Here, the reliability of a transistor is described. Here, one of indexes for evaluating the reliability of a transistor is a GBT (gate bias-temperature) stress test in which an electric field applied to a gate is retained. Among GBTs, a test in which a state where a positive potential (positive bias) relative to a source potential and a drain potential is supplied to a gate is maintained at high temperatures is referred to as a PBTS (Positive Bias Temperature Stress) test, and a test in which a state where a negative potential (negative bias) is supplied to a gate is maintained at high temperatures is referred to as an NBTS (Negative Bias Temperature Stress) test. The PBTS test and the NBTS test conducted in a state where irradiation is performed are respectively referred to as a PBTIS (Positive Bias Temperature Illumination Stress) test and an NBTIS (Negative Bias Temperature Illumination Stress) test.

In particular, in an n-channel transistor, a positive potential is applied to a gate in putting the transistor in an on state (a state where current flows); thus, the amount of change in threshold voltage in the PBTS test is one important item to be focused on as an indicator of the reliability of the transistor.

With the use of a metal oxide that does not contain gallium or has a low gallium content in the semiconductor layer where the channel of the transistor is formed, the transistor can be highly reliable against positive bias application. In other words, the amount of change in the threshold voltage of the transistor in the PBTS test can be small. In the case of using a metal oxide containing gallium, the gallium content is preferably lower than the indium content. As a result, the transistor can have high reliability.

One of the factors in change in the threshold voltage in the PBTS test is a defect state at the interface between a gate insulating layer and a semiconductor layer where the channel of the transistor is formed or in the vicinity of the interface. As the density of defect states increases, degradation in the PBTS test becomes significant. Generation of a defect state can be inhibited by a reduction in the gallium content in a region of the semiconductor layer where the channel of the transistor is formed, which is in contact with the gate insulating layer.

The following can be given as the reason why the amount of change in the threshold voltage in the PBTS test can be reduced when a metal oxide that does not contain gallium or has a low gallium content is used for the semiconductor layer where the channel of the transistor is formed. Gallium contained in the metal oxide more has a property of attracting oxygen more easily than another metal element (e.g., indium or zinc) does. Therefore, when, at the interface between the metal oxide containing a large amount of gallium and the gate insulating layer, gallium is bonded to excess oxygen in the gate insulating layer, carrier (here, electron) trap sites are likely to be generated easily. This might cause the change in the threshold voltage when a positive potential is supplied to a gate and carriers are trapped at the interface between the semiconductor layer where the channel of the transistor is formed and the gate insulating layer.

Specifically, in the case where an In—Ga—Zn oxide is used for the semiconductor layer where the channel of the transistor is formed, a metal oxide in which the atomic ratio of indium is higher than that of gallium is preferably used. It is further preferable to use a metal oxide in which the atomic ratio of zinc is higher than that of gallium. In other words, a metal oxide with metal elements in an atomic ratio satisfying both relationships In>Ga and Zn>Ga is preferably used for the semiconductor layer where the channel of the transistor is formed.

For example, a metal oxide with metal elements in any of the following atomic ratios can be used for the semiconductor layer where the channel of the OS transistor is formed: In:Ga:Zn=2:1:3, In:Ga:Zn=3:1:2, In:Ga:Zn=4:2:3, In:Ga:Zn=4:2:4.1, In:Ga:Zn=5:1:3, In:Ga:Zn=5:1:6, In:Ga:Zn=5:1:7, In:Ga:Zn=5:1:8, In:Ga:Zn=6:1:6, In:Ga:Zn=10:1:3, In:Ga:Zn=10:1:6, In:Ga:Zn=10:1:7, In:Ga:Zn=10:1:8, In:Ga:Zn=5:2:5, In:Ga:Zn=10:1:10, In:Ga:Zn=20:1:10, In:Ga:Zn=40:1:10, and the vicinity thereof.

In the case where a metal oxide is used for the semiconductor layer where the channel of the OS transistor is formed, the atomic ratio of gallium to the metal elements contained in the metal oxide is higher than 0 atomic % and lower than or equal to 50 atomic %, preferably higher than or equal to 0.1 atomic % and lower than or equal to 40 atomic %, further preferably higher than or equal to 0.1 atomic % and lower than or equal to 35 atomic %, further preferably higher than or equal to 0.1 atomic % and lower than or equal to 30 atomic %, further preferably higher than or equal to 0.1 atomic % and lower than or equal to 25 atomic %, further preferably higher than or equal to 0.1 atomic % and lower than or equal to 20 atomic %, further preferably higher than or equal to 0.1 atomic % and lower than or equal to 15 atomic %, further preferably higher than or equal to 0.1 atomic % and lower than or equal to 10 atomic %. The reduction in the gallium content in the semiconductor layer enables the transistor to be highly resistant to the PBTS test. Note that oxygen vacancies (Vo) are less likely to be generated in the metal oxide when the metal oxide contains gallium.

A metal oxide that does not contain gallium may be used for the semiconductor layer where the channel of the OS transistor is formed. For example, an In—Zn oxide can be used for the semiconductor layer. In this case, when the atomic ratio of indium to the metal elements contained in the metal oxide is increased, the field-effect mobility of the transistor can be increased. By contrast, when the atomic ratio of zinc to the metal elements contained in the metal oxide is increased, the metal oxide has high crystallinity; thus, a change in the electrical characteristics of the transistor can be suppressed and the reliability can be increased. A metal oxide that contains neither gallium nor zinc, such as indium oxide, can be used for the semiconductor layer. The use of a metal oxide that does not contain gallium can make a change in the threshold voltage particularly in the PBTS test extremely small.

For example, an oxide containing indium and zinc can be used for the semiconductor layer where the channel of the OS transistor is formed. At that time, for example, a metal oxide with metal elements in an atomic ratio of In:Zn=2:3, In:Zn=4:1, or the vicinity thereof can be used.

Although the case of using gallium is described as an example, the same applies in the case where the element M is used instead of gallium. A metal oxide that has an atomic ratio of indium higher than that of the element M is preferably used for the semiconductor layer where the channel of the OS transistor is formed. Furthermore, a metal oxide in which the atomic ratio of zinc is higher than that of the element M is preferably used.

With the use of a metal oxide with a low content of the element M for the semiconductor layer where the channel of the OS transistor is formed, the transistor can be highly reliable against positive bias application. With the use of the transistor as a transistor that is required to have high reliability against positive bias application, a highly reliable semiconductor device can be provided.

Next, the reliability of a transistor against light is described.

Light incidence on a transistor may change its electrical characteristics. In particular, a transistor provided in a region on which light can be incident preferably exhibits a small change in electrical characteristics under light irradiation and has high reliability against light. The reliability against light can be evaluated by the amount of change in threshold voltage in a NBTIS test, for example.

The high content of the element M in a metal oxide used for the semiconductor layer where the channel of the transistor is formed enables the transistor to be highly reliable against light. In other words, the amount of change in the threshold voltage of the transistor in the NBTIS test can be small. Specifically, in a metal oxide in which the atomic ratio of the element M is higher than or equal to that of indium, the band gap is increased and accordingly the amount of change in the threshold voltage of the transistor in the NBTIS test can be reduced. The band gap of the metal oxide in the semiconductor layer where the channel of the transistor is formed is preferably greater than or equal to 2.0 eV, further preferably greater than or equal to 2.5 eV, further preferably greater than or equal to 3.0 eV, further preferably greater than or equal to 3.2 eV, further preferably greater than or equal to 3.3 eV, further preferably greater than or equal to 3.4 eV, further preferably greater than or equal to 3.5 eV.

For example, a metal oxide with metal elements in any of the following atomic ratios can be used for the semiconductor layer where the channel of the transistor is formed: In:M:Zn=1:1:1, In:M:Zn=1:1:1.2, In:M:Zn=1:3:2, In:M:Zn=1:3:3, or In:M:Zn=1:3:4, or the vicinity thereof.

For the semiconductor layer where the channel of the transistor is formed, in particular, it is suitable to use a metal oxide in which the atomic ratio of the element M to that of the metal elements contained in the metal oxide is higher than or equal to 20 atomic % and lower than or equal to 70 atomic %, preferably higher than or equal to 30 atomic % and lower than or equal to 70 atomic %, further preferably higher than or equal to 30 atomic % and lower than or equal to 60 atomic %, further preferably higher than or equal to 40 atomic % and lower than or equal to 60 atomic %, further preferably higher than or equal to 50 atomic % and lower than or equal to 60 atomic %.

In the case where an In—Ga—Zn oxide is used for the semiconductor layer where the channel of the transistor is formed, a metal oxide in which the atomic ratio of indium to that of the metal elements is lower than or equal to that of gallium can be used. For example, a metal oxide with metal elements in any of the following atomic ratios can be used: In:Ga:Zn=1:1:1, In:Ga:Zn=1:1:1.2, In:Ga:Zn=1:3:2, In:Ga:Zn=1:3:3, In:Ga:Zn=1:3:4, or the vicinity thereof.

For the semiconductor layer where the channel of the transistor is formed, in particular, it is suitable to use a metal oxide in which the atomic ratio of gallium to that of the metal elements contained in the metal oxide is higher than or equal to 20 atomic % and lower than or equal to 60 atomic %, preferably higher than or equal to 30 atomic % and lower than or equal to 60 atomic %, further preferably higher than or equal to 40 atomic % and lower than or equal to 60 atomic %, further preferably higher than or equal to 50 atomic % and lower than or equal to 60 atomic %.

With the use of a metal oxide with a high content of the element M for the semiconductor layer where the channel of the transistor is formed, the transistor can be highly reliable against light. With the use of the transistor as a transistor that is required to have high reliability against light, a highly reliable semiconductor device can be provided.

As described above, electrical characteristics and reliability of a transistor depend on the composition of the metal oxide used for the semiconductor layer where the channel of the transistor is formed. Thus, the composition of the metal oxide is varied according to the electrical characteristics and reliability required for the transistor so that a display apparatus can achieve both excellent electrical characteristics and high reliability.

The semiconductor layer where the channel of the transistor is formed may have a stacked structure of two or more metal oxide layers. The two or more metal oxide layers included in the semiconductor layer may have the same composition or substantially the same compositions. Employing a stacked-layer structure of metal oxide layers having the same composition can reduce the manufacturing cost because the metal oxide layers can be formed using the same sputtering target.

The two or more metal oxide layers in the semiconductor layer where the channel of the transistor is formed may have different compositions. For example, a stacked-layer structure of a first metal oxide layer having an atomic ratio of In:M:Zn=1:3:4 or a composition in the vicinity thereof and a second metal oxide layer having an atomic ratio of In:M:Zn=1:1:1 or a composition in the vicinity thereof and being formed over the first metal oxide layer can be suitably employed. In particular, gallium or aluminum is preferably used as the element M. A stacked structure of one selected from indium oxide, indium gallium oxide, and IGZO, and one selected from IAZO, IAGZO, and ITZO (registered trademark) may be employed, for example.

A metal oxide having crystallinity is preferably used for the semiconductor layer in which the channel of the transistor is formed. For example, a metal oxide layer having a CAAC (c-axis aligned crystal) structure, a polycrystalline structure, a nc (nano-crystal) structure, or the like can be used. By using a metal oxide layer having crystallinity for the semiconductor layer, the density of defect states in the semiconductor layer can be reduced, which enables the display apparatus to have high reliability.

As the metal oxide layer used for the semiconductor layer where the channel of the transistor is formed has higher crystallinity, the density of defect states in the semiconductor layer can be lower. In contrast, with the use of a metal oxide layer having low crystallinity, a large amount of current can flow through the transistor.

In the case where the metal oxide layer is formed by a sputtering method, the higher the substrate temperature (the stage temperature) in the formation is, the higher the crystallinity of the metal oxide layer can be. The crystallinity of the metal oxide layer can be increased as the proportion of a flow rate of an oxygen gas to the whole formation gas (also referred to as oxygen flow rate ratio) used in formation is higher.

The semiconductor layer where the channel of the OS transistor is formed may have a stacked structure of two or more metal oxide layers having different crystallinities. For example, a stacked-layer structure of a first metal oxide layer and a second metal oxide layer over the first metal oxide layer can be employed; the second metal oxide layer can include a region having higher crystallinity than the first metal oxide layer. Alternatively, the second metal oxide layer can include a region having lower crystallinity than the first metal oxide layer. The two or more metal oxide layers included in the semiconductor layer may have the same composition or substantially the same compositions. Employing a stacked-layer structure of metal oxide layers having the same composition can reduce the manufacturing cost because the metal oxide layers can be formed using the same sputtering target. For example, with use of the same sputtering target and different oxygen flow rate ratios, a stacked-layer structure of two or more metal oxide layers having different crystallinities can be formed. Note that the two or more metal oxide layers included in the semiconductor layer may have different compositions.

Modification examples of the above structure example are described below. Note that in some cases, the above description is referred to for the portions already described and the description thereof is omitted.

### Modification Example 1

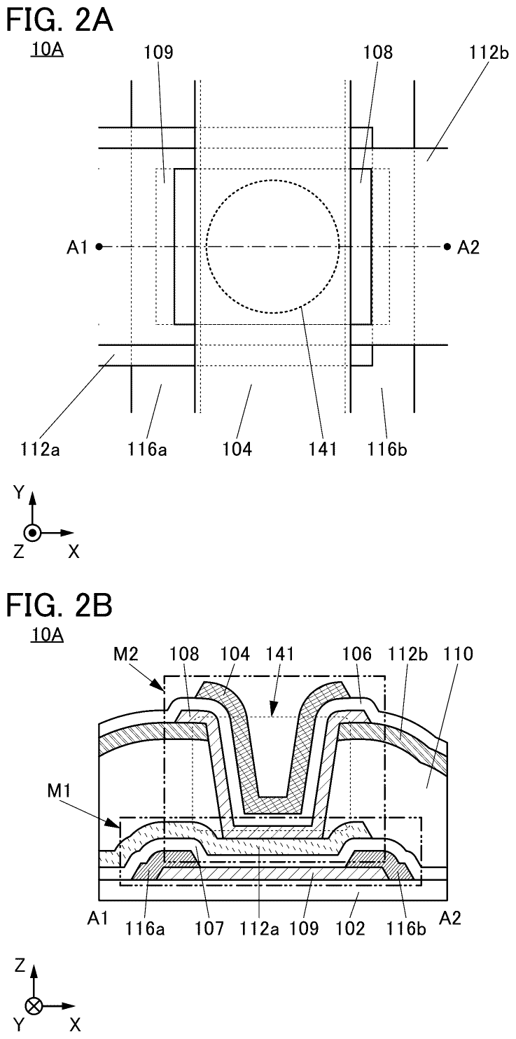

A semiconductor device 10A illustrated in FIG. 2A and FIG. 2B is different from the semiconductor device 10 illustrated in FIG. 1A and FIG. 1B in that the transistor M2 is provided to be over and overlap with the transistor M1.

As illustrated in FIG. 2B, in the semiconductor device 10A, the bottom surface of the semiconductor layer 108, which functions as the semiconductor layer where the channel of the transistor M2 is formed, is in contact with the top surface of the conductive layer 112a, which functions as the gate electrode of the transistor M1.

In the semiconductor device 10A, the conductive layer 112a functions as the gate electrode of the transistor M1 and also as one of the source electrode and the drain electrode of the transistor M2. In other words, the gate electrode of the transistor M1 is electrically connected to the one of the source electrode and the drain electrode of the transistor M2 in the semiconductor device 10A.

As illustrated in FIG. 2A, in the semiconductor device 10A, the semiconductor layer 109, which functions as the semiconductor layer where the channel of the transistor M1 is formed, and the semiconductor layer 108, which functions as the semiconductor layer where the channel of the transistor M2 is formed, overlap with each other.

The transistors with the above-described structure can be arranged with high density in the semiconductor device. The area in a substrate plane occupied by the semiconductor device 10A can be smaller than the area occupied by the semiconductor device 10 illustrated in FIG. 1A and FIG. 1B. Thus, a semiconductor device having a high degree of integration can be provided.

### Modification Example 2

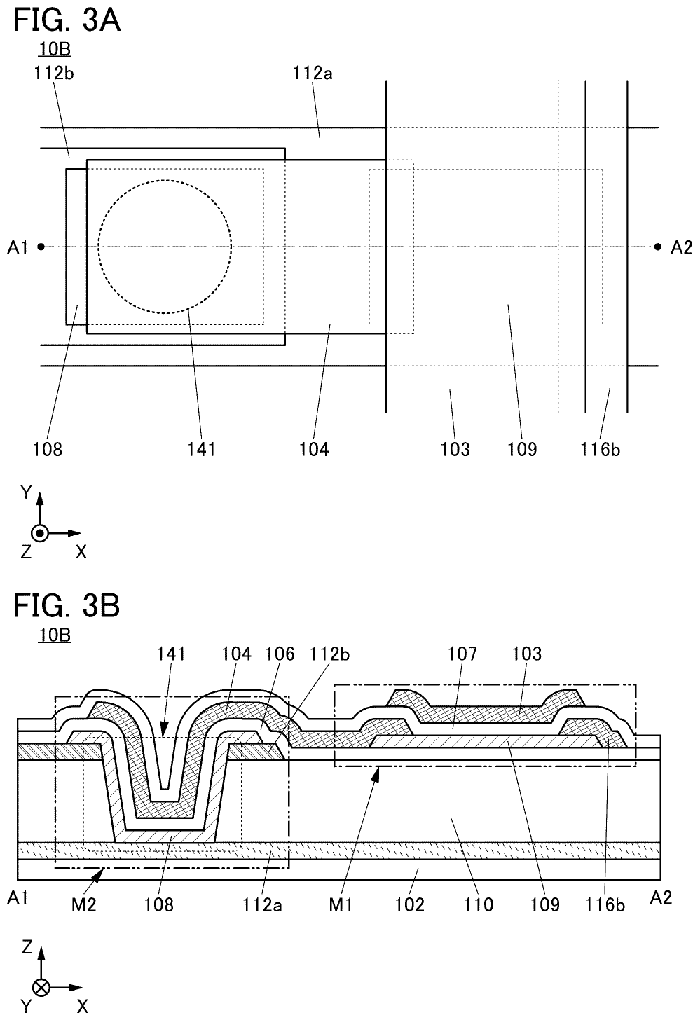

A semiconductor device 10B illustrated in FIG. 3A and FIG. 3B is different from the semiconductor device 10 illustrated in FIG. 1A and FIG. 1B in the structure of the gate electrode of the transistor M1, the structure of one of the source electrode and the drain electrode of the transistor M1, and the structure of the gate electrode of the transistor M2.

As illustrated in FIG. 3B, in the semiconductor device 10B, one end portion of the conductive layer 104, which functions as the gate electrode of the transistor M2, is extended to the transistor M1 and covers the one side end portion of the semiconductor layer 109, which functions as the semiconductor layer where the channel of the transistor M1 is formed. In addition, the insulating layer 106 functioning as the gate insulating layer of the transistor M2 is extended to the transistor M1, and placed below the semiconductor layer 109 functioning as the semiconductor layer where the channel of the transistor M1 is formed, and the conductive layer 116b functioning as the other of the gate electrode and the drain electrode of the transistor M1.

In the semiconductor device 10B, a conductive layer 103 functions as the gate electrode of the transistor M1. Furthermore, the conductive layer 104 functions as the one of the source electrode and the drain electrode of the transistor M1 and also as the gate electrode of the transistor M2. Thus, in the semiconductor device 10B, one of the source electrode and the drain electrode of the transistor M1 are electrically connected to the gate electrode of the transistor M2. In other words, the transistor M1 in the semiconductor device 10B corresponds to the transistor M2 of the semiconductor device 10, and the transistor M2 in the semiconductor device 10B corresponds to the transistor M1 in the semiconductor device 10. With this structure, the effect similar to that obtained with the semiconductor device 10 can be obtained.

### Modification Example 3

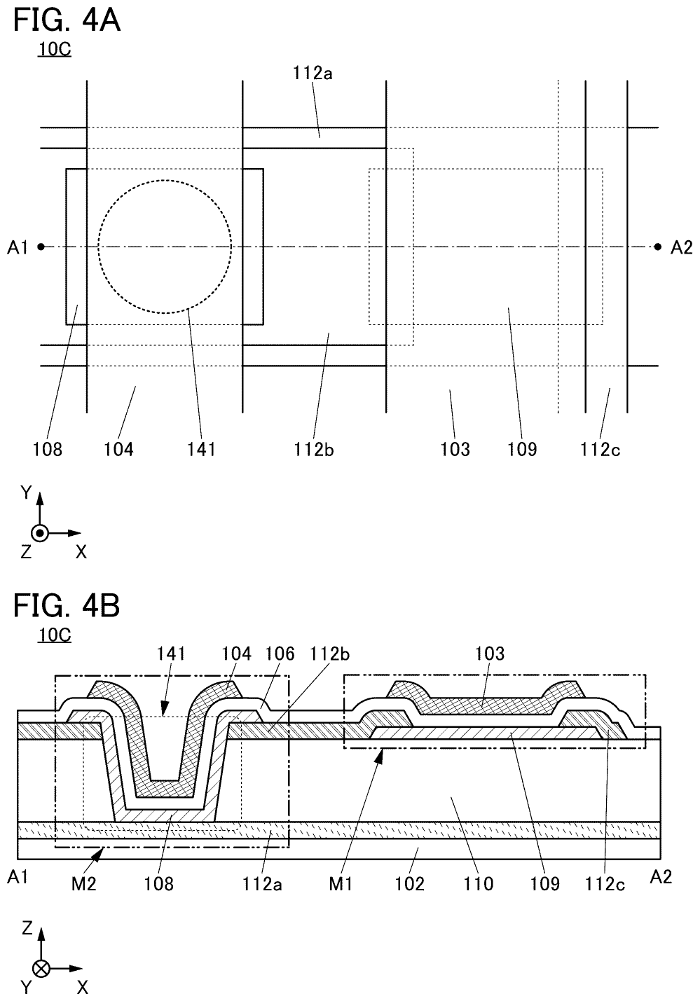

A semiconductor device 10C illustrated in FIG. 4A and FIG. 4B is different from the semiconductor device 10 illustrated in FIG. 1A and FIG. 1B in the structure of the gate electrode of the transistor M1, the structure of the one of the source electrode and the drain electrode of the transistor M1, the structure of the other of the source electrode and the drain electrode of the transistor M2, and the structure of the gate insulating layer of the transistor M2.

As illustrated in FIG. 4B, in the semiconductor device 10C, the conductive layer 112b, which functions as the one of the source electrode and the drain electrode of the transistor M1, is extended to the transistor M2 and in contact with the bottom surface of the semiconductor layer 108, which functions as the semiconductor layer where the channel of the transistor M2 is formed. In addition, the insulating layer 106 functioning as the gate insulating layer of the transistor M2 is extended to the transistor M1, and covers the conductive layer 112b, the semiconductor layer 109 functioning as the semiconductor layer where the channel of the transistor M1 is formed, and a conductive layer 112c functioning as the other of the source electrode and the drain electrode of the transistor M1.

In the semiconductor device 10C, the conductive layer 103 functions as the gate electrode of the transistor M1. Furthermore, the conductive layer 112b functions as the one of the source electrode and the drain electrode of the transistor M1 and also as the other of the source electrode and the drain electrode of the transistor M2. Thus, in the semiconductor device 10C, the one of the source electrode and the drain electrode of the transistor M1 and the other of the source electrode and the drain electrode of the transistor M2 are electrically connected to each other. The conductive layer 112c has functions as the other of the source electrode and the drain electrode of the transistor M1. The insulating layer 106 functions as the gate insulating layer of the transistor M1 and also as the gate insulating layer of the transistor M2. With this structure, the effect similar to that obtained with the semiconductor device 10 can be obtained. The number of fabrication steps can be reduced by not including the insulating layer 107 of the semiconductor device 10.

### Modification Example 4

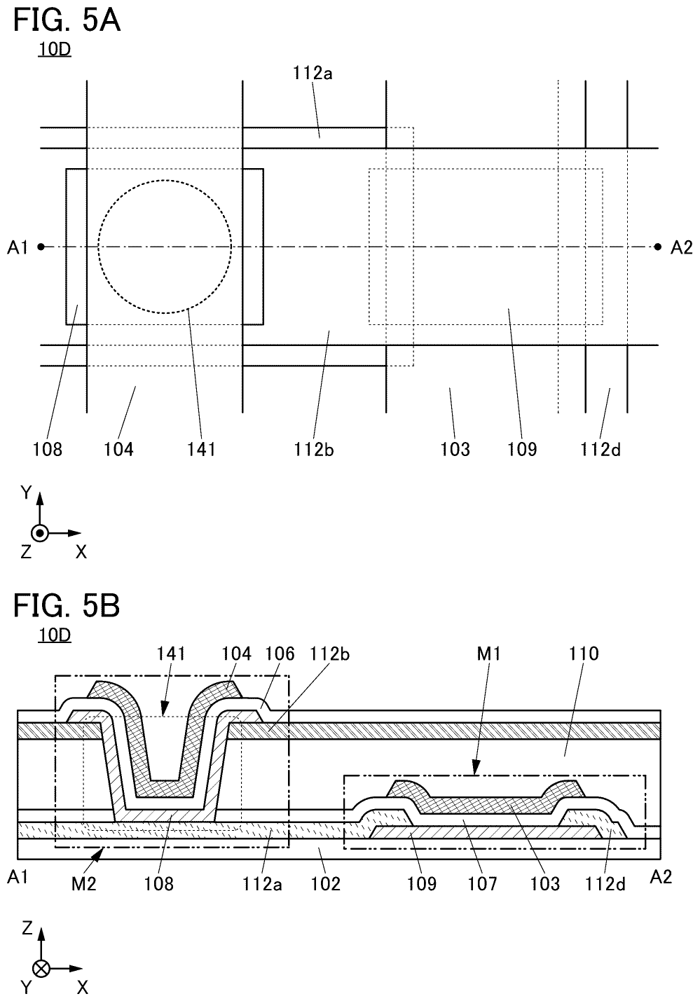

A semiconductor device 10D illustrated in FIG. 5A and FIG. 5B is different from the semiconductor device 10 illustrated in FIG. 1A and FIG. 1B in the structures of the gate electrode of the transistor M1, the structure of the one of the source electrode and the drain electrode of the transistor M1, and the structure of the other of the source electrode and the drain electrode of the transistor M2.

In the semiconductor device 10D, the conductive layer 103 functions as the gate electrode of the transistor M1. Furthermore, the conductive layer 112a functions as the one of the source electrode and the drain electrode of the transistor M1 and also as the one of the source electrode and the drain electrode of the transistor M2. A conductive layer 112d functions as the other of the source electrode and the drain electrode of the transistor M1. The conductive layer 112b functions as the other of the source electrode and the drain electrode of the transistor M2. The conductive layer 112b is provided to extend over the transistor M1 with the insulating layer 110 interposed therebetween. Thus, in the semiconductor device 10D, the one of the source electrode and the drain electrode of the transistor M1 is electrically connected to the one of the source electrode and the drain electrode of the transistor M2. With this structure, the effect similar to that obtained with the semiconductor device 10 can be obtained.

### Modification Example 5

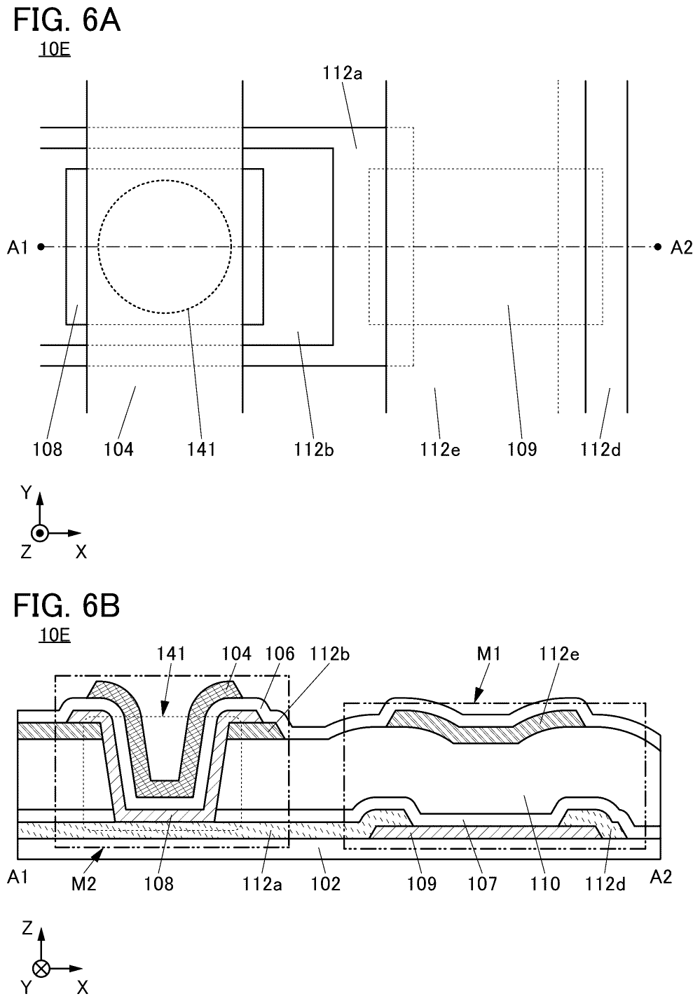

A semiconductor device 10E illustrated in FIG. 6A and FIG. 6B is different from the semiconductor device 10 illustrated in FIG. 1A and FIG. 1B in the structures of the gate electrode of the transistor M1, the gate insulating layer of the transistor M1, the structure of the one of the source electrode and the drain electrode of the transistor M1, the structure of the one of the source electrode and the drain electrode of the transistor M2, and the structure of the other of the source electrode and the drain electrode of the transistor M2.

In the semiconductor device 10E, a conductive layer 112e functions as the gate electrode of the transistor M1. In addition, the insulating layer 107 and the insulating layer 110 function as the gate insulating layer of the transistor M1. Furthermore, the conductive layer 112a functions as the one of the source electrode and the drain electrode of the transistor M1 and also as the one of the source electrode and the drain electrode of the transistor M2. The conductive layer 112d functions as the other of the source electrode and the drain electrode of the transistor M1. The conductive layer 112b functions as the other of the source electrode and the drain electrode of the transistor M2. Thus, the thickness of the gate insulating layer of the transistor M1 in the semiconductor device 10E is larger than the thickness of the gate insulating layer of the transistor M1 in the semiconductor device 10. The one of the source electrode and the drain electrode of the transistor M1 is electrically connected to the one of the source electrode and the drain electrode of the transistor M2. With this structure, the effect similar to that obtained with the semiconductor device 10 can be obtained.

### Modification Example 6

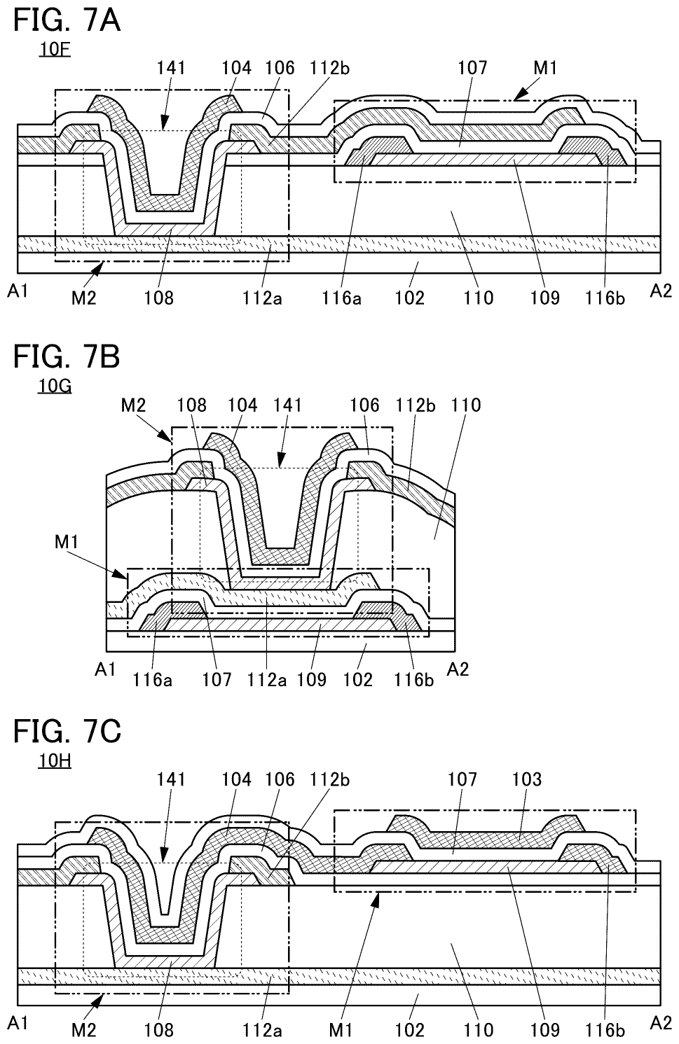

A semiconductor device 10F illustrated in FIG. 7A is different from the semiconductor device 10 illustrated in FIG. 1A and FIG. 1B in that the other of the source electrode and the drain electrode (conductive layer 112b) of the transistor M2 is in contact with a top surface of the semiconductor layer (semiconductor layer 108) where the channel of the transistor M2 is formed, and that the bottom surface of the semiconductor layer is in contact with the top surface of the gate insulating layer (insulating layer 107) of the transistor M1. The other components are similar to those in the semiconductor device 10. With this structure, the effect similar to that obtained with the semiconductor device 10 can be obtained.

### Modification Example 7

A semiconductor device 10G illustrated in FIG. 7B is different from the semiconductor device 10A illustrated in FIG. 2A and FIG. 2B in that the other of the source electrode and the drain electrode (conductive layer 112b) of the transistor M2 is in contact with the top surface of the semiconductor layer (semiconductor layer 108) where the channel of the transistor M2 is formed. The other components are similar to those in the semiconductor device 10A. With this structure, the effect similar to that obtained with the semiconductor device 10A can be obtained.

### Modification Example 8

A semiconductor device 10H illustrated in FIG. 7C is different from the semiconductor device 10B illustrated in FIG. 3A and FIG. 3B in that the other of the source electrode and the drain electrode (conductive layer 112b) of the transistor M2 is in contact with the top surface of the semiconductor layer (semiconductor layer 108) where the channel of the transistor M2 is formed. The other components are similar to those in the semiconductor device 10B. With this structure, the effect similar to that obtained with the semiconductor device 10B can be obtained.

### Modification Example 9

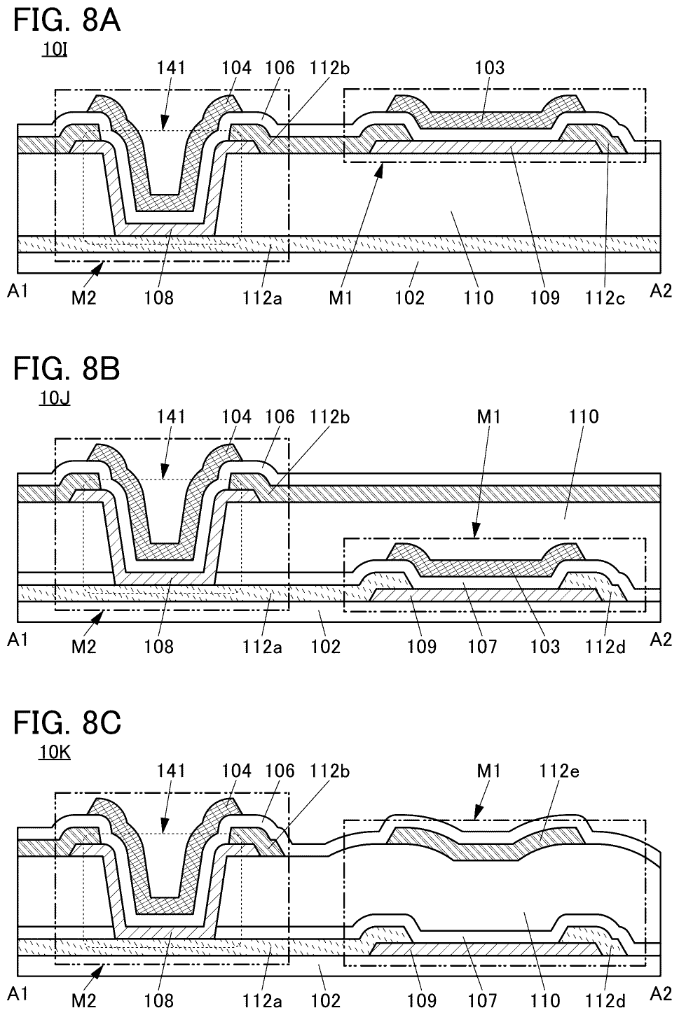

A semiconductor device 10I illustrated in FIG. 8A is different from the semiconductor device 10C illustrated in FIG. 4A and FIG. 4B in that the other of the source electrode and the drain electrode (conductive layer 112b) of the transistor M2 is in contact with the top surface of the semiconductor layer (semiconductor layer 108) where the channel of the transistor M2 is formed. The other components are similar to those in the semiconductor device 10C. With this structure, the effect similar to that obtained with the semiconductor device 10C can be obtained.

### Modification Example 10

A semiconductor device 10J illustrated in FIG. 8B is different from the semiconductor device 10D illustrated in FIG. 5A and FIG. 5B in that the other of the source electrode and the drain electrode (conductive layer 112b) of the transistor M2 is in contact with the top surface of the semiconductor layer (semiconductor layer 108) where the channel of the transistor M2 is formed. The other components are similar to those in the semiconductor device 10D. With this structure, the effect similar to that obtained with the semiconductor device 10D can be obtained.

### Modification Example 11

A semiconductor device 10K illustrated in FIG. 8C is different from the semiconductor device 10E illustrated in FIG. 6A and FIG. 6B in that the other of the source electrode and the drain electrode (conductive layer 112b) of the transistor M2 is in contact with the top surface of the semiconductor layer (semiconductor layer 108) where the channel of the transistor M2 is formed. The other components are similar to those in the semiconductor device 10E. With this structure, the effect similar to that obtained with the semiconductor device 10E can be obtained.

### Fabrication Method Example

Next, an example of a method for fabricating the semiconductor device 10 is described below. First, materials of the layers and formation methods of the layers are described.

### [Method for Forming Layers]

The insulating layers, the semiconductor layers, the conductive layers that form electrodes or wirings, and the like can be formed by any of a sputtering method, a CVD method, a vacuum evaporation method, a pulsed laser deposition (PLD) method, an ALD method, and the like. As the CVD method, a plasma-enhanced CVD (PECVD) method or a thermal CVD method may be used. As an example of thermal CVD method, a Metal Organic CVD (MOCVD) method may be used.

Insulating layers, semiconductor layers, conductive layers, and the like included in the semiconductor device may be formed by a method such as spin coating, dipping, spray coating, ink jetting, dispensing, screen printing, offset printing, slit coating, roll coating, curtain coating, or knife coating.

A high-quality film can be obtained at a relatively low temperature through a PECVD method. With the use of a film deposition method that does not use plasma at the time of film deposition such as an MOCVD method, an ALD method, or a thermal CVD method, the formation surface is not easily damaged. A wiring, an electrode, an element (e.g., a transistor or a capacitor), or the like included in a semiconductor device might be charged up by receiving charges from plasma, for example. In that case, accumulated charges might break the wiring, electrode, element, or the like included in the semiconductor device. Conversely, such plasma damage is not caused in the case of using a deposition method that does not use plasma, and thus the yield of a semiconductor device can be increased. Furthermore, as there is no plasma damage during deposition, a film with few defects can be obtained.

Unlike a deposition method in which particles ejected from a target or the like are deposited, a CVD method and an ALD method are deposition methods in which a film is formed by reaction at a surface of an object. Thus, a CVD method and an ALD method can provide good step coverage, almost regardless of the shape of an object to be processed. In particular, an ALD method allows excellent step coverage and excellent thickness uniformity and can be suitably used to cover a surface of an opening portion with a high aspect ratio, for example. Note that an ALD method has a relatively low deposition rate; hence, in some cases, an ALD method is preferably combined with another deposition method with a high deposition rate, such as a CVD method.

A CVD method or an ALD method enables control of composition of a film to be obtained with a flow rate ratio of the source gases. For example, in a CVD method or an ALD method, a film with a desired composition can be deposited by adjusting the flow ratio of the source gases. Moreover, by a CVD method or an ALD method, by changing the flow ratio of the source gases during the deposition, a film whose composition is continuously changed can be deposited. In the case where the film is formed while changing the flow rate ratio of the source gases, as compared to the case where the film is formed using a plurality of deposition chambers, time taken for the whole film formation process can be reduced because time taken for transfer and pressure adjustment is omitted. Hence, the productivity of the semiconductor device can be improved in some cases.

When layers (thin films) included in the semiconductor device are processed, a photolithography method or the like can be used for the processing. Alternatively, island-shaped layers may be formed by a deposition method using a blocking mask. Alternatively, a nanoimprinting method, a sandblasting method, a lift-off method, or the like may be used for the processing of the layers. Examples of the photolithography method include a method in which a resist mask is formed over a layer (thin film) to be processed, part of the layer (thin film) is selectively removed using the resist mask as a mask, after which the resist mask is removed, and a method in which a photosensitive layer is formed and then exposed to light and developed to be processed into a desired shape.

In the case of using light in a photolithography method, an i-line (a wavelength of 365 nm), a g-line (a wavelength of 436 nm), and an h-line (a wavelength of 405 nm), or light combining any of them can be used for light exposure. Ultraviolet light, KrF laser light, ArF laser light, or the like can also be used. Light exposure may be performed by liquid immersion exposure technique. Furthermore, as the light used for the light exposure, Extreme Ultra-violet (EUV) light or X-rays may be used. Furthermore, instead of the light for exposure, an electron beam can be used. It is preferable to use extreme ultraviolet light, X-rays, or an electron beam to perform extremely minute processing. Note that a photomask is not needed when light exposure is performed by scanning with a beam such as an electron beam.

For removal (etching) of the layers (thin films), a dry etching method, a wet etching method, a sandblasting method, or the like can be used. These etching methods may be employed in combination.

An example of a method for fabricating the semiconductor device 10 is described below.

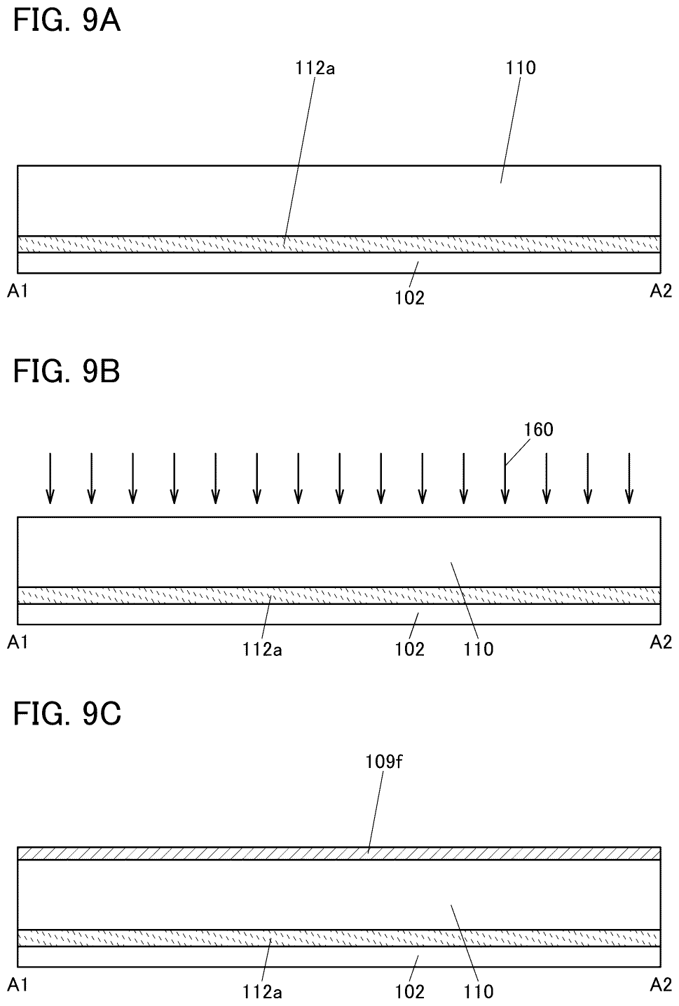

First, the conductive layer 112a is formed over the substrate 102, and the insulating layer 110 is formed over the conductive layer 112a (see FIG. 9A).

As the substrate 102, for example, an insulator substrate having an insulating surface is used. Examples of the insulator substrate include a glass substrate, a quartz substrate, a sapphire substrate, a stabilized zirconia substrate (e.g., an yttria-stabilized zirconia substrate), and a resin substrate.

A semiconductor substrate or a conductor substrate may be used as the substrate 102, as needed. Examples of the semiconductor substrate include a semiconductor substrate of silicon, germanium, or the like and a compound semiconductor substrate of silicon carbide, silicon germanium, gallium arsenide, indium phosphide, zinc oxide, or gallium oxide. Another example is a semiconductor substrate having an insulator region in the semiconductor substrate described above, e.g., an SOI (Silicon On Insulator) substrate. Examples of the conductor substrate include a graphite substrate, a metal substrate, an alloy substrate, and a conductive resin substrate. Other examples include a substrate containing a nitride of a metal, a substrate including an oxide of a metal. Moreover, an insulator substrate provided with a conductor or a semiconductor, a semiconductor substrate provided with a conductor or an insulator, and a conductor substrate provided with a semiconductor or an insulator. Alternatively, any of these substrates provided with an element may be used. Examples of the elements provided over the substrates include a capacitor, a resistor, a switching element, a light-emitting element, and a memory element.

A conductive film to be the conductive layer 112a can be formed with the above-described material by a sputtering method, for example. A resist mask (not illustrated) is formed over the conductive film by a photolithography process, and then the conductive film is processed, whereby the conductive layer 112a to be the one of the source electrode and the drain electrode of the transistor M2 later is formed. For processing of the conductive film, one or both of a wet etching method and a dry etching method can be used.

When the conductive layer 112a having a function of the one of the source electrode and the drain electrode of the transistor M2 is intended also to have a function of a wiring, a material with low electric resistance is preferably used to form the wiring. That is, the conductive layer 112a is preferably formed using a material with low electric resistance. Alternatively, a conductive layer formed using a material whose electric resistance is lower than that of the conductive layer 112a is preferably provided over or under the conductive layer 112a.

For example, preferably, a conductive oxide material is used for the conductive layer 112a, and a metal, an alloy, or a nitride thereof that can be used for the conductive layer 104 or the like described above is used for the conductive layer provided over or under the conductive layer 112a. When a conductive layer whose electric resistance is lower than that of the conductive layer 112a is in contact with the conductive layer 112a, the wiring resistance of the conductive layer 112a used as a wiring can be reduced.

The insulating layer 110 can be formed with the above-described material by a PECVD method, for example. The insulating layer 110 may have a stacked structure of two or more layers. The insulating layer 110 with this structure is preferably formed successively in vacuum without exposure of the surfaces of the layers to the air. Such formation can inhibit attachment of atmospherically derived impurities to the surfaces of the layers. Examples of the impurities include water and organic substances.

The substrate temperature at the time of forming the insulating layer 110 is preferably higher than or equal to 180° C. and lower than or equal to 450° C., further preferably higher than or equal to 200° C. and lower than or equal to 450° C., further preferably higher than or equal to 250° C. and lower than or equal to 450° C., further preferably higher than or equal to 300° C. and lower than or equal to 450° C., further preferably higher than or equal to 300° C. and lower than or equal to 400° C., further preferably higher than or equal to 350° C. and lower than or equal to 400° C. With the substrate temperature at the time of forming the insulating layer 110 in the above range, impurities (e.g., water and hydrogen) released from the insulating layer 110 itself can be decreased, which inhibits the diffusion of the impurities to the semiconductor layer 109 formed later. Consequently, a semiconductor device with favorable electrical characteristics and high reliability can be provided.

Since the formation of the insulating layer 110 precedes the formation of the semiconductor layer 109, heat applied in the formation of the insulating layer 110 is unlikely to cause the release of oxygen from the semiconductor layer 109.

Heat treatment may be performed after the insulating layer 110 is formed. By the heat treatment, water and hydrogen can be released from the surface and inside of the insulating layer 110.

The heat treatment temperature is preferably higher than or equal to 150° C. and lower than the strain point of the substrate, further preferably higher than or equal to 200° C. and lower than or equal to 450° C., further preferably higher than or equal to 250° C. and lower than or equal to 450° C., further preferably higher than or equal to 300° C. and lower than or equal to 450° C., further preferably higher than or equal to 300° C. and lower than or equal to 400° C., further preferably higher than or equal to 350° C. and lower than or equal to 400° C. The heat treatment can be performed in an atmosphere containing one or more of a rare gas, nitrogen, and oxygen. As a nitrogen-containing atmosphere or an oxygen-containing atmosphere, clean dry air (CDA) may be used. Note that the content of hydrogen, water, or the like in the atmosphere is preferably as low as possible. As the atmosphere, a high-purity gas with a dew point of −60° C. or lower, preferably −100° C. or lower is preferably used. With the use of an atmosphere where the content of hydrogen, water, or the like is as low as possible, entry of hydrogen, water, and the like into the insulating layer 110 can be prevented as much as possible. An oven, a rapid thermal annealing (RTA) apparatus, or the like can be used for the heat treatment. With the RTA apparatus, the heat treatment time can be shortened.

Next, treatment for supplying oxygen 160 to the insulating layer 110 is performed (see FIG. 9B). Examples of the oxygen 160 include an oxygen radical, an oxygen atom, an oxygen atomic ion, and an oxygen molecular ion. The oxygen 160 can be supplied by, for example, an ion implantation method, an ion doping method, a plasma immersion ion implantation method, plasma treatment, or the like.

For the plasma treatment, an apparatus with which an oxygen gas is made to be plasma by high-frequency power (also referred to as a plasma etching apparatus or a plasma ashing apparatus) is suitably used. For example, plasma treatment in an atmosphere containing oxygen may be performed. Alternatively, oxygen may be supplied to the insulating layer 110 by plasma treatment in an atmosphere containing an oxidizing gas such as dinitrogen monoxide (N₂O). When plasma treatment is performed using a dinitrogen monoxide gas, an organic substance on the surface of the insulating layer 110 can be suitably removed and oxygen can be supplied to the insulating layer 110.

Next, a metal oxide film 109f to be the semiconductor layer 109 later is formed over the insulating layer 110 (see FIG. 9C). The metal oxide film 109f is preferably formed by a sputtering method using a metal oxide target.

The metal oxide film 109f is preferably a dense film with as few defects as possible. The metal oxide film 109f is preferably a highly purified film in which impurities containing hydrogen elements are reduced as much as possible. It is particularly preferable to use a metal oxide film having crystallinity as the metal oxide film 109f.

In forming the metal oxide film 109f, an oxygen gas is preferably used. For example, in the case of using an oxygen gas at the time of forming the metal oxide film 109f, oxygen can be suitably supplied to the insulating layer 110.

By the supply of oxygen to the insulating layer 110, oxygen is supplied to the semiconductor layer 109 in a later step, so that oxygen vacancies (Vo) and defects in which hydrogen has entered an oxygen vacancy (hereinafter, also referred to as VoH) in the semiconductor layer 109 can be reduced.

In forming the metal oxide film 109f, an oxygen gas and an inert gas (such as a helium gas, an argon gas, or a xenon gas) may be mixed. The higher the proportion of the oxygen gas in the whole formation gas (oxygen flow rate ratio) is in forming the metal oxide film 109f, the higher the crystallinity of the metal oxide film 109f can be, achieving the highly reliable transistor M1. By contrast, the lower the oxygen flow rate ratio is, the lower the crystallinity of the metal oxide film 109f is, offering the transistor M1 with increased on-state current.

In forming the metal oxide film 109f, as the substrate temperature becomes higher, the denser metal oxide film 109f having higher crystallinity can be formed. On the other hand, as the substrate temperature becomes lower, the metal oxide film 109f having lower crystallinity and higher electric conductivity can be formed.

The metal oxide film 109f is formed at a substrate temperature higher than or equal to room temperature and lower than or equal to 250° C., preferably higher than or equal to room temperature and lower than or equal to 200° C., further preferably higher than or equal to room temperature and lower than or equal to 140° C. For example, when the substrate temperature is higher than or equal to room temperature and lower than or equal to 140° C., high productivity is achieved, which is preferable. When the metal oxide film 109f is formed at a substrate temperature set to room temperature or without heating the substrate, the metal oxide film 109f can have low crystallinity.

In the case where the semiconductor layer 109 has a stacked-layer structure, an upper metal oxide film is preferably formed successively after the formation of a lower metal oxide film without exposure of the surface of the lower metal oxide film to the air.

Heat treatment may be performed after the formation of the metal oxide film 109f. By the heat treatment, water or hydrogen can be released from the surface and inside of the metal oxide film 109f. By the heat treatment, oxygen can also be supplied from the insulating layer 110 to the metal oxide film 109f. Furthermore, the film quality of the metal oxide film 109f is improved (e.g., the number of defects is reduced or crystallinity is increased) by the heat treatment in some cases. For the heat treatment, the conditions for the above heat treatment that can be used after the formation of the insulating layer 110 can be used.

Note that the heat treatment is not necessarily performed. The heat treatment is not necessarily performed in this step, and heat treatment performed in a later step may also serve as the heat treatment in this step. In some cases, treatment at a high temperature (e.g., film formation step) or the like in a later step can serve as the heat treatment in this step.

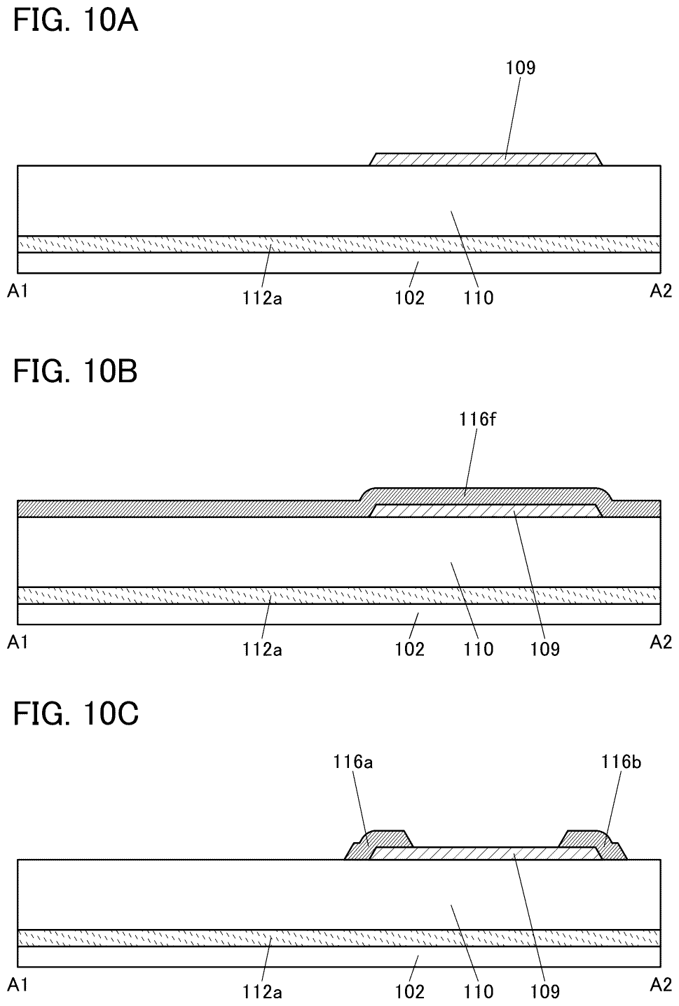

Next, the metal oxide film 109f is processed into an island shape to form the semiconductor layer 109 (see FIG. 10A).

For the formation of the semiconductor layer 109, either one or both of a wet etching method and a dry etching method can be used. For example, a wet etching method can be suitably used to form the semiconductor layer 109. At this time, part of the insulating layer 110 in the region that does not overlap with the semiconductor layer 109 is etched and thinned in some cases. Note that in the etching of the metal oxide film 109f, the reduction in the thickness of the insulating layer 110 can be inhibited when a material having a high etching selectivity is used for the insulating layer 110.

Then, a conductive film 116f to be the conductive layer 116a and the conductive layer 116b later is formed over the semiconductor layer 109 and the insulating layer 110 (see FIG. 10B). The conductive film 116f can be formed with the above-described material by a sputtering method, for example.

Next, a resist mask (not illustrated) is formed over the conductive film 116f by a photolithography process, and then the conductive film is processed, whereby the conductive layer 116a and the conductive layer 116b, which each cover the side surface and part of the top surface of the semiconductor layer 109, are formed (see FIG. 10C). The conductive layer 116a and the conductive layer 116b are conductive layers to be the source electrode and the drain electrode of the transistor M1 later. For the formation of the conductive layer 116a and the conductive layer 116b, either one or both of a wet etching method and a dry etching method can be used. For example, a wet etching method can be suitably used for formation of the conductive layer 116a and the conductive layer 116b.

Note that at the time of forming the conductive layer 116a and the conductive layer 116b, the thickness of the semiconductor layer 109 in the region overlapping with neither the conductive layer 116a nor the conductive layer 116b is sometimes smaller than the thickness of semiconductive layer 109 in the region overlapping with the conductive layer 116a and the conductive layer 116b. In addition, the thickness of the insulating layer 110 in the region overlapping with neither the conductive layer 116a nor the conductive layer 116b is sometimes smaller than the thickness of the insulating layer 110 in the region overlapping with the conductive layer 116a and the conductive layer 116b.

After the conductive layer 116a and the conductive layer 116b are formed, cleaning treatment may be performed. As the cleaning treatment, wet cleaning using a cleaning solution or the like or cleaning by plasma treatment using plasma can be employed. Such cleaning methods may be performed in combination as appropriate.

The surface of the semiconductor layer 109 might be damaged at the time of forming the conductive layer 116a and the conductive layer 116b. In some cases, Vo is formed in the damaged semiconductor layer 109 and VoH is further formed. The damaged layer can be removed by performing the cleaning treatment after the formation of the conductive layer 116a and the conductive layer 116b. By performing the cleaning treatment, impurities (e.g., metal and an organic substance) attached on the surface of the semiconductor layer 109 at the time of forming the conductive layer 116a and the conductive layer 116b can be removed.

For the wet cleaning, for example, a cleaning solution containing one or more of phosphoric acid, oxalic acid, and hydrochloric acid can be used. A cleaning solution containing phosphoric acid is suitably used for the wet cleaning. The concentration of a cleaning solution is preferably determined in consideration of the etching rate of the semiconductor layer 109. For example, in the case where a cleaning solution containing phosphoric acid is used, the concentration of phosphoric acid is preferably higher than or equal to 0.01 weight % and lower than or equal to 5 weight %, further preferably higher than or equal to 0.02 weight % and lower than or equal to 4 weight %, still further preferably higher than or equal to 0.05 weight % and lower than or equal to 3 weight %, yet further preferably higher than or equal to 0.1 weight % and lower than or equal to 2 weight %, yet still further preferably higher than or equal to 0.15 weight % and lower than or equal to 1 weight %. With the concentration in the above range, the semiconductor layer 109 can be inhibited from being lost, and the damaged layer in the semiconductor layer 109 and impurities (e.g., a metal and an organic substance) attached to the semiconductor layer 109 can be efficiently removed.

For the plasma treatment, for example, a gas containing one or more of oxygen, ozone, nitrogen, dinitrogen monoxide (N₂O), and argon can be used. An oxygen-containing gas is preferably used for the plasma treatment. In particular, with the use of a gas containing dinitrogen monoxide (N₂O), an organic substance on the surface of the semiconductor layer 109 can be suitably removed. The plasma treatment can be performed with a PECVD apparatus or an etching apparatus, for example.

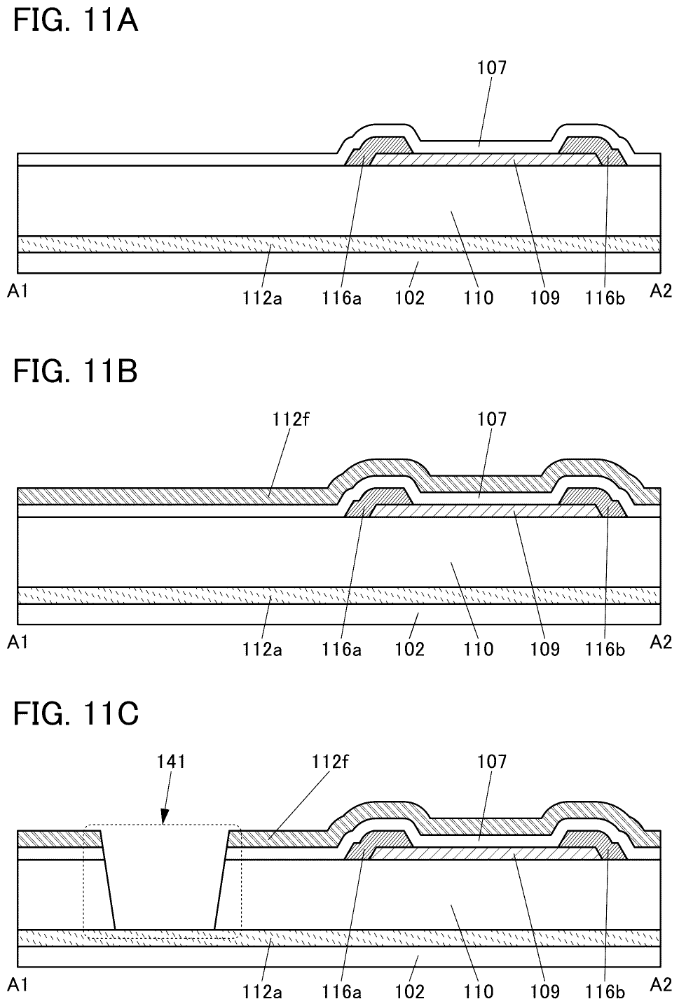

Next, the insulating layer 107 to be the gate insulating layer of the transistor M1 later is formed over the semiconductor layer 109, the conductive layer 116a, the conductive layer 116b, and the insulating layer 110 (see FIG. 11A). The insulating layer 107 can be formed with the above-described material by a PECVD method or the like, for example.

When an oxide semiconductor is used for the semiconductor layer 109, an insulating material in which oxygen is contained and hydrogen is reduced is preferably used for the insulating layer 107. Thus, the semiconductor layer 109 including a region in contact with the insulating layer 107 is less likely to have n-type conductivity. In addition, oxygen can be supplied from the insulating layer 107 to the semiconductor layer 109 efficiently, and accordingly, oxygen vacancies (Vo) in the semiconductor layer 109 can be reduced. The semiconductor layer 109 functions as the semiconductor layer where the channel of the transistor M1 is formed later. Thus, the insulating layer 107 using the material described above allows the transistor M1 to have favorable electrical characteristics and high reliability.

When the temperature at the time of forming the insulating layer 107 functioning as the gate insulating layer of the transistor M1 is increased, an insulating layer with few defects can be obtained. However, the high temperature at the time of forming the insulating layer 107 sometimes allows release of oxygen from the semiconductor layer 109, which increases the oxygen vacancies (Vo) and VoH in the semiconductor layer 109. The substrate temperature at the time of forming the insulating layer 107 is preferably higher than or equal to 180° C. and lower than or equal to 450° C., further preferably higher than or equal to 200° C. and lower than or equal to 450° C., further preferably higher than or equal to 250° C. and lower than or equal to 450° C., further preferably higher than or equal to 300° C. and lower than or equal to 450° C., further preferably higher than or equal to 300° C. and lower than or equal to 400° C. When the substrate temperature at the time of forming the insulating layer 107 is in the above range, release of oxygen from the semiconductor layer 109 can be inhibited while the defects in the insulating layer 107 can be reduced. Consequently, the transistor M1 can have favorable electrical characteristics and high reliability.

Before the formation of the insulating layer 107, a surface of the semiconductor layer 109 may be subjected to plasma treatment. By the plasma treatment, impurities such as water adsorbed on the surface of the semiconductor layer 109 can be reduced. Accordingly, impurities at the interface between the semiconductor layer 109 and the insulating layer 107 can be reduced, enabling the transistor M1 to have high reliability. The plasma treatment is particularly preferable in the case where the surface of the semiconductor layer 109 is exposed to the air in the process from formation of the semiconductor layer 109 to formation of the insulating layer 107. The plasma treatment can be performed in an atmosphere of oxygen, ozone, nitrogen, dinitrogen monoxide, argon, or the like. The plasma treatment and the formation of the insulating layer 107 are preferably performed successively without exposure to the air.

Then, a conductive film 112f to be the conductive layer 112b later is formed over the insulating layer 107 (see FIG. 11B). The conductive film 112f can be formed with the above-described material by a sputtering method, for example.

Next, a resist mask (not illustrated) is formed over the conductive film 112f that does not overlap with the position where the transistor M2 is formed later by a photolithography process, and then the conductive film 112f, the insulating layer 107, and the insulating layer 110 are each processed, whereby the opening 141 is formed (see FIG. 11C). As the method of forming the opening 141, at least one of a wet etching method and a dry etching method can be used. The opening 141 can be suitably formed by a dry etching method, for example.

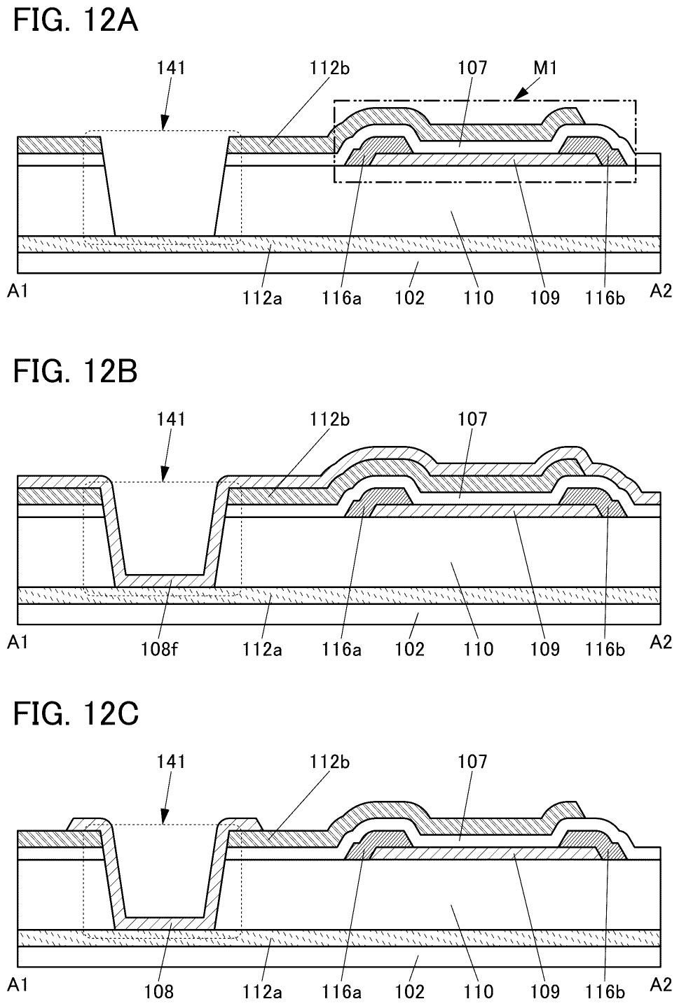

Next, a resist mask (not illustrated) is formed over the conductive film 112f that overlaps with the position to be the gate electrode of the transistor M1 later by a photolithography process, and then the conductive film is processed, whereby the conductive layer 112b is formed (see FIG. 12A). For the formation of the conductive layer 112b, either one or both of a wet etching method and a dry etching method can be used. A wet etching method can be suitably used for formation of the conductive layer 112b.

Through the above steps, the transistor M1 is formed.

Next, the metal oxide film 108f to be the semiconductor layer 108 later is formed to cover the inner wall of the opening 141 (part of the top surface of the conductive layer 112a, the side surface of the insulating layer 110, the side surface of the insulating layer 107, and the side surface of the conductive layer 112b), the top surface of the conductive layer 112b, and part of the top surface of the insulating layer 107 (see FIG. 12B). The metal oxide film 108f is preferably formed by a sputtering method using a metal oxide target.

The conditions of the formation of the metal oxide film 109f and the heat treatment performed after the formation of the metal oxide film 109f described above can be referred to for the conditions of the formation of the metal oxide film 108f and the heat treatment performed after the formation of the metal oxide film 108f.

Next, the metal oxide film 108f is processed into an island shape to include a region overlapping with the inner wall of the opening 141, whereby the semiconductor layer 108 is formed (see FIG. 12C).

For the formation of the semiconductor layer 108, either one or both of a wet etching method and a dry etching method can be used. For example, a wet etching method can be suitably used to form the semiconductor layer 108.

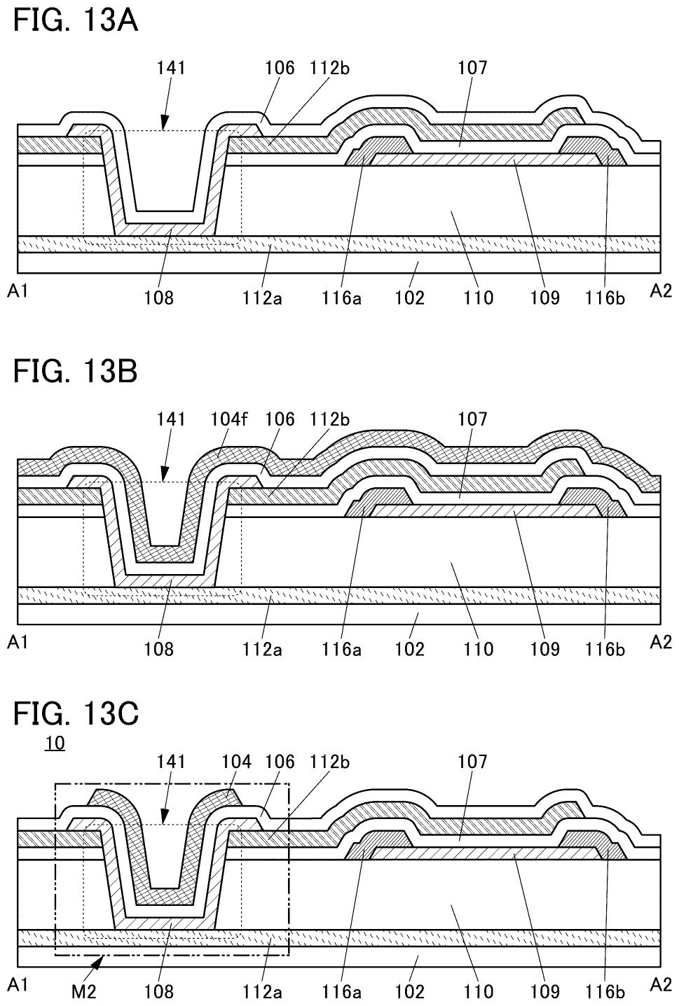

Next, the insulating layer 106 to be the gate insulating layer of the transistor M2 later is formed over the semiconductor layer 108, the conductive layer 112b, and the insulating layer 107 (see FIG. 13A). The insulating layer 106 can be formed with the above-described material by a PECVD method, for example.

The conditions of the formation of the insulating layer 107 and the plasma treatment of the semiconductor layer 109 prior to the formation of the insulating layer 107 described above can be referred to for the conditions of the formation of the insulating layer 106 and the plasma treatment of the semiconductor layer 108 prior to the formation of the insulating layer 106.

Then, a conductive film 104f to be the conductive layer 104 later is formed over the insulating layer 106 (see FIG. 13B). The conductive film 104f can be formed with the above-described material by a sputtering method, for example.

Next, a resist mask (not illustrated) is formed over the conductive film 104f to include a region overlapping with the opening 141, and then the conductive film is processed, whereby the conductive layer 104 is formed (see FIG. 13C). For the formation of the conductive layer 104, either one or both of a wet etching method and a dry etching method can be used. For example, a wet etching method can be suitably used to form the conductive layer 104.

Through the above process, the transistor M2 is formed.

Thus, the semiconductor device 10 (FIG. 1A and FIG. 1B) of one embodiment of the present invention, which includes the transistors M1 and M2, can be fabricated.

As described above, the semiconductor device of one embodiment of the present invention can be applied to a pixel circuit of a display apparatus, for example. Configuration examples of the pixel circuit to which the semiconductor device of one embodiment of the present invention can be applied are described below.

### Structure Example of Pixel Circuit

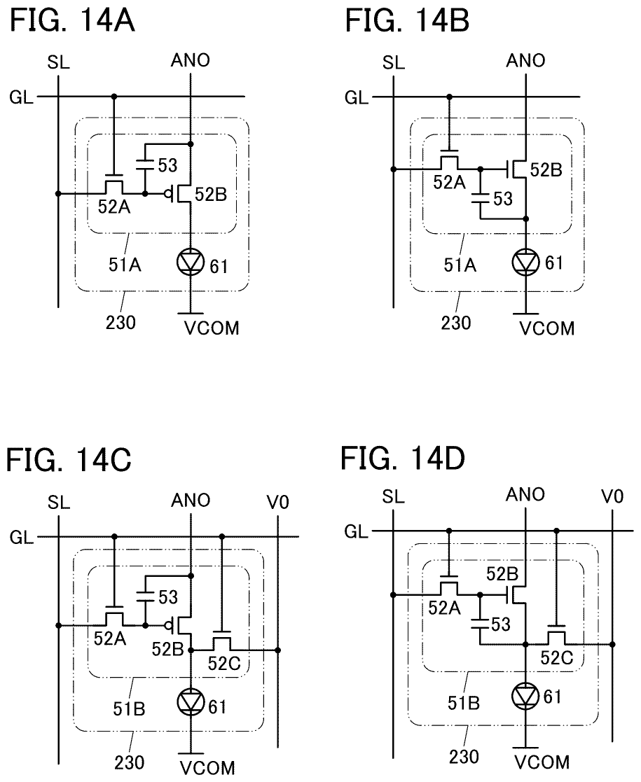

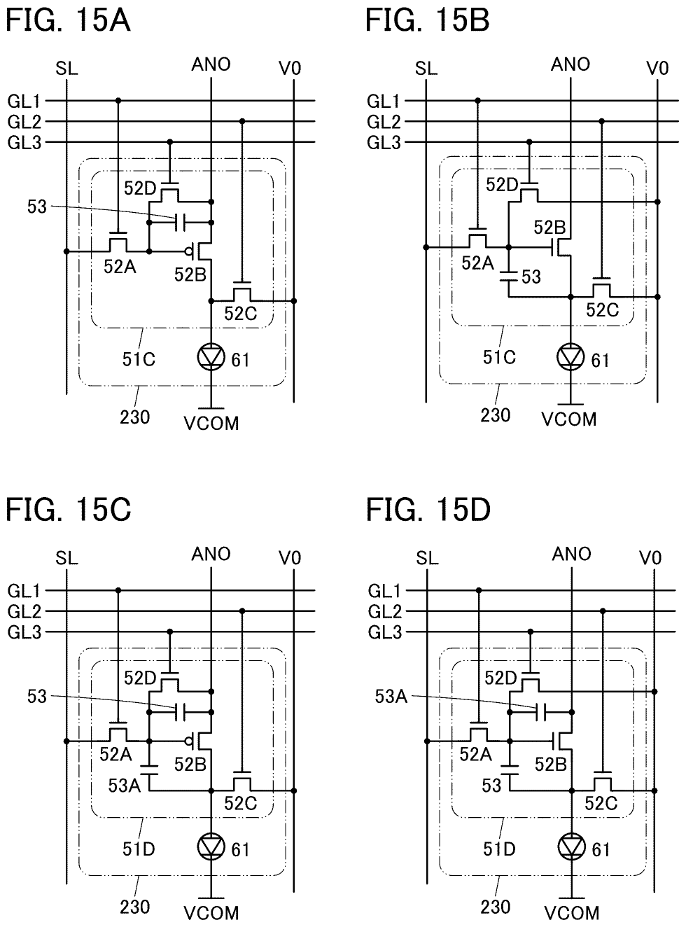

FIG. 14A to FIG. 14D and FIG. 15A to FIG. 15D show the structure examples of a pixel 230 of a display apparatus to which the semiconductor device of one embodiment of the present invention can be applied. The pixel 230 includes a pixel circuit 51 (a pixel circuit 51A, a pixel circuit 51B, a pixel circuit 51C, or a pixel circuit 51D) and a light-emitting device 61.

The term light-emitting device in this embodiment and the like refers to a self-luminous display device (also referred to as a display element) such as an organic EL element (also referred to as OLED (organic LED)). Note that the light-emitting element electrically connected to the pixel circuit can be a self-luminous light-emitting element such as an LED, a micro LED, a quantum-dot LED (QLED), or a semiconductor laser.

The pixel circuit 51A illustrated in FIG. 14A is a 2Tr1C pixel circuit including a transistor 52A, a transistor 52B, and a capacitor 53.

One of a source and a drain of the transistor 52A is electrically connected to a wiring SL and a gate of the transistor 52A is electrically connected to a wiring GL. The other of the source and the drain of the transistor 52A is electrically connected to a gate of the transistor 52B. One of a source and a drain of the transistor 52B and one terminal of the capacitor 53 are electrically connected to a wiring ANO. The other terminal of the capacitor 53 is electrically connected to the gate of the transistor 52B. The other of the source and the drain of the transistor 52B is electrically connected to an anode of the light-emitting element 61. A cathode of the light-emitting device 61 is electrically connected to a wiring VCOM.

The wiring GL corresponds to the conductive layer 104 of the semiconductor device 10, and the wiring SL corresponds to the conductive layer 112a of the semiconductor device 10. The wiring VCOM supplies a potential for supplying a current to the light-emitting device 61. The transistor 52A has a function of controlling the conduction state or the non-conduction state between the wiring SL and the gate of the transistor 52B on the basis of the potential of the wiring GL. For example, VDD is supplied to the wiring ANO and VSS is supplied to the wiring VCOM.

The transistor 52B has a function of controlling the amount of current flowing through the light-emitting device 61. The capacitor 53 has a function of holding a gate potential of the transistor 52B. The intensity of light emitted by the light-emitting device 61 can be controlled in accordance with an image signal supplied to the gate of the transistor 52B.

In the pixel circuit 51A illustrated in FIG. 14A, an n-channel transistor is used as the transistor 52A and a p-channel transistor is used as the transistor 52B. Note that like in the pixel circuit 51A illustrated in FIG. 14B, an n-channel transistor may be used as the transistor 52B. When an n-channel transistor is used as the transistor 52B, one terminal of the capacitor 53 can be electrically connected to the other of the source or the drain of the transistor 52B.

The semiconductor device of one embodiment of the present invention can be used in the pixel circuit 51A illustrated in FIG. 14B. For example, the transistor M2 included in the semiconductor device illustrated in any of FIG. 1A to FIG. 2B and FIG. 7A and FIG. 7B can be used as the transistor 52A included in the pixel circuit 51A, and the transistor M1 included in the semiconductor device illustrated in any of FIG. 1A to FIG. 2B and FIG. 7A and FIG. 7B can be used as the transistor 52B included in the pixel circuit 51A.

For example, the transistor M1 included in the semiconductor device illustrated in any of FIG. 3A, FIG. 3B, and FIG. 7C can be used as the transistor 52A included in the pixel circuit 51A, and the transistor M2 included in the semiconductor device illustrated in any of FIG. 3A, FIG. 3B, and FIG. 7C can be used as the transistor 52B included in the pixel circuit 51A.

When a p-channel transistor is used as the transistor 52B, a circuit configuration of the pixel circuit 51B in FIG. 14C may be employed. The pixel circuit 51B illustrated in FIG. 14C is a 3Tr1C pixel circuit including the transistor 52A, the transistor 52B, a transistor 52C, and the capacitor 53. The pixel circuit 51B illustrated in FIG. 14C has a structure in which the transistor 52C is added to the pixel circuit 51A illustrated in FIG. 14A.

When an n-channel transistor is used as the transistor 52B, a circuit configuration of the pixel circuit 51B in FIG. 14D may be employed. The pixel circuit 51B illustrated in FIG. 14D has a structure in which the transistor 52C is added to the pixel circuit 51A in FIG. 14B.

One of a source and a drain of the transistor 52C is electrically connected to the other of the source and the drain of the transistor 52B in the pixel circuit 51B in FIG. 14C and the pixel circuit 51B illustrated in FIG. 14D. The other of the source and the drain of the transistor 52C is electrically connected to a wiring V0. For example, a reference potential is supplied to the wiring V0.

The transistor 52C has a function of controlling the conduction state or the non-conduction state between the other of the source or the drain of the transistor 52B and the wiring V0 on the basis of the potential of the wiring GL. The wiring V0 is a wiring that supplies the reference potential. When an n-channel transistor is used as the transistor 52B, variations in the gate-source voltage of the transistor 52B can be reduced by the reference potential of the wiring V0 supplied through the transistor 52C.

A current value that can be used for setting of pixel parameters can be obtained with the use of the wiring V0. Specifically, the wiring V0 can function as a monitor line for outputting a current flowing in the transistor 52B or a current flowing in the light-emitting device 61 to the outside. A current output to the wiring V0 is converted into a voltage by a source follower circuit or the like and can be output to the outside. Alternatively, the current is converted into a digital signal by an A-D converter or the like and can be output to the outside.

The semiconductor device of one embodiment of the present invention can be used in the pixel circuit 51B illustrated in FIG. 14D. For example, the transistor M2 included in the semiconductor device illustrated in any of FIG. 1A to FIG. 2B and FIG. 7A and FIG. 7B can be used as the transistor 52A included in the pixel circuit 51B, and the transistor M1 included in the semiconductor device illustrated in any of FIG. 1A to FIG. 2B and FIG. 7A and FIG. 7B can be used as the transistor 52B included in the pixel circuit 51B.

For example, the transistor M1 included in the semiconductor device illustrated in any of FIG. 3A, FIG. 3B, and FIG. 7C can be used as the transistor 52A included in the pixel circuit 51B, and the transistor M2 included in the semiconductor device illustrated in any of FIG. 3A, FIG. 3B, and FIG. 7C can be used as the transistor 52B included in the pixel circuit 51B.

For example, the transistor M1 (transistor M2) included in the semiconductor device illustrated in any of FIG. 4A to FIG. 6B and FIG. 8A to FIG. 8C can be used as the transistor 52B included in the pixel circuit 51B, and the transistor M2 (transistor M1) included in the semiconductor device illustrated in any of FIG. 4A to FIG. 6B and FIG. 8A to FIG. 8C can be used as the transistor 52C included in the pixel circuit 51B.

The pixel circuit 51C illustrated in FIG. 15A has a structure in which a transistor 52D is added to the pixel circuit 51B illustrated in FIG. 14C. The pixel circuit 51C illustrated in FIG. 15A is a 4Tr1C pixel circuit including the transistor 52A, the transistor 52B, the transistor 52C, the transistor 52D and the capacitor 53.

One of a source and a drain of the transistor 52D is electrically connected to the wiring ANO, and the other is electrically connected to the other of the source and the drain of the transistor 52A, the other terminal of the capacitor 53, and the gate of the transistor 52B.

A wiring GL1, a wiring GL2, and a wiring GL3 are electrically connected to the pixel circuit 51C. In this embodiment and the like, the wiring GL1, the wiring GL2, and the wiring GL3 are collectively referred to as the wiring GL in some cases. Thus, the wiring GL may be one wiring or a plurality of wirings.

The wiring GL1 is electrically connected to the gate of the transistor 52A, the wiring GL2 is electrically connected to a gate of the transistor 52C, and the wiring GL3 is electrically connected to a gate of the transistor 52D.

When the transistor 52D is turned on, the source and the gate of the transistor 52B have the same potential, so that the transistor 52B can be turned off. Thus, a current flowing to the light-emitting device 61 can be blocked forcibly. Such a pixel circuit is suitable for the case of using a display method in which a display period and an off period are alternately provided. The transistor 52C may be turned on at the same time when the transistor 52D is turned on.

The semiconductor device of one embodiment of the present invention can be used in the pixel circuit 51C illustrated in FIG. 15A. For example, the transistor M1 (transistor M2) included in the semiconductor device illustrated in any of FIG. 4A to FIG. 6B and FIG. 8A to FIG. 8C can be used as the transistor 52A included in the pixel circuit 51C, and the transistor M2 (transistor M1) included in the semiconductor device illustrated in any of FIG. 4A to FIG. 6B and FIG. 8A to FIG. 8C can be used as the transistor 52D included in the pixel circuit 51C.

In the pixel circuit 51C illustrated in FIG. 15A, an n-channel transistor is used as the transistor 52A, the transistor 52C, and the transistor 52D and a p-channel transistor is used as the transistor 52B. Note that as in the pixel circuit 51C illustrated in FIG. 15B, an n-channel transistor may be used as the transistor 52B. When an n-channel transistor is used as the transistor 52B, one terminal of the capacitor 53 can be electrically connected to the other of the source or the drain of the transistor 52B. The one of the source and the drain of the transistor 52D is electrically connected to the wiring V0.

The semiconductor device of one embodiment of the present invention can be used in the pixel circuit 51C illustrated in FIG. 15B. For example, the transistor M1 (transistor M2) included in the semiconductor device illustrated in any of FIG. 4A to FIG. 6B and FIG. 8A to FIG. 8C can be used as the transistor 52A included in the pixel circuit 51C, and the transistor M2 (transistor M1) included in the semiconductor device illustrated in any of FIG. 4A to FIG. 6B and FIG. 8A to FIG. 8C can be used as the transistor 52D included in the pixel circuit 51C.

For example, the transistor M1 (transistor M2) included in the semiconductor device illustrated in any of FIG. 4A to FIG. 6B and FIG. 8A to FIG. 8C can be used as the transistor 52B included in the pixel circuit 51C, and the transistor M2 (transistor M1) included in the semiconductor device illustrated in any of FIG. 4A to FIG. 6B and FIG. 8A to FIG. 8C can be used as the transistor 52C included in the pixel circuit 51C.

For example, the transistor M2 included in the semiconductor device illustrated in any of FIG. 1A to FIG. 2B and FIG. 7A and FIG. 7B can be used as the transistor 52A included in the pixel circuit 51C, and the transistor M1 included in the semiconductor device illustrated in any of FIG. 1A to FIG. 2B and FIG. 7A and FIG. 7B can be used as the transistor 52B included in the pixel circuit 51C.

For example, the transistor M1 included in the semiconductor device illustrated in any of FIG. 3A, FIG. 3B, and FIG. 7C can be used as the transistor 52A included in the pixel circuit 51C, and the transistor M2 included in the semiconductor device illustrated in any of FIG. 3A, FIG. 3B, and FIG. 7C can be used as the transistor 52B included in the pixel circuit 51C.

For example, the transistor M2 included in the semiconductor device illustrated in any of FIG. 1A to FIG. 2B and FIG. 7A and FIG. 7B can be used as the transistor 52D included in the pixel circuit 51C, and the transistor M1 included in the semiconductor device illustrated in any of FIG. 1A to FIG. 2B and FIG. 7A and FIG. 7B can be used as the transistor 52B included in the pixel circuit 51C.

For example, the transistor M1 included in the semiconductor device illustrated in any of FIG. 3A, FIG. 3B, and FIG. 7C can be used as the transistor 52D included in the pixel circuit 51C, and the transistor M2 included in the semiconductor device illustrated in any of FIG. 3A, FIG. 3B, and FIG. 7C can be used as the transistor 52B included in the pixel circuit 51C.

The pixel circuit 51D illustrated in FIG. 15C has a structure in which a capacitor 53A is added to the pixel circuit 51C illustrated in FIG. 15A. In the pixel circuit 51D illustrated in FIG. 15C, one terminal of the capacitor 53A is electrically connected to the other terminal of the source and the drain of the transistor 52B, and the other terminal of the capacitor 53A is electrically connected to the gate of the transistor 52B.

The semiconductor device of one embodiment of the present invention can be used in the pixel circuit 51D illustrated in FIG. 15C. For example, the transistor M1 (transistor M2) included in the semiconductor device illustrated in any of FIG. 4A to FIG. 6B and FIG. 8A to FIG. 8C can be used as the transistor 52A included in the pixel circuit 51D, and the transistor M2 (transistor M1) included in the semiconductor device illustrated in any of FIG. 4A to FIG. 6B and FIG. 8A to FIG. 8C can be used as the transistor 52D included in the pixel circuit 51D.

The pixel circuit 51D illustrated in FIG. 15D has a structure in which the capacitor 53A is added to the pixel circuit 51C illustrated in FIG. 15B. In the pixel circuit 51D illustrated in FIG. 15D, the one terminal of the capacitor 53A is electrically connected to the wiring ANO, and the other terminal of the capacitor 53A is electrically connected to the gate of the transistor 52B. The capacitor 53 and the capacitor 53A each function as a storage capacitor. The pixel circuits 51D illustrated in FIG. 15C and FIG. 15D are 4Tr2C pixel circuits.

The semiconductor device of one embodiment of the present invention can be used in the pixel circuit 51D illustrated in FIG. 15D. For example, the transistor M1 (transistor M2) included in the semiconductor device illustrated in any of FIG. 4A to FIG. 6B and FIG. 8A to FIG. 8C can be used as the transistor 52A included in the pixel circuit 51D, and the transistor M2 (transistor M1) included in the semiconductor device illustrated in any of FIG. 4A to FIG. 6B and FIG. 8A to FIG. 8C can be used as the transistor 52D included in the pixel circuit 51D.

For example, the transistor M1 (transistor M2) included in the semiconductor device illustrated in any of FIG. 4A to FIG. 6B and FIG. 8A to FIG. 8C can be used as the transistor 52B included in the pixel circuit 51D, and the transistor M2 (transistor M1) included in the semiconductor device illustrated in any of FIG. 4A to FIG. 6B and FIG. 8A to FIG. 8C can be used as the transistor 52C included in the pixel circuit 51D.

For example, the transistor M2 included in the semiconductor device illustrated in any of FIG. 1A to FIG. 2B and FIG. 7A and FIG. 7B can be used as the transistor 52A included in the pixel circuit 51D, and the transistor M1 included in the semiconductor device illustrated in any of FIG. 1A to FIG. 2B and FIG. 7A and FIG. 7B can be used as the transistor 52B included in the pixel circuit 51D.

For example, the transistor M1 included in the semiconductor device illustrated in any of FIG. 3A, FIG. 3B, and FIG. 7C can be used as the transistor 52A included in the pixel circuit 51D, and the transistor M2 included in the semiconductor device illustrated in any of FIG. 3A, FIG. 3B, and FIG. 7C can be used as the transistor 52B included in the pixel circuit 51D.

For example, the transistor M2 included in the semiconductor device illustrated in any of FIG. 1A to FIG. 2B and FIG. 7A and FIG. 7B can be used as the transistor 52D included in the pixel circuit 51D, and the transistor M1 included in the semiconductor device illustrated in any of FIG. 1A to FIG. 2B and FIG. 7A and FIG. 7B can be used as the transistor 52B included in the pixel circuit 51D.

For example, the transistor M1 included in the semiconductor device illustrated in any of FIG. 3A, FIG. 3B, and FIG. 7C can be used as the transistor 52D included in the pixel circuit 51D, and the transistor M2 included in the semiconductor device illustrated in any of FIG. 3A, FIG. 3B, and FIG. 7C can be used as the transistor 52B included in the pixel circuit 51D.

Each of the transistor 52A, the transistor 52B, the transistor 52C, and the transistor 52D preferably includes a back gate electrode (second gate electrode), in which case the back gate electrode and a gate electrode can be supplied with the same signals or different signals.

P-channel transistors may be used not only as the transistor 52B but also as the transistor 52A, the transistor 52C, and the transistor 52D.

As described above, the semiconductor device of one embodiment of the present invention can be applied to a pixel circuit of a display apparatus. The semiconductor device of one embodiment of the present invention, where the transistors can be arranged with high density, can be highly integrated, and accordingly, the display apparatus using the semiconductor device in a pixel circuit can have high resolution.

This embodiment can be combined with any of the other embodiments or an example as appropriate. In this specification, in the case where a plurality of structure examples are described in one embodiment, the structure examples can be combined as appropriate.

### Embodiment 2

In this embodiment, a display apparatus using the semiconductor device of one embodiment of the present invention is described.

The display apparatus in this embodiment can be a high-resolution display apparatus. Accordingly, the display apparatus in this embodiment can be used for display portions of information terminals (wearable devices) such as watch-type and bracelet-type information terminals and display portions of wearable devices capable of being worn on the head, such as a VR device like a head-mounted display (HMD) and a glasses-type AR device.

The display apparatus in this embodiment can be a high-definition display apparatus or a large-sized display apparatus. Accordingly, the display apparatus in this embodiment can be used for display portions of electronic devices such as a digital camera, a digital video camera, a digital photo frame, a mobile phone, a portable game console, a portable information terminal, and an audio reproducing device, in addition to display portions of electronic devices with a relatively large screen, such as a television device, a desktop or laptop personal computer, a monitor of a computer or the like, digital signage, and a large game machine such as a pachinko machine.

### Display Apparatus 200A

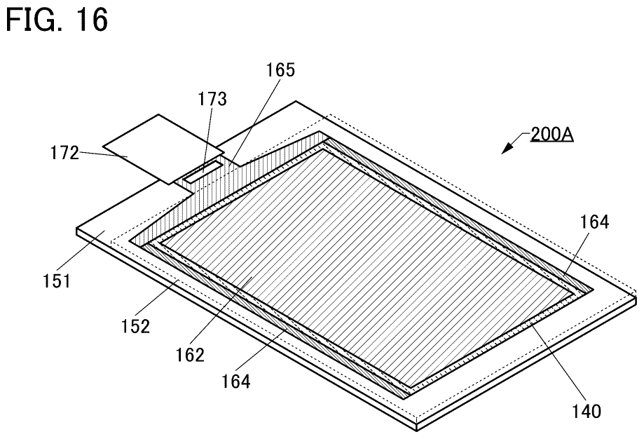

FIG. 16 is a perspective view of a display apparatus 200A.

In the display apparatus 200A, a substrate 152 and a substrate 151 are attached to each other. In FIG. 16, the substrate 152 is denoted by a dashed line.

The display apparatus 200A includes a display portion 162, a connection portion 140, a circuit 164, a wiring 165, and the like. FIG. 16 illustrates an example in which an IC 173 and an FPC 172 are mounted on the display apparatus 200A. Thus, the structure illustrated in FIG. 16 can be regarded as a display module including the display apparatus 200A, the IC (integrated circuit), and the FPC.

A plurality of subpixels are arranged in a matrix in the display portion 162. Each of the pixels includes a plurality of subpixels.

Each subpixel includes a display device. Examples of the display device include a liquid crystal device (also referred to as a liquid crystal element) and a light-emitting device. As the light-emitting device, an OLED or a QLED is preferably used, for example. Examples of a light-emitting substance contained in the light-emitting device include a substance emitting fluorescent light (a fluorescent material), a substance emitting phosphorescent light (a phosphorescent material), a substance exhibiting thermally activated delayed fluorescence (a thermally activated delayed fluorescent (TADF) material), and an inorganic compound (e.g., a quantum dot material). An LED such as a micro-LED can also be used as the light-emitting device.

The light-emitting device can emit infrared, red, green, blue, cyan, magenta, yellow, or white light, for example. When the light-emitting device has a microcavity structure, the color purity can be further increased.

In the following description, a structure where a light-emitting device is used as the display device is given as an example.

A display apparatus of one embodiment of the present invention includes light-emitting devices of different colors, which are separately formed, and can perform full-color display.

The display apparatus of one embodiment of the present invention can have any of the following structures: a top-emission structure in which light is emitted in a direction opposite to the substrate where the light-emitting device is formed, a bottom-emission structure in which light is emitted toward the substrate where the light-emitting device is formed, and a dual-emission structure in which light is emitted toward both surfaces.

The connection portion 140 is provided outside the display portion 162. The connection portion 140 can be provided along one side or a plurality of sides of the display portion 162, for example. There is no particular limitation on the planar shape of the connection portion 140, and the shape can be a belt-like shape, an L shape, a U shape, a frame-like shape, or the like. The number of connection portions 140 may be one or more. FIG. 16 illustrates an example where the connection portion 140 is provided to surround the four sides of the display portion 162. The common electrode of the light-emitting device is electrically connected to a conductive layer in the connection portion 140, and thus a potential can be supplied to the common electrode. The connection portion 140 can also be referred to as a cathode contact portion.

As the circuit 164, a scan line driver circuit can be used, for example.

The wiring 165 has a function of supplying a signal and power to the display portion 162 and the circuits 164. The signal and power are input to the wiring 165 from the outside through the FPC 172 or input to the wiring 165 from the IC 173.

FIG. 16 illustrates an example where the IC 173 is provided over the substrate 151 by a COG (chip on glass) method, a COF (chip on film) method, or the like. An IC including a scan line driver circuit, a signal line driver circuit, or the like can be used as the IC 173, for example. Note that the display apparatus 200A and the display module are not necessarily provided with an IC. The IC may be mounted on the FPC by a COF method or the like.

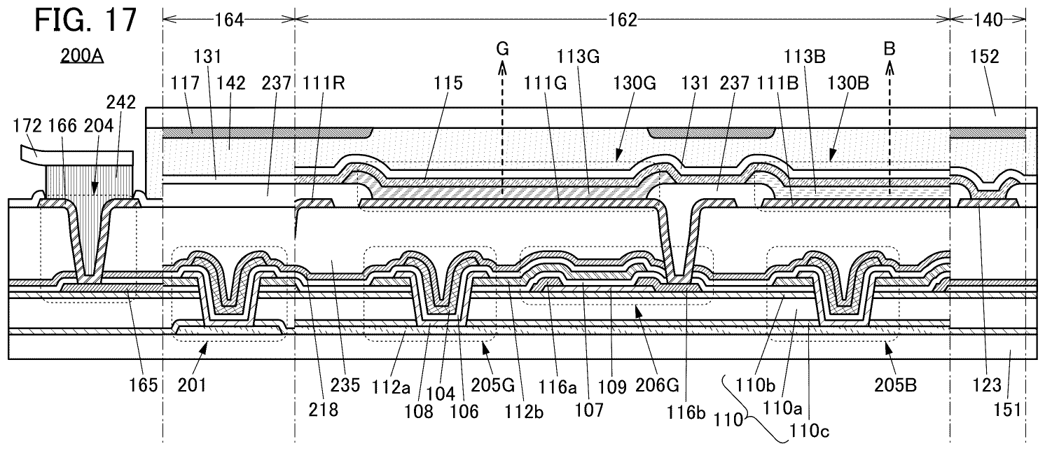

FIG. 17 illustrates an example of cross sections of part of a region including the FPC 172, part of the circuit 164, part of the display portion 162, part of the connection portion 140, and part of a region including an end portion of the display apparatus 200A.

The display apparatus 200A illustrated in FIG. 17 includes a transistor 201, a transistor 205R (not illustrated), a transistor 205G, a transistor 205B, a transistor 206R (not illustrated), a transistor 206G, a transistor 206B (not illustrated), a light-emitting device 130R (not illustrated), a light-emitting device 130G, a light-emitting device 130B, and the like between the substrate 151 and the substrate 152.

Over the substrate 151, the transistor 201, the transistor 205R, the transistor 205G, the transistor 205B, the transistor 206R, the transistor 206G, and the transistor 206B are provided. An insulating layer 218 and an insulating layer 235 over the insulating layer 218 are provided to cover the transistor 201, the transistor 205R, the transistor 205G, the transistor 205B, the transistor 206R, the transistor 206G, and the transistor 206B. The light-emitting device 130R, the light-emitting device 130G, and the light-emitting device 130B are provided over the insulating layer 235.

Matters common to the light-emitting device 130R, the light-emitting device 130G, and the light-emitting device 130B are sometimes described using the term light-emitting device 130 without any letter of the alphabet distinguishing these light-emitting devices. Likewise, in the description of matters common to the components that are distinguished using letters of the alphabet, such as the transistor 205R, the transistor 205G, and the transistor 205B, reference numerals without the letters of the alphabet are sometimes used.

The transistor 201, the transistor 205R, the transistor 205G, the transistor 205B, the transistor 206R, the transistor 206G, and the transistor 206B are each provided over the substrate 151. The transistor 201, the transistor 205R, the transistor 205G, and the transistor 205B can be fabricated with the same material and the same process. The transistor 206R, the transistor 206G, and the transistor 206B can be fabricated with the same material and the same process. Although FIG. 17 shows an example in which the transistor 201 has the same structure as the transistor 205 (the transistor 205R, the transistor 205G, and the transistor 205B), one embodiment of the present invention is not limited thereto. The transistor 201 may have the same structure as the transistor 206 (the transistor 206R, the transistor 206G, and the transistor 206B).

The transistor described in Embodiment 1 can be suitably used as the transistor 201, the transistor 205R, the transistor 205G, the transistor 205B, the transistor 206R, the transistor 206G, and the transistor 206B. FIG. 17 shows the structure in which the transistor M2 in the semiconductor device 10 illustrated in FIG. 1A and FIG. 1B is used as the transistor 201, the transistor 205R, the transistor 205G, and the transistor 205B. In the structure, the transistor M1 in the semiconductor device 10 illustrated in FIG. 1A and FIG. 1B is used as the transistor 206R, the transistor 206G, and the transistor 206B.

In other words, the transistor 205R and the transistor 206R are included in the semiconductor device in a subpixel that emits red (R) light, the transistor 205G and the transistor 206G are included in the semiconductor device in a subpixel that emits green (G) light, and the transistor 205B and the transistor 206B are included in the semiconductor device in a subpixel that emits blue (B) light. In the example in FIG. 17, the insulating layer 110 has a stacked structure of three layers, an insulating layer 110c, an insulating layer 110a, and an insulating layer 110b. With the use of the transistor described in Embodiment 1 for the display portion 162, the display apparatus can have high resolution. With the use of the transistor described in Embodiment 1 for the circuit 164, the display apparatus can have a narrow bezel.

All of the transistors included in the display portion 162 may be OS transistors or all of the transistors included in the display portion 162 may be Si transistors; alternatively, some of the transistors included in the display portion 162 may be OS transistors and the others may be Si transistors. As a Si transistor, a transistor using LTPS (hereinafter, referred to as a LTPS transistor) may be used.

For example, when both an LTPS transistor and an OS transistor are used in the display portion 162, the display apparatus with low power consumption and high drive capability can be achieved. Note that a structure in which the LTPS transistor and the OS transistor are combined is referred to as LTPO in some cases. For example, it is preferable to use the OS transistor as a transistor functioning as a switch for controlling electrical continuity and discontinuity between wirings and the LTPS transistor is used as a transistor for controlling current.

For example, one transistor (transistor 206) included in the display portion 162 can function as a transistor for controlling current flowing through the light-emitting device and be referred to as a driving transistor. One of a source and a drain of the driving transistor is electrically connected to the pixel electrode of the light-emitting device. An LTPS transistor is preferably used as the driving transistor. Accordingly, the amount of current flowing through the light-emitting device can be increased in the pixel circuit. By contrast, another transistor (transistor 205) included in the display portion 162 may function as a switch for controlling selection or non-selection of a pixel and be referred to as a selection transistor. A gate of the selection transistor is electrically connected to a gate line, and one of a source and a drain thereof is electrically connected to a source line (signal line). An OS transistor is preferably used as the selection transistor. Accordingly, the gray level of the pixel can be maintained even with an extremely low frame frequency (e.g., 1 fps or lower); thus, power consumption can be reduced by stopping the driver in displaying a still image.

The light-emitting device 130R, the light-emitting device 130G, and the light-emitting device 130B each include a pair of electrodes and a layer between the pair of electrodes. The layer includes at least a light-emitting layer. One of the pair of electrodes of the light-emitting device functions as an anode, and the other electrode functions as a cathode. The case where the pixel electrode functions as an anode and a common electrode functions as a cathode is described below as an example in some cases.

The light-emitting device 130R includes a pixel electrode 111R over the insulating layer 235, an island-shaped layer 113R (not illustrated) over the pixel electrode 111R, and a common electrode 115 over the island-shaped layer 113R.

The light-emitting device 130G includes a pixel electrode 111G over the insulating layer 235, an island-shaped layer 113G over the pixel electrode 111G, and the common electrode 115 over the island-shaped layer 113G.

The light-emitting device 130B includes a pixel electrode 111B over the insulating layer 235, an island-shaped layer 113B over the pixel electrode 111B, and the common electrode 115 over the island-shaped layer 113B.

Each of the layer 113R, the layer 113G, and the layer 113B includes at least a light-emitting layer. For example, the light-emitting device 130R emits red (R) light, the light-emitting device 130G emits green (G) light, and the light-emitting device 130B emits blue (B) light. For example, the layer 113R includes a light-emitting layer that emits red light, the layer 113G includes a light-emitting layer that emits green light, and the layer 113B includes a light-emitting layer that emits blue light. In other words, the layer 113R includes a light-emitting material that emits red light, the layer 113G includes a light-emitting material that emits green light, and the layer 113B includes a light-emitting material that emits blue light. The layer 113R, the layer 113G, and the layer 113B may each include one or more functional layers. Examples of the functional layers include carrier-injection layers (a hole-injection layer and an electron-injection layer), carrier-transport layers (a hole-transport layer and an electron-transport layer), carrier-blocking layers (a hole-blocking layer and an electron-blocking layer), and the like.

Although the layer 113R, the layer 113G, and the layer 113B have the same thickness in FIG. 17, the present invention is not limited thereto. The layer 113R, the layer 113G, and the layer 113B may have different thicknesses. For example, the thicknesses of the layer 113R, the layer 113G, and the layer 113B are preferably set to match an optical path length that intensifies light emitted from each layer. Thus, a microcavity structure can be achieved and the color purity of each light-emitting device 130 can be increased.

The layer 113R, the layer 113G, and the layer 113B can be formed by a vacuum evaporation method using a fine metal mask, for example. In the vacuum evaporation method using a fine metal mask, the layer 113R, the layer 113G, and the layer 113B can be formed in an area wider than an opening of the fine metal mask. The end portions of the layer 113R, the layer 113G, and the layer 113B each have a tapered shape. Note that a sputtering method using a fine metal mask or an inkjet method may be used to form the layer 113R, the layer 113G, and the layer 113B.

The light-emitting device of this embodiment may have either a single structure (a structure including only one light-emitting unit) or a tandem structure (a structure including a plurality of light-emitting units). The light-emitting unit includes at least one light-emitting layer.

In the case of using a tandem light-emitting device, it is preferable that the layer 113R include a plurality of light-emitting units that emit red light, the layer 113G include a plurality of light-emitting units that emit green light, and the layer 113B include a plurality of light-emitting units that emit blue light. A charge-generation layer (also referred to as an intermediate layer) is preferably provided between the light-emitting units.

The common electrode 115 is shared between the light-emitting device 130R, the light-emitting device 130G, and the light-emitting device 130B. The common electrode 115 is electrically connected to a conductive layer 123 provided in the connection portion 140. As the conductive layer 123, a conductive layer formed using the same material and the same process as the pixel electrode 111R, the pixel electrode 111G, and the pixel electrode 111B are preferably used. Preferably, none of the layer 113R, the layer 113G, and the layer 113B are provided over the conductive layer 123.

In the connection portion 140, the common electrode 115 is provided over the conductive layer 123. The common electrode 115 can be formed by a sputtering method or a vacuum evaporation method, for example. Alternatively, a film formed by an evaporation method and a film formed by a sputtering method may be stacked. A mask (also referred to as an area mask, a rough metal mask, or the like to distinguish it from a fine metal mask) for specifying the area where the common electrode 115 is formed may be used to form the common electrode 115.

The insulating layer 218 provided over the transistor 205R, the transistor 205G, the transistor 205B, the transistor 206R, the transistor 206G, and the transistor 206B functions as a protective layer for the transistor 205R, the transistor 205G, the transistor 205B, the transistor 206R, the transistor 206G, and the transistor 206B. The insulating layer 218 is preferably formed using a material through which impurities are not easily diffused. The insulating layer 218 functions as a blocking film that inhibits the diffusion of impurities from the outside into the transistors. Examples of the impurities include water and hydrogen. By providing the insulating layer 218, reliability of the display device can be increased.

The insulating layer 218 can be an insulating layer including an inorganic material or an insulating layer including an organic material. An inorganic material can be suitably used for the insulating layer 218. As the inorganic material, one or more of an oxide, an oxynitride, a nitride oxide, and a nitride can be used. Specifically, one or more of silicon nitride, silicon nitride oxide, silicon oxynitride, aluminum oxide, aluminum oxynitride, aluminum nitride, hafnium oxide, and hafnium aluminate can be used. For example, silicon nitride oxide can be suitably used for the insulating layer 218 because the amount of impurities (such as water and hydrogen) released from silicon nitride oxide itself is small and a silicon nitride oxide film can function as a blocking film that inhibits the diffusion of impurities into the transistors from above the transistors. As an organic material, for example, one or both of an acrylic resin and a polyimide resin can be used. As an organic material, a photosensitive material may be used. A stack including two or more of the above insulating films may also be used. The insulating layer 218 may have a stacked-layer structure of an insulating layer including an inorganic material and an insulating layer including an organic material.

Increasing the temperature at the time of forming an insulating film to be the insulating layer 218 enhances the property of blocking impurities (e.g., water and hydrogen). However, when an oxide semiconductor is used for the semiconductor layer 108 and the semiconductor layer 109, which function as the semiconductor layers where the channels of the transistor 205 and the transistor 206 are respectively formed, the high temperature at the time of forming the insulating film sometimes allows release of oxygen from the semiconductor layer 108 and the semiconductor layer 109, which increases the oxygen vacancies (Vo) and VoH in the semiconductor layer 108 and the semiconductor layer 109. The substrate temperature at the time of forming the insulating film is preferably higher than or equal to 180° C. and lower than or equal to 450° C., further preferably higher than or equal to 200° C. and lower than or equal to 450° C., further preferably higher than or equal to 250° C. and lower than or equal to 450° C., further preferably higher than or equal to 300° C. and lower than or equal to 450° C., further preferably higher than or equal to 300° C. and lower than or equal to 400° C. With the substrate temperature at the time of forming the insulating film in the above range, release of oxygen from the semiconductor layer 108 and the semiconductor layer 109 can be inhibited while the insulating layer 218 can have an improved property of blocking impurities. Consequently, the transistor 205 and the transistor 206 can have favorable electrical characteristics and high reliability.

The insulating layer 235 has a function of reducing unevenness caused by the transistor 205R, the transistor 205G, the transistor 205B, the transistor 206R, the transistor 206G, and the transistor 206B to make a formation surface of the light-emitting device 130 flatter. Note that in this specification and the like, the insulating layer 235 is referred to as a planarization layer in some cases.

For the insulating layer 235, an organic material can be suitably used. As the organic material, a photosensitive organic resin is preferably used, and for example, a photosensitive resin composite containing an acrylic resin is preferably used. Note that in this specification and the like, an acrylic resin refers to not only a polymethacrylic acid ester or a methacrylic resin, but also all the acrylic polymer in a broad sense in some cases.

Alternatively, the insulating layer 235 may be formed using an acrylic resin, a polyimide resin, an epoxy resin, an imide resin, a polyamide resin, a polyimide-amide resin, a silicone resin, a siloxane resin, a benzocyclobutene-based resin, a phenol resin, precursors of these resins, or the like. Alternatively, the insulating layer 235 may be formed using an organic material such as polyvinyl alcohol (PVA), polyvinyl butyral, polyvinylpyrrolidone, polyethylene glycol, polyglycerin, pullulan, water-soluble cellulose, or an alcohol-soluble polyamide resin. A photoresist may be used as the photosensitive resin. As the photosensitive organic resin, either a positive-type material or a negative-type material may be used.

The insulating layer 235 may have a stacked-layer structure of an organic insulating layer and an inorganic insulating layer. For example, the insulating layer 235 can have a stacked-layer structure of an organic insulating layer and an inorganic insulating layer over the organic insulating layer. An inorganic insulating layer provided on the outermost surface of the insulating layer 235 can function as an etching protective layer. This can inhibit a decrease in the flatness of the insulating layer 235, which is caused by etching of part of the insulating layer 235 in the formation of the pixel electrode 111.

The low flatness of the top surface of the insulating layer 235, which is the formation surface of the light-emitting device 130, might cause a defect such as a connection defect due to disconnection of the common electrode 115 or an increase in electric resistance due to the locally thinned regions of the common electrode 115. In addition, the low flatness of the top surface of the insulating layer 235 might lower the processing accuracy of the layer to be formed over the insulating layer 235. Making the top surface of the insulating layer 235 flat increases the processing accuracy of the light-emitting device 130 and the like to be provided over the insulating layer 235, whereby the display apparatus can have high resolution. Furthermore, since a connection defect due to disconnection of the common electrode 115 and an increase in electric resistance due to the locally thinned regions of the common electrode 115 can be prevented, the display apparatus can have high display quality.

In some cases, the insulating layer 235 is partly removed when the pixel electrode 111R, the pixel electrode 111G, and the pixel electrode 111B are formed. The insulating layer 235 may have a concave portion in a region overlapping with none of the pixel electrode 111R, the pixel electrode 111G, and the pixel electrode 111B.

The structure of the pixel electrode that can be applied to the display apparatus of one embodiment of the present invention is not limited to the structure of the pixel electrode 111 shown in FIG. 17 and the like.

An insulating layer 237 covers end portions of the top surfaces of the pixel electrode 111R, the pixel electrode 111G, and the pixel electrode 111B. The insulating layer 237 functions as a partition (also referred to as a bank or a spacer). The insulating layer 237 can be an insulating layer including an inorganic material or an insulating layer including an organic material. A material that can be used for the insulating layer 218 or a material that can be used for the insulating layer 235 can be used for the insulating layer 237. The insulating layer 237 may have a stacked structure of an inorganic insulating layer and an organic insulating layer.

The insulating layer 237 prevents contact between the pixel electrode 111 and the common electrode 115 to inhibit a short-circuit in the light-emitting device 130. An end portion of the insulating layer 237 preferably has a tapered shape. When the end portion of the insulating layer 237 has a tapered shape, coverage with the film formed later can be increased. In particular, a photosensitive material is preferably used for an organic insulating layer of the insulating layer 237 so that the shape of the end portion can be easily controlled by the conditions of light exposure and development. Note that an inorganic insulating layer may be used for the insulating layer 237. Using an inorganic insulating layer for the insulating layer 237 enables the display apparatus to have high resolution.

When a photosensitive organic material is used for a film to be the insulating layer 237, the insulating layer 237 can be formed in such a manner that a composition containing an organic material is applied by a spin coating method, and then is subjected to selective light exposure and development. When the photosensitive organic material is used for the film to be the insulating layer 237, a positive-type photosensitive resin or a negative-type photosensitive resin may be used. Light used for the exposure preferably includes the i-line. Furthermore, light used for the exposure may include at least one of the g-line and the h-line. Adjusting the amount of light exposed can change the width of the opening. As another formation method, one or more of a sputtering method, an evaporation method, a droplet discharging method (e.g., an inkjet method), screen printing, and offset printing may be used.

In the pixel electrode 111R, the pixel electrode 111G, and the pixel electrode 111B, a depressed portion is formed to cover the opening in the insulating layer 107, the insulating layer 106, the insulating layer 218, and the insulating layer 235. The insulating layer 237 is embedded in the depressed portion. For example, the insulating layer 237 covering the end portion of the top surface of the pixel electrode 111 and the opening is formed, and then the island-shaped layer 113R, the layer 113G, and the layer 113B can be formed with a fine metal mask.

The layer 113R, the layer 113G, and the layer 113B may be provided over the insulating layer 237. Although adjacent layers 113 are not in contact with each other in the structure shown in FIG. 17, one embodiment of the present invention is not limited thereto. Adjacent layers 113 may be in contact with each other over the insulating layer 237. Adjacent layers 113 may overlap with each other over the insulating layer 237. Over the insulating layer 237, for example, the layer 113R may be in contact with the layer 113G, and the layer 113G and the layer 113R may overlap with each other.

The insulating layer 237 can be applied to other structure examples.

A protective layer 131 is provided over the light-emitting device 130R, the light-emitting device 130G, and the light-emitting device 130B. The protective layer 131 and the substrate 152 are bonded to each other with an adhesive layer 142. The substrate 152 is provided with a light-blocking layer 117. A solid sealing structure, a hollow sealing structure, or the like can be employed to seal the light-emitting devices. In FIG. 17, a solid sealing structure is employed, in which a space between the substrate 152 and the substrate 151 is filled with the adhesive layer 142. Alternatively, a hollow sealing structure may be employed, in which the space is filled with an inert gas (e.g., nitrogen or argon). In that case, the adhesive layer 142 may be provided not to overlap with the light-emitting device. Alternatively, the space may be filled with a resin other than the frame-like adhesive layer 142.

The protective layer 131 is preferably provided over the light-emitting device 130R, the light-emitting device 130G, and the light-emitting device 130B. The protective layer 131 can inhibit oxidation of the common electrode 115 and entry of impurities (e.g., water and oxygen) into the light-emitting devices. Thus, the light-emitting devices are inhibited from deteriorating and the reliability of the display apparatus can be increased. The protective layer 131 may have a single-layer structure or a stacked structure including two or more layers. There is no limitation on the conductivity of the protective layer 131. As the protective layer 131, at least one type of an insulating layer, a semiconductor layer, and a conductive layer can be used.

An inorganic substance can be used for the protective layer 131. For example, one or more of an oxide, an oxynitride, a nitride oxide, and a nitride can be used for the protective layer 131. Specifically, silicon oxide, silicon oxynitride, silicon nitride oxide, silicon nitride, aluminum oxide, aluminum oxynitride, and hafnium oxide can be given. In particular, the protective layer 131 preferably includes a nitride or a nitride oxide, and further preferably includes a nitride.

As the protective layer 131, a layer containing In—Sn oxide (ITO), In—Zn oxide, Ga—Zn oxide, Al—Zn oxide, In—Ga—Zn oxide (IGZO), or the like can also be used. The layer preferably has high resistance, specifically, higher resistance than the common electrode 115. The layer may further contain nitrogen.

When light emitted from the light-emitting device is extracted through the protective layer 131, the protective layer 131 preferably has a good property of transmitting visible light. For example, In—Sn oxide, In—Ga—Zn oxide, and aluminum oxide are preferable because they have a good property of transmitting visible light.

Furthermore, the protective layer 131 may include an organic film. For example, the protective layer 131 may include both an organic film and an inorganic film.

Examples of methods of forming the protective layer 131 include a vacuum evaporation method, a sputtering method, a CVD method, and an ALD method. The protective layer 131 may have a stacked structure of layers formed by different formation methods.

The protective layer 131 is provided at least in the display portion 162, and preferably provided to cover the entire display portion 162. The protective layer 131 is preferably provided to cover not only the display portion 162 but also the connection portion 140 and the circuit 164. It is further preferable that the protective layer 131 be provided to extend to the end portion of the display apparatus 200A.

A connection portion 204 is provided in a region of the substrate 151 not overlapping with the substrate 152. In the connection portion 204, the wiring 165 is electrically connected to the FPC 172 through a conductive layer 166 and a connection layer 242. The conductive layer 166 can be formed through the same process as the pixel electrode 111R, the pixel electrode 111G, and the pixel electrode 111B. On the top surface of the connection portion 204, the conductive layer 166 is exposed. Thus, the connection portion 204 and the FPC 172 can be electrically connected to each other through the connection layer 242.

As the connection layer 242, for example, an anisotropic conductive film (ACF) or an anisotropic conductive paste (ACP) can be used.

Note that the connection portion 204 has a portion not provided with the protective layer 131 so that the FPC 172 and the conductive layer 166 are electrically connected to each other. For example, the protective layer 131 is formed over the entire surface of the display apparatus 200A and then a region of the protective layer 131 overlapping with the conductive layer 166 is removed, so that the conductive layer 166 can be exposed.

A stacked structure of at least one organic layer and a conductive layer may be provided over the conductive layer 166, and the protective layer 131 may be provided over the stacked structure. Then, a separation trigger (a portion that can be a trigger of separation) may be formed in the stacked structure using laser or a sharp cutter (e.g., a needle or a utility knife) to selectively remove the stacked structure and the protective layer 131 thereover, so that the conductive layer 166 may be exposed. For example, the protective layer 131 can be selectively removed when an adhesive roller is pressed to the substrate 151 and then moved relatively while being rolled. Alternatively, an adhesive tape may be attached to the substrate 151 and then peeled. Since adhesion between the organic layer and the conductive layer or between the organic layers is low, separation occurs at the interface between the organic layer and the conductive layer or in the organic layer. Thus, a region of the protective layer 131 overlapping with the conductive layer 166 can be selectively removed. Note that when the organic layer and the like remain over the conductive layer 166, the remaining organic layer and the like can be removed by an organic solvent or the like.

As the organic layer, it is possible to use at least one of the organic layers (the layer functioning as the light-emitting layer, the carrier-blocking layer, the carrier-transport layer, or the carrier-injection layer) used for the layer 113B, the layer 113G, or the layer 113R, for example. The organic layer may be formed concurrently with the layer 113B, the layer 113G, or the layer 113R, or may be provided separately. The conductive layer can be formed using the same process and the same material as the common electrode 115. An ITO film is preferably formed as the common electrode 115 and the conductive layer, for example. Note that in the case where a stacked structure is used for the common electrode 115, at least one of the layers included in the common electrode 115 is provided as the conductive layer.

The top surface of the conductive layer 166 may be covered with a mask so that the protective layer 131 is not provided over the conductive layer 166. As the mask, a metal mask (area metal mask) or a tape or a film having adhesiveness or attachability may be used. The protective layer 131 is formed while the mask is placed and then the mask is removed, so that the conductive layer 166 can be kept exposed even after the protective layer 131 is formed.

With such a method, a region not provided with the protective layer 131 can be formed in the connection portion 204, and the conductive layer 166 and the FPC 172 can be electrically connected to each other through the connection layer 242 in the region.

The conductive layer 123 is provided over the insulating layer 235 in the connection portion 140. End portions of the conductive layer 123 are covered with the insulating layer 237. The common electrode 115 is provided over the conductive layer 123.

The display apparatus 200A illustrated in FIG. 17 has a top-emission structure. Light emitted from the light-emitting devices is emitted toward the substrate 152. For the substrate 152, a material having a high visible-light-transmitting property is preferably used. The pixel electrode 111 includes a material that reflects visible light, and the common electrode 115 includes a material that transmits visible light. In FIG. 17, arrows with broken lines indicate light G and light B, which are emitted toward the substrate 152 from the light-emitting device 130G and the light-emitting device 130B, respectively.

The light-blocking layer 117 is preferably provided on the surface of the substrate 152 on the substrate 151 side. The light-blocking layer 117 can be provided over a region between adjacent light-emitting devices, in the connection portion 140, and in the circuit 164. The light-blocking layer 117 can prevent color mixture by blocking light emitted from adjacent subpixels. Furthermore, the light-blocking layer 117 can prevent external light from reaching the transistor 201, the transistor 205R, the transistor 205G, the transistor 205B, the transistor 206R, the transistor 206G, and the transistor 206B, so that deterioration of the transistor 201, the transistor 205R, the transistor 205G, the transistor 205B, the transistor 206R, the transistor 206G, and the transistor 206B by the external light can be inhibited. Note that a structure without the light-blocking layer 117 may be employed.

A variety of optical members can be provided on the outer surface of the substrate 152. Examples of optical members include a polarizing plate, a retardation plate, a light diffusion layer (e.g., a diffusion film), an anti-reflective layer, and a light-condensing film. Furthermore, an antistatic film inhibiting the attachment of dust, a water repellent film inhibiting the attachment of stain, a hard coat film inhibiting generation of a scratch caused by the use, an impact-absorbing layer, or the like may be provided as a surface protective layer on the outer surface of the substrate 152. For example, it is preferable to provide, as the surface protective layer, a glass layer or a silica layer (SiOₓ layer) because the surface contamination or damage can be prevented. The surface protective layer may be formed using diamond-like carbon (DLC), aluminum oxide (AlOₓ), a polyester-based material, a polycarbonate-based material, or the like. For the surface protective layer, a material having a high visible light transmittance is preferably used. The surface protective layer is preferably formed using a material with high hardness.

A material that can be used for the substrate 102 illustrated in FIG. 1B and the like can be used for each of the substrate 151 and the substrate 152. The substrate through which light from the light-emitting device is extracted is formed using a material that transmits the light. A polarizing plate may be used as the substrate through which light from the light-emitting device is extracted.

When the substrate 151 and the substrate 152 are formed using a flexible material, the flexibility of the display apparatus can be increased. For each of the substrate 151 and the substrate 152, any of the following can be used, for example: polyester resins such as polyethylene terephthalate (PET) and polyethylene naphthalate (PEN), a polyacrylonitrile resin, an acrylic resin, a polyimide resin, a polymethyl methacrylate resin, a polycarbonate (PC) resin, a polyethersulfone (PES) resin, polyamide resins (e.g., nylon and aramid), a polysiloxane resin, a cycloolefin resin, a polystyrene resin, a polyamide-imide resin, a polyurethane resin, a polyvinyl chloride resin, a polyvinylidene chloride resin, a polypropylene resin, a polytetrafluoroethylene (PTFE) resin, an ABS resin, and cellulose nanofiber. Glass that is thin enough to have flexibility may be used as each of the substrate 151 and the substrate 152.

In the case where a circularly polarizing plate overlaps with the display apparatus, a highly optically isotropic substrate is preferably used as the substrate included in the display apparatus. A highly optically isotropic substrate has a low birefringence (in other words, a small amount of birefringence).

The absolute value of a retardation (phase difference) of a highly optically isotropic substrate is preferably less than or equal to 30 nm, further preferably less than or equal to 20 nm, still further preferably less than or equal to 10 nm.

Examples of a highly optically isotropic film include a triacetyl cellulose (TAC, also referred to as cellulose triacetate) film, a cycloolefin polymer (COP) film, a cycloolefin copolymer (COC) film, and an acrylic film.

When a film used as the substrate absorbs water, the shape of the display apparatus might be changed, e.g., creases might be caused. Thus, as the substrate, a film with a low water absorption rate is preferably used. For example, the water absorption rate of the film is preferably 1% or lower, further preferably 0.1% or lower, still further preferably 0.01% or lower.

For the adhesive layer 142, a variety of curable adhesives such as a photocurable adhesive like an ultraviolet curable adhesive, a reactive curable adhesive, a thermosetting adhesive, and an anaerobic adhesive can be used. Examples of these adhesives include an epoxy resin, an acrylic resin, a silicone resin, a phenol resin, a polyimide resin, an imide resin, a polyvinyl chloride (PVC) resin, a polyvinyl butyral (PVB) resin, and an ethylene vinyl acetate (EVA) resin. In particular, a material with low moisture permeability, such as an epoxy resin, is preferable. A two-component-mixture-type resin may be used. An adhesive sheet or the like may be used.

Structure examples different from the aforementioned display apparatus are described below. Note that portions similar to those of the aforementioned display apparatus are not described in some cases. In the drawings that are referred to later, the same hatching pattern is applied to portions having functions similar to those of the aforementioned display apparatus, and the portions are not denoted by reference numerals in some cases.

### Display Apparatus 200B

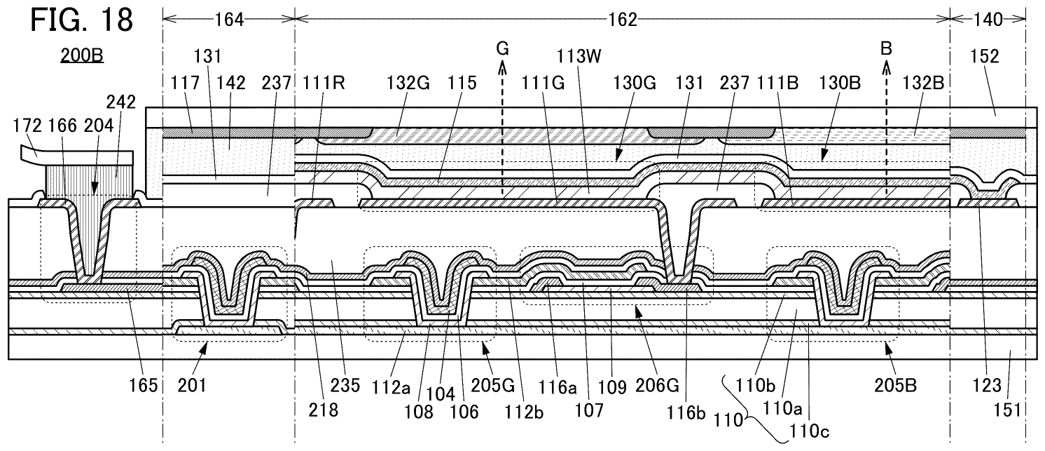

A display apparatus 200B illustrated in FIG. 18 differs from the display apparatus 200A illustrated in FIG. 17 mainly in the structures of the light-emitting device 130R (not illustrated), the light-emitting device 130G and the light-emitting device 130B.

The light-emitting device 130R includes a layer 113W instead of the layer 113R. The light-emitting device 130G includes the layer 113W instead of the layer 113G. The light-emitting device 130B includes the layer 113W instead of the layer 113B. For example, the layer 113W can emit white light. The layer 113W can be formed by a vacuum evaporation method or a sputtering method, for example. The light-emitting device 130R, the light-emitting device 130G, and the light-emitting device 130B can share layer 113W. The layer 113W shared between the plurality of light-emitting devices 130 enables the layer 113W to be formed without a fine metal mask. The layer 113W is provided in the display portion 162. For example, an area mask can be used to form the layer 113W.

An optical adjustment layer (not illustrated) may be provided between the pixel electrode 111 and the layer 113. As the optical adjustment layer, a conductive layer having a visible-light-transmitting property can be used. The thickness of the optical adjustment layer may differ among the light-emitting device 130R, the light-emitting device 130G, and the light-emitting device 130B. When the thickness of the optical adjustment layer is adjusted to optimize the optical path length, the light-emitting device 130 can exhibit light with a desired wavelength, which is intensified, even with the layer 113W emitting white light.

A coloring layer 132R transmitting red light (not illustrated), a coloring layer 132G transmitting green light, and a coloring layer 132B transmitting blue light may be provided on the side of the substrate 152 that faces the adhesive layer 142. The coloring layer 132R is provided in a position overlapping with the light-emitting device 130R. The coloring layer 132G is provided in a position overlapping with the light-emitting device 130G. The coloring layer 132B is provided in a position overlapping with the light-emitting device 130B. For example, light with an unnecessary wavelength emitted from the red-light-emitting device 130R can be blocked by the coloring layer 132R. Such a structure can further increase the color purity of light emitted from each light-emitting device. Note that a similar effect can be obtained in a combination of the light-emitting device 130G and the coloring layer 132G or a combination of the light-emitting device 130B and the coloring layer 132B.

The coloring layer 132R, the coloring layer 132G, and the coloring layer 132B can be applied to other structure examples.

### Display Apparatus 200C

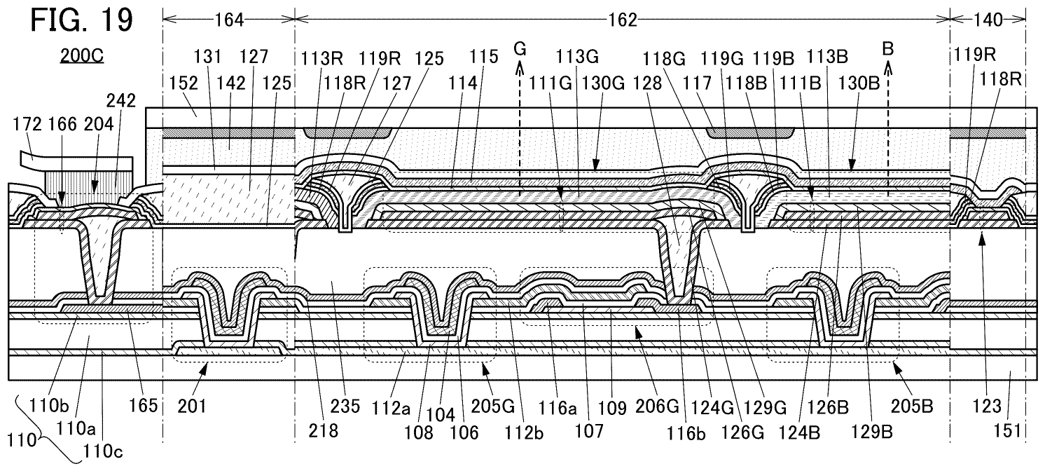

A display apparatus 200C illustrated in FIG. 19 differs from the display apparatus 200A illustrated in FIG. 17 mainly in the structures of the pixel electrode 111R (not illustrated), the pixel electrode 111G, the pixel electrode 111B, the conductive layer 123, and the conductive layer 166 and also in that the insulating layer 237 is not included, the layer 113 covers a top surface and a side surface of the pixel electrode 111, and a common layer 114, an insulating layer 125, and an insulating layer 127 are included.

The light-emitting device 130R (not illustrated) includes the pixel electrode 111R over the insulating layer 235, the island-shaped layer 113R over the pixel electrode 111R, the common layer 114 over the island-shaped layer 113R and the common electrode 115 over the common layer 114. In the light-emitting device 130R, the layer 113R and the common layer 114 can be collectively referred to as an EL layer.

The light-emitting device 130G includes a pixel electrode 111G over the insulating layer 235, the island-shaped layer 113G over the pixel electrode 111G, the common layer 114 over the island-shaped layer 113G, and the common electrode 115 over the common layer 114. In the light-emitting device 130G, the layer 113G and the common layer 114 can be collectively referred to as an EL layer.

The light-emitting device 130B includes the pixel electrode 111B over the insulating layer 235, the island-shaped layer 113B over the pixel electrode 111B, the common layer 114 over the island-shaped layer 113B, and the common electrode 115 over the common layer 114. In the light-emitting device 130B, the layer 113B and the common layer 114 can be collectively referred to as an EL layer.

In this specification and the like, in the EL layers included in the light-emitting devices, the island-shaped layer provided in each light-emitting device is referred to as the layer 113R, the layer 113G, or the layer 113B, and the layer shared by the plurality of light-emitting devices is referred to as the common layer 114. Note that in this specification and the like, only the layer 113R, the layer 113G, and the layer 113B are sometimes referred to as island-shaped EL layers, EL layers formed in an island shape, or the like, in which case the common layer 114 is not included in the EL layer.

For example, the layer 113R, the layer 113G, and the layer 113B may each include a hole-injection layer, a hole-transport layer, a light-emitting layer, and an electron-transport layer in this order. In addition, an electron-blocking layer may be provided between the hole-transport layer and the light-emitting layer. In addition, a hole-blocking layer may be provided between the electron-transport layer and the light-emitting layer. Furthermore, an electron-injection layer may be provided over the electron-transport layer.

Alternatively, the layer 113R, the layer 113G, and the layer 113B may each include an electron-injection layer, an electron-transport layer, a light-emitting layer, and a hole-transport layer in this order, for example. In addition, a hole-blocking layer may be provided between the electron-transport layer and the light-emitting layer. In addition, an electron-blocking layer may be provided between the hole-transport layer and the light-emitting layer. Furthermore, a hole-injection layer may be provided over the hole-transport layer.

Thus, the layer 113R, the layer 113G, and the layer 113B each preferably include the light-emitting layer and a carrier-transport layer (an electron-transport layer or a hole-transport layer) over the light-emitting layer. Alternatively, the layer 113R, the layer 113G, and the layer 113B each preferably include a light-emitting layer and a carrier-blocking layer (a hole-blocking layer or an electron-blocking layer) over the light-emitting layer. Alternatively, the layer 113R, the layer 113G, and the layer 113B each preferably include a light-emitting layer, a carrier-blocking layer over the light-emitting layer, and a carrier-transport layer over the carrier-blocking layer.

The light-emitting device 130R, the light-emitting device 130G, and the light-emitting device 130G may have a tandem structure. In the case of using a tandem structure, preferably, the layer 113R includes a plurality of light-emitting units that emit red light, the layer 113G includes a plurality of light-emitting units that emit green light, and the layer 113B includes a plurality of light-emitting units that emit blue light. A charge-generation layer is preferably provided between the light-emitting units. The layer 113R, the layer 113G, and the layer 113B may include a first light-emitting unit, a charge-generation layer over the first light-emitting unit, and a second light-emitting unit over the charge-generation layer, for example.

It is preferable that the second light-emitting unit include a light-emitting layer and a carrier-transport layer (an electron-transport layer or a hole-transport layer) over the light-emitting layer. Alternatively, the second light-emitting unit preferably includes a light-emitting layer and a carrier-blocking layer (a hole-blocking layer or an electron-blocking layer) over the light-emitting layer. Alternatively, the second light-emitting unit preferably includes a light-emitting layer, a carrier-blocking layer over the light-emitting layer, and a carrier-transport layer over the carrier-blocking layer. Since the surface of the second light-emitting unit is exposed in the fabrication process of the display apparatus, providing one or both of the carrier-transport layer and the carrier-blocking layer over the light-emitting layer inhibits the light-emitting layer from being exposed on the outermost surface, so that damage to the light-emitting layer can be reduced. Thus, the reliability of the light-emitting device can be increased. Note that in the case where three or more light-emitting units are provided, the uppermost light-emitting unit preferably includes a light-emitting layer and one or both of a carrier-transport layer and a carrier-blocking layer over the light-emitting layer.

The common layer 114 includes, for example, an electron-injection layer or a hole-injection layer. Alternatively, the common layer 114 may be a stack of an electron-transport layer and an electron-injection layer, or may be a stack of a hole-transport layer and a hole-injection layer. The common layer 114 is shared by the light-emitting device 130R, the light-emitting device 130G, and the light-emitting device 130B. The common layer 114 can be formed by an evaporation method (including a vacuum evaporation method), a transfer method, a printing method, an inkjet method, or a coating method, for example.

The common layer 114 is not necessarily provided in the connection portion 140. In the structure shown in FIG. 19, the common electrode 115 is provided directly on the conductive layer 123. The structure in which the common layer 114 is provided over the conductive layer 123, and the conductive layer 123 and the common electrode 115 are electrically connected to each other through the common layer 114 may be employed. For example, by using an area mask, the common layer 114 can be formed in a region different from a region where the common electrode 115 is formed.

As illustrated in FIG. 19, the pixel electrode 111G included in the light-emitting device 130G has a stacked structure including a conductive layer 124G, a conductive layer 126G over the conductive layer 124G, and a conductive layer 129G over the conductive layer 126G.

The conductive layer 124G is electrically connected to the conductive layer 116b included in the transistor 206G through an opening provided in the insulating layer 107, the insulating layer 106, the insulating layer 218, and the insulating layer 235.

The end portion of the conductive layer 124G is positioned outside the end portion of the conductive layer 126G. Alternatively, the end portion of the conductive layer 126G is positioned inside the end portion of the conductive layer 129G. The end portion of the conductive layer 124G may be positioned outside the end portion of the conductive layer 129G. In other words, the end portion of the conductive layer 126G is positioned over the conductive layer 124G. The end portion of the conductive layer 129G is positioned over the conductive layer 124G. A top surface and a side surface of the conductive layer 126G are covered with the conductive layer 129G.

For the conductive layer 124G, no particular limitations are imposed on the properties of transmitting and reflecting visible light. As the conductive layer 124G, a conductive layer having a property of transmitting visible light or a conductive layer having a property of reflecting visible light can be used. As a conductive layer having a property of transmitting visible light, a conductive layer including an oxide conductor (also referred to as an oxide conductive layer) can be used, for example. Specifically, an In—Si—Sn oxide (also referred to as ITSO) can be suitably used as the conductive layer 124G. For a conductive layer having a property of reflecting visible light, metal such as aluminum, titanium, chromium, nickel, copper, yttrium, zirconium, silver, tin, zinc, silver, platinum, gold, molybdenum, tantalum, or tungsten, or an alloy containing the metal as its main component (e.g., an alloy of silver, palladium, and copper (Ag—Pd—Cu (APC))) can be used, for example. The conductive layer 124G may have a stacked structure of a conductive layer having a property of transmitting visible light and a conductive layer having a property of reflecting visible light having a property of transmitting visible light over the conductive layer. For the conductive layer 124G, a material with high adhesion to the formation surface of the conductive layer 124G (here, the insulating layer 235) is preferably used. Accordingly, separation of the conductive layer 124G can be inhibited.

A conductive layer having a property of reflecting visible light can be used as the conductive layer 126G. The conductive layer 126G may have a stacked structure of a conductive layer having a property of transmitting visible light and a conductive layer having a property of reflecting visible light having a property of transmitting visible light over the conductive layer. For the conductive layer 126G, the same material as the conductive layer 124G can be used. Specifically, a stacked structure of an In—Si—Sn oxide (ITSO), an alloy of silver, palladium, and copper (APC) over the In—Si—Sn oxide (ITSO) can be suitably used as the conductive layer 126G.

For the conductive layer 129G, the same material as the conductive layer 124G can be used. A conductive layer having a property of transmitting visible light can be used as the conductive layer 129G. Specifically, an In—Si—Sn oxide (ITSO) can be used for the conductive layer 129G.

When a material that is easily oxidized is used for the conductive layer 126G, a material that is not easily oxidized is used for the conductive layer 129G and the conductive layer 126G is covered with the conductive layer 129G, whereby oxidation of the conductive layer 126G can be inhibited. In addition, precipitation of a metal component included in the conductive layer 126G can be inhibited. For example, when a material including silver is used for the conductive layer 126G, an In—Si—Sn oxide (ITSO) can be suitably used for the conductive layer 129G. Thus, oxidation of the conductive layer 126G can be inhibited, and precipitation of silver can be inhibited

A conductive layer 124R (not illustrated), a conductive layer 126R (not illustrated), and a conductive layer 129R (not illustrated) in the light-emitting device 130R, and a conductive layer 124B, a conductive layer 126B, and a conductive layer 129B in the light-emitting device 130B are similar to the conductive layer 124G, the conductive layer 126G, and the conductive layer 129G in the light-emitting device 130G; thus, the detailed description thereof is omitted.

The pixel electrode 111R, the pixel electrode 111G, and the pixel electrode 111B and the conductive layer 123 and the conductive layer 166 illustrated in FIG. 19 and the like can also be applied to other structure examples.

In the conductive layer 124R, the conductive layer 124G, and the conductive layer 124B, a depressed portion is formed to cover the opening provided in the insulating layer 107, the insulating layer 106, the insulating layer 218, and the insulating layer 235. A layer 128 is embedded in the depressed portion.

The layer 128 has a function of flattening the conductive layer 124R, the conductive layer 124G, and the conductive layer 124B. Over the conductive layer 124R, the conductive layer 124G, and the conductive layer 124B and the layer 128, the conductive layer 126R, the conductive layer 126G, and the conductive layer 126B that are respectively electrically connected to the conductive layer 124R, the conductive layer 124G, and the conductive layer 124B are provided. Thus, in the light-emitting devices 130, the regions overlapping with the depressed portions of the conductive layer 124R, the conductive layer 124G, and the conductive layer 124B can also function as light-emitting regions, whereby the aperture ratio of the pixel can be increased.

The layer 128 may be an insulating layer or a conductive layer. Any of a variety of inorganic insulating materials, organic insulating materials, and conductive materials can be used for the layer 128 as appropriate. In particular, the layer 128 is preferably formed using an organic material. In particular, a photosensitive organic resin is preferably used as the organic material. For example, a photosensitive resin composition containing an acrylic resin is suitably used for the layer 128.

When the layer 128 is a conductive layer, the layer 128 can serve as part of a pixel electrode. For the layer 128, for example, an organic resin in which metal particles are dispersed can be used.

The layer 128 illustrated in FIG. 19 and the like can be applied to other structure examples.

FIG. 19 illustrates an example where the end portion of the layer 113G is positioned on the outer side of the end portion of the pixel electrode 111G. The layer 113G is formed to cover the end portion of the pixel electrode 111G. Such a structure enables the entire top surface of the pixel electrode to be a light-emitting region, and the aperture ratio can be increased as compared with the structure where the end portion of the island-shaped EL layer is positioned on the inner side of the end portion of the pixel electrode. Covering the side surface of the pixel electrode 111 with the EL layer inhibits contact between the pixel electrode 111 and the common electrode 115, thereby inhibiting a short-circuit of the light-emitting device 130. Note that although the pixel electrode 111G and the layer 113G are given as an example, the following description applies to the pixel electrode 111R and the layer 113R, and the pixel electrode 111B and the layer 113B.

An insulating layer (see the insulating layer 237 in FIG. 17) covering an end portion of the top surface of the pixel electrode 111G is not provided between the pixel electrode 111G and the layer 113G. An insulating layer covering an end portion of the top surface of the pixel electrode 111B is not provided between the pixel electrode 111B and the layer 113B. Thus, the distance between adjacent light-emitting devices can be shortened. Accordingly, the display apparatus can have a high resolution or a high definition. In addition, a mask for forming the insulating layer is not needed, which leads to a reduction in manufacturing cost of the display apparatus.

The EL layer can be formed by a photolithography method, for example. Specifically, a film to be the light-emitting layers is formed across a plurality of pixel electrodes that have been formed independently for respective subpixels. Then, the film is processed by a photolithography method so that one island-shaped light-emitting layer is formed for every pixel electrode. Thus, the light-emitting layer can be divided into island-shaped light-emitting layers for respective subpixels. A photolithography method enables a miniaturized EL layer to be formed. When the EL layer is provided in an island shape for each light-emitting device, a leakage current between adjacent light-emitting devices can be inhibited. This can prevent crosstalk due to unintended light emission, so that a display apparatus with extremely high contrast can be obtained. Specifically, a display apparatus having high current efficiency at low luminance can be obtained.

The upper temperature limit of the compounds contained in the layer 113R, the layer 113G, and the layer 113B is preferably higher than or equal to 100° C. and lower than or equal to 180° C., further preferably higher than or equal to 120° C. and lower than or equal to 180° C., still further preferably higher than or equal to 140° C. and lower than or equal to 180° C. For example, the glass transition point (Tg) of these compounds is preferably higher than or equal to 100° C. and lower than or equal to 180° C., further preferably higher than or equal to 120° C. and lower than or equal to 180° C., still further preferably higher than or equal to 140° C. and lower than or equal to 180° C. This inhibits a reduction in light emission efficiency and a decrease in lifetime which are due to damage to the layer 113R, the layer 113G, and the layer 113B by heat applied in a fabrication process.

In a region between adjacent light-emitting devices 130, the insulating layer 125 and the insulating layer 127 over the insulating layer 125 are provided. Although FIG. 19 illustrates cross sections of a plurality of insulating layers 125 and a plurality of insulating layers 127, the insulating layers 125 and the insulating layers 127 are each a continuous layer when the display apparatus 200C is seen from above. In other words, the display apparatus 200C can have a structure including one insulating layer 125 and one insulating layer 127, for example. Note that the display apparatus 200C may include a plurality of insulating layers 125 that are separated from each other and a plurality of insulating layers 127 that are separated from each other.

The insulating layer 125 is preferably in contact with the side surfaces of the layer 113R, the layer 113G, and the layer 113B. The insulating layer 125 in contact with the layer 113R, the layer 113G, and the layer 113B can prevent separation of the layer 113R, the layer 113G, and the layer 113B. When the insulating layer 125 is in close contact with the layer 113R, the layer 113G, and the layer 113B, adjacent layers 113 and the like can be fixed or bonded to each other by the insulating layer 125. Thus, the reliability of the light-emitting device can be increased. The fabrication yield of the light-emitting devices can also be improved.

The insulating layer 125 can be formed using an inorganic material. For the insulating layer 125, one or more of an oxide, an oxynitride, a nitride oxide, and a nitride can be used, for example. The insulating layer 125 may have a single-layer structure or a stacked-layer structure. Examples of the oxide include silicon oxide, aluminum oxide, magnesium oxide, indium-gallium-zinc oxide, gallium oxide, germanium oxide, yttrium oxide, zirconium oxide, lanthanum oxide, neodymium oxide, hafnium oxide, and tantalum oxide. Examples of the nitride include silicon nitride and aluminum nitride. Examples of the oxynitride include silicon oxynitride and aluminum oxynitride. Examples of the nitride oxide include silicon nitride oxide and aluminum nitride oxide. In particular, aluminum oxide is preferably used because it has high selectivity with respect to the EL layer in etching and has a function of protecting the EL layer.

The insulating layer 125 preferably has a function of a barrier insulating layer against at least one of water and oxygen. The insulating layer 125 preferably has a function of inhibiting diffusion of at least one of water and oxygen. Alternatively, the insulating layer 125 preferably has a function of capturing or fixing (also referred to as gettering) at least one of water and oxygen. Note that in this specification and the like, a barrier insulating layer refers to an insulating layer having a barrier property. A barrier property in this specification and the like means a function of inhibiting diffusion of a particular substance (also referred to as a function of less easily transmitting the substance).

When the insulating layer 125 has a function of the barrier insulating layer or a gettering function, entry of impurities (typically, at least one of water and oxygen) that would diffuse into the light-emitting devices from the outside can be inhibited. With this structure, a highly reliable light-emitting device and a highly reliable display apparatus can be provided.

The insulating layer 127 is provided over the insulating layer 125 to fill a depressed portion formed in the insulating layer 125. The insulating layer 127 can overlap with the side surface and part of the top surface of each of the layer 113R, the layer 113G, and the layer 113B with the insulating layer 125 therebetween. The insulating layer 127 preferably covers at least part of the side surface of the insulating layer 125. The insulating layer 125 and the insulating layer 127 can fill a gap between the adjacent island-shaped layers, whereby unevenness of the surface where the layers (e.g., the carrier-injection layer and the common electrode) provided over the island-shaped layers are formed can be reduced and the coverage with the layers can be improved. The top surface of the insulating layer 127 preferably has a shape with higher flatness, but may include a projection portion, a convex surface, a concave surface, or a depressed portion.

As the insulating layer 127, an insulating layer containing an organic material can be suitably used. As the organic material, a photosensitive organic resin is preferably used, and for example, a photosensitive resin composite containing an acrylic resin is preferably used.

Alternatively, the insulating layer 127 may be formed using an acrylic resin, a polyimide resin, an epoxy resin, an imide resin, a polyamide resin, a polyimide-amide resin, a silicone resin, a siloxane resin, a benzocyclobutene-based resin, a phenol resin, precursors of these resins, or the like. Alternatively, the insulating layer 127 may be formed using an organic material such as polyvinyl alcohol (PVA), polyvinyl butyral, polyvinylpyrrolidone, polyethylene glycol, polyglycerin, pullulan, water-soluble cellulose, or an alcohol-soluble polyamide resin. A photoresist may be used for the photosensitive resin. As the photosensitive organic resin, either a positive-type material or a negative-type material may be used.

The insulating layer 127 may be formed using a material absorbing visible light. When the insulating layer 127 absorbs light emitted from the light-emitting device, leakage of light (stray light) from the light-emitting device to the adjacent light-emitting device through the insulating layer 127 can be inhibited. Thus, the display quality of the display apparatus can be improved. Since no polarizing plate is required to improve the display quality of the display apparatus, the weight and thickness of the display apparatus can be reduced.

Examples of the material absorbing visible light include materials containing pigment of black or the like, materials containing dye, light-absorbing resin materials (e.g., polyimide), and resin materials that can be used for color filters (color filter materials). Using the resin material obtained by stacking or mixing color filter materials of two or three or more colors is particularly preferred, in which case the effect of blocking visible light is enhanced. In particular, mixing color filter materials of three or more colors enables the formation of a black or nearly black resin layer.

A mask layer 118R and a mask layer 119R are positioned over the layer 113R included in the light-emitting device 130R, a mask layer 118G and a mask layer 119G are positioned over the layer 113G included in the light-emitting device 130G, and a mask layer 118B and a mask layer 119B are positioned over the layer 113B included in the light-emitting device 130B. The mask layer 118 and the mask layer 119 are provided to surround the light-emitting region. In other words, the mask layer 118 and the mask layer 119 have an opening in a portion overlapping with the light-emitting region. The mask layer 118R and the mask layer 119R are remaining parts of the mask layers provided over the layer 113R at the time of processing the layer 113R. In a similar manner, the mask layer 118G and the mask layer 119G are remaining parts of the mask layers at the time of forming the layer 113G, and the mask layer 118B and the mask layer 119B are remaining parts of the mask layers provided at the time of forming the layer 113B. Thus, the mask layer used to protect the EL layer in the fabrication of the display apparatus may partly remain in the display apparatus of one embodiment of the present invention.

The common layer 114 and the common electrode 115 are provided over the layer 113R, the layer 113G, and the layer 113B, the mask layer 118 and the mask layer 119, and the insulating layer 125 and the insulating layer 127. Before the insulating layer 125 and the insulating layer 127 are provided, a step is generated due to a difference between a region where the pixel electrode and the island-shaped EL layer are provided and a region where neither the pixel electrode nor the island-shaped EL layer is provided (region between the light-emitting devices). In the display apparatus of one embodiment of the present invention, the step can be reduced with the insulating layer 125 and the insulating layer 127, and the coverage with the common layer 114 and the common electrode 115 can be improved. Thus, connection defects caused by step disconnection of the common layer 114 and the common electrode 115 can be inhibited. In addition, an increase in the electric resistance of the common electrode 115, which is caused by local thinning of the common electrode 115 due to the level difference, can be inhibited.

The insulating layer 127 may cover at least part of the side surface of the insulating layer 125, a side surface of the mask layer 118R, a side surface of the mask layer 119R, a side surface of the mask layer 118G, a side surface of the mask layer 119G, a side surface of the mask layer 118B, and a side surface of the mask layer 119B. The insulating layer 127 may include regions in contact with the layer 113R, the layer 113G, and the layer 113B.

### Display Apparatus 200D

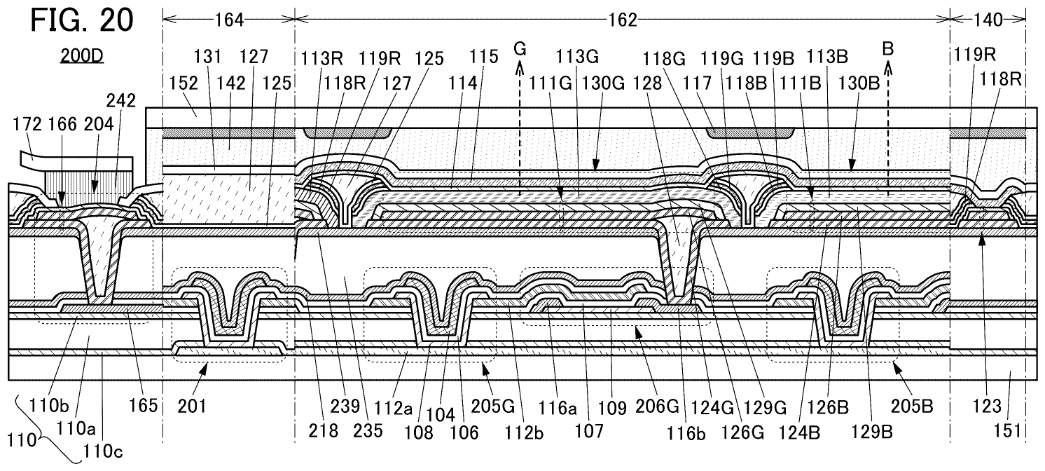

A display apparatus 200D illustrated in FIG. 20 differs from the display apparatus 200C illustrated in FIG. 19 mainly in including an insulating layer 239.

The insulating layer 239 is provided over the insulating layer 235 and includes an opening in a region overlapping with the opening in the insulating layer 235. The pixel electrode 111 is provided to cover the opening provided in the insulating layer 239, the insulating layer 235, the insulating layer 218, the insulating layer 106, and the insulating layer 107.

The insulating layer 239 can function as an etching protective film when the layer 113, the mask layer 118, and the mask layer 119 are formed. The insulating layer 239 can prevent generation of unevenness in the insulating layer 235 caused by etching of part of the insulating layer 235 at the time when the layer 113, the mask layer 118, and the mask layer 119 are formed. Thus, steps in the formation surface of the insulating layer 125 become small, whereby the coverage with the insulating layer 125 can be increased. Consequently, the side surface of the layer 113 is covered with the insulating layer 125, which inhibits separation of the layer 113.

The insulating layer 239 can be an insulating layer including an inorganic material. As the insulating layer 239, an inorganic insulating film such as an oxide insulating film, a nitride insulating film, an oxynitride insulating film, or a nitride oxide insulating film can be used, for example. The insulating layer 239 may have a single-layer structure or a stacked-layer structure. Examples of the oxide insulating film include a silicon oxide film, an aluminum oxide film, a magnesium oxide film, an indium-gallium-zinc oxide film, a gallium oxide film, a germanium oxide film, an yttrium oxide film, a zirconium oxide film, a lanthanum oxide film, a neodymium oxide film, a hafnium oxide film, and a tantalum oxide film. Examples of the nitride insulating film include a silicon nitride film and an aluminum nitride film. Examples of the oxynitride insulating film include a silicon oxynitride film and an aluminum oxynitride film. Examples of the nitride oxide insulating film include a silicon nitride oxide film and an aluminum nitride oxide film. A silicon oxide film or a silicon oxynitride film can be suitably used as the insulating layer 239, for example.

For the insulating layer 239, it is preferable to select a material having a high etching rate (also referred to as high selectivity) with respect to films to be the layer 113, the mask layer 118, and the mask layer 119 in etching of the films.

The low flatness of the formation surface of the light-emitting device 130, might cause a defect, such as a connection defect due to disconnection of the common electrode 115 or an increase in electric resistance due to the locally thinned regions of the common electrode 115. In addition, the processing accuracy of the layer to be formed on the formation surface might be lowered.

In the display apparatus of one embodiment of the present invention, the formation surface of the light-emitting device 130 can be made flatter by providing the insulating layer 239. Accordingly, the processing accuracy of the light-emitting device 130 and the like provided over the insulating layer 239 is increased, whereby the display apparatus can have high resolution. Furthermore, since a connection defect due to disconnection of the common electrode 115 and an increase in electric resistance due to local thinning of the common electrode 115 can be prevented, the display apparatus can have high display quality.

Although the insulating layer 239 has a single-layer structure in FIG. 20, one embodiment of the present invention is not limited thereto. The insulating layer 239 may have a stacked-layer structure.

In the region that does not overlap with any of the layer 113R, the layer 113G, and the layer 113B, part of the insulating layer 239 may be removed. The thickness of the insulating layer 239 in the region that does not overlap with any of the layer 113R, the layer 113G, and the layer 113B may be smaller than the thickness of the insulating layer 239 in the region that overlaps with the layer 113R, the layer 113G, or the layer 113B.

The insulating layer 239 can be applied to other structure examples.

### Display Apparatus 200E

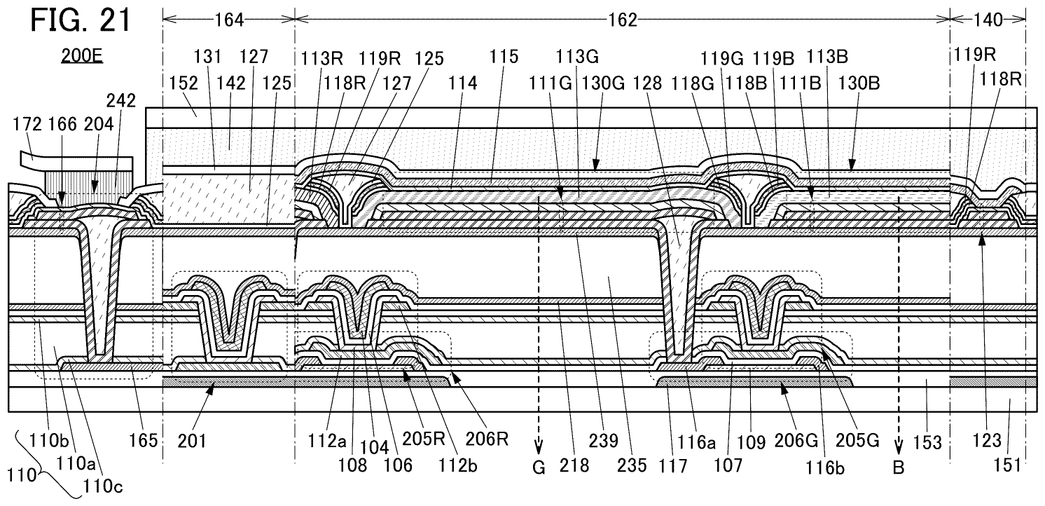

A display apparatus 200E illustrated in FIG. 21 differs from the display apparatuses illustrated in FIG. 17 to FIG. 20 in the arrangement of the transistor 205 and the transistor 206. The display apparatus 200E differs from the display apparatus 200D illustrated in FIG. 20 mainly in having a bottom-emission structure.

In the display apparatuses illustrated in FIG. 17 to FIG. 20, the transistor 205 and the transistor 206 are adjacent to each other to form the positional relationship in the semiconductor device 10 illustrated in FIG. 1A and FIG. 1B as a whole. Meanwhile, in the display apparatus 200E, the transistor 205 is placed over and overlaps with the transistor 206 to form the positional relationship in the semiconductor device 10A illustrated in FIG. 2A and FIG. 2B as a whole. In a bottom-emission display apparatus, light emitted by light-emitting devices is emitted toward the substrate 151. Thus, the positional relationship between the transistor 205 and the transistor 206 in the semiconductor device 10A increases the aperture ratio of the display apparatus more significantly than that in the semiconductor device 10.

As described above, light from the light-emitting device is emitted toward the substrate 151. For the substrate 151, a material having a high visible-light-transmitting property is preferably used. By contrast, there is no limitation on the light-transmitting property of a material used for the substrate 152.

The light-blocking layer 117 is preferably formed between the substrate 151 and the transistor 201 and between the substrate 151 and the transistors 205 and 206. FIG. 21 shows an example in which the light-blocking layer 117 is provided over the substrate 151, an insulating layer 153 is provided over the light-blocking layer 117, and the transistor 201, the transistor 205R, the transistor 206R, the transistor 205G, and the transistor 206G are provided over the insulating layer 153.

A material having a high visible-light-transmitting property is used for each of the pixel electrode 111R (not illustrated), the pixel electrode 111G, and the pixel electrode 111B. A material that reflects visible light is preferably used for the common electrode 115.

### Display Apparatus 200F

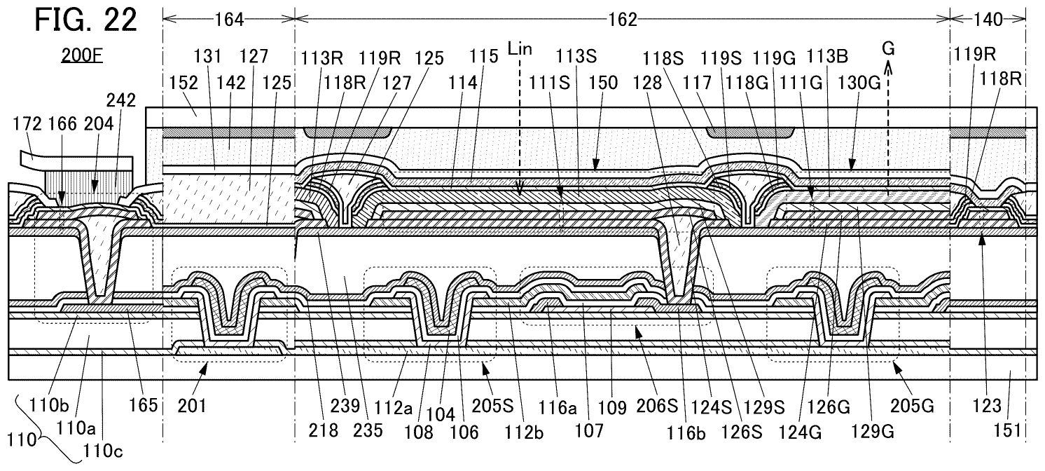

A display apparatus 200F illustrated in FIG. 22 differs from the display apparatus 200D illustrated in FIG. 20 mainly in including a light-receiving device 150.

As the light-receiving device 150, a pn photodiode or a pin photodiode can be used, for example. The light-receiving device 150 functions as a photoelectric conversion device (also referred to as a photoelectric conversion element) that senses light entering the light-receiving device and generate electric charge. The amount of electric charge generated from the light-receiving device 150 depends on the amount of light entering the light-receiving device 150.

The light-receiving device 150 can detect one or both of visible light and infrared light. In the case of sensing visible light, for example, one or more of blue light, violet light, bluish violet light, green light, yellowish green light, yellow light, orange light, red light, and the like can be detected. The infrared light is preferably detected because an object can be detected even in a dark environment.

It is particularly preferable to use an organic photodiode including a layer containing an organic compound as the light-receiving device 150. An organic photodiode, which is easily made thin, lightweight, and large in area and has a high degree of freedom for shape and design, can be used in a variety of display apparatuses.

In one embodiment of the present invention, an organic EL device is used as the light-emitting device 130, and an organic photodiode is used as the light-receiving device 150. The organic EL device and the organic photodiode can be formed over the same substrate. Thus, the organic photodiode can be incorporated into the display apparatus including the organic EL device.

The light-receiving device 150 is driven by application of reverse bias between a pixel electrode 111S and the common electrode 115, whereby light entering the light-receiving device can be detected and electric charge can be generated and extracted as a current.

In FIG. 22, the light G, which is emitted toward the substrate 152 from the light-emitting device 130G, and light Lin, which enters the light-receiving device 150 through the substrate 152, are indicated by arrows of dashed lines.

A fabrication method similar to that of the light-emitting device 130 can be employed for the light-receiving device 150. An island-shaped active layer (also referred to as a photoelectric conversion layer) included in the light-receiving device can be formed with a fine metal mask, for example. The active layer can be formed by a photolithography method instead of the method with a fine metal mask. In the photolithography method, a film that is to be the active layer is processed after formed on the entire surface, and accordingly the island-shaped active layer with a uniform thickness can be formed. Moreover, providing the mask layer over the active layer can reduce damage to the active layer in the fabrication process of the display apparatus, resulting in an improvement in reliability of the light-receiving device. A structure example in which the active layer is formed by the photolithography method is described.

The light-receiving device 150 includes the pixel electrode 111S, a layer 113S, the common layer 114, and the common electrode 115. The layer 113S includes at least an active layer. The pixel electrode 111S has a stacked structure of a conductive layer 124S, a conductive layer 126S over the conductive layer 124S, and a conductive layer 129S over the conductive layer 126S. The pixel electrode 111S can be formed in the same process as the pixel electrode 111R (not illustrated), the pixel electrode 111G, and the pixel electrode 111B (not illustrated).

The pixel electrode 111S is electrically connected to the conductive layer 116b included in a transistor 206S. A transistor 205S can be fabricated in the same process as the transistor 205R, the transistor 205G, and the transistor 205B. The transistor 206S can be fabricated in the same process as the transistor 206R, the transistor 206G, and the transistor 206B. The insulating layer 235, the insulating layer 218, the insulating layer 106, and the insulating layer 107 include an opening in a region overlapping with the conductive layer 116b included in the transistor 206S. The pixel electrode 111S included in the light-receiving device 150 is provided to cover the opening. The conductive layer 116b included in the transistor 206S is electrically connected to the pixel electrode 111S through the opening. The layer 113S is provided over the pixel electrode 111S. The common layer 114 is provided over the layer 113S, and the common electrode 115 is provided over the common layer 114. The common layer 114 is a continuous layer shared between the light-receiving device 150 and the light-emitting device 130.

Here, the layer 113S includes at least an active layer, preferably includes a plurality of functional layers. Examples of the functional layer include carrier-transport layers (a hole-transport layer and an electron-transport layer) and carrier-blocking layers (a hole-blocking layer and an electron-blocking layer). In addition, one or more layers are preferably formed over the active layer. A layer between the active layer and the mask layer can inhibit the active layer from being exposed on the outermost surface during the fabrication process of the display apparatus and can reduce damage to the active layer. Accordingly, the reliability of the light-receiving device 150 can be increased. Thus, the layer 113S preferably includes an active layer and a carrier-blocking layer (a hole-blocking layer or an electron-blocking layer) or a carrier-transport layer (an electron-transport layer or a hole-transport layer) over the active layer.

The layer 113S is a layer that is provided in the light-receiving device 150 and is not provided in the light-emitting device 130. Note that the functional layer other than the active layer in the layer 113S may include the same material as the functional layer other than the light-emitting layer in the layer 113R, the layer 113G, or the layer 113B. Meanwhile, the common layer 114 is a continuous layer shared by the light-emitting device 130 and the light-receiving device 150.

Here, a layer shared by the light-receiving device and the light-emitting device may have a different function in the light-emitting device and the light receiving device. In this specification, the name of a component is based on its function in the light-emitting device in some cases. For example, a hole-injection layer functions as a hole-injection layer in the light-emitting device and functions as a hole-transport layer in the light-receiving device. Similarly, an electron-injection layer functions as an electron-injection layer in the light-emitting device and functions as an electron-transport layer in the light-receiving device. A layer shared by the light-receiving device and the light-emitting device may have the same function in both the light-emitting device and the light-receiving device. For example, the hole-transport layer functions as a hole-transport layer in both the light-emitting device and the light-receiving device, and the electron-transport layer functions as an electron-transport layer in both the light-emitting device and the light-receiving device.

The insulating layer 125 and the insulating layer 127 over the insulating layer 125 are provided in a region between the light-emitting device 130 and the light-receiving device 150 adjacent to each other.

The mask layer 118R and the mask layer 119R are positioned between the layer 113R and the insulating layer 125, and a mask layer 118S and a mask layer 119S are positioned between the layer 113S and the insulating layer 125. The mask layer 118R and the mask layer 119R are remaining parts of the mask layer provided over the layer 113R at the time of processing the layer 113R. The mask layer 118S and the layer 119S are remaining parts of a mask layer provided in contact with the top surface of the layer 113S at the time of processing the layer 113S, which is a layer including the active layer. The mask layer 118R and the mask layer 118S may contain the same material or different materials. The mask layer 119R and the mask layer 119S may contain the same material or different materials.

This embodiment can be combined with any of the other embodiments or an example as appropriate.

### Embodiment 3

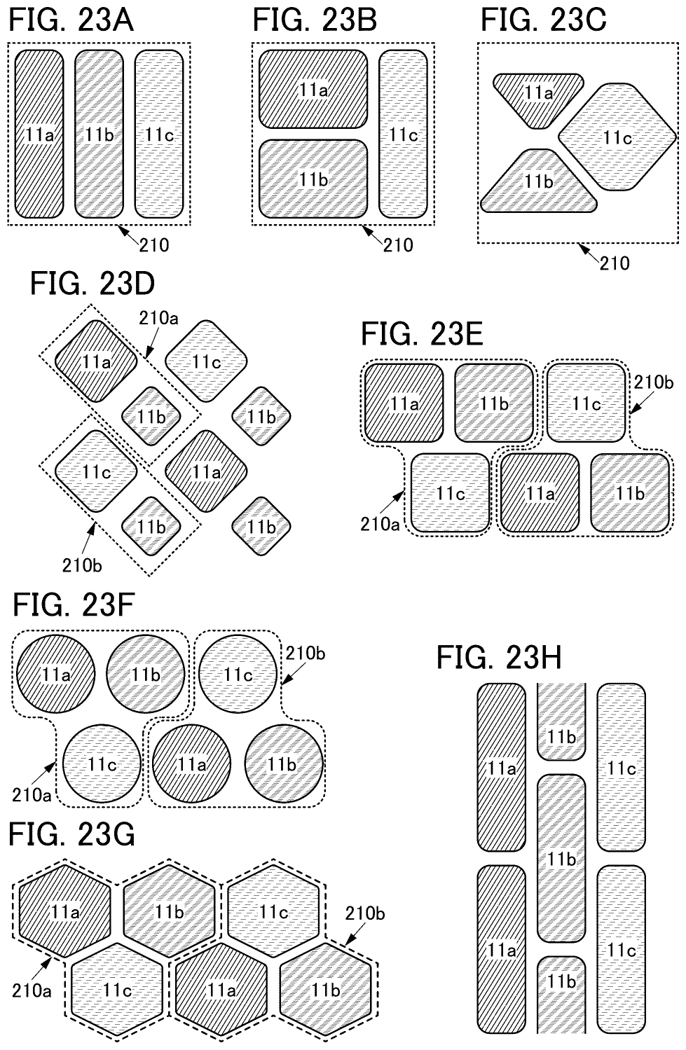

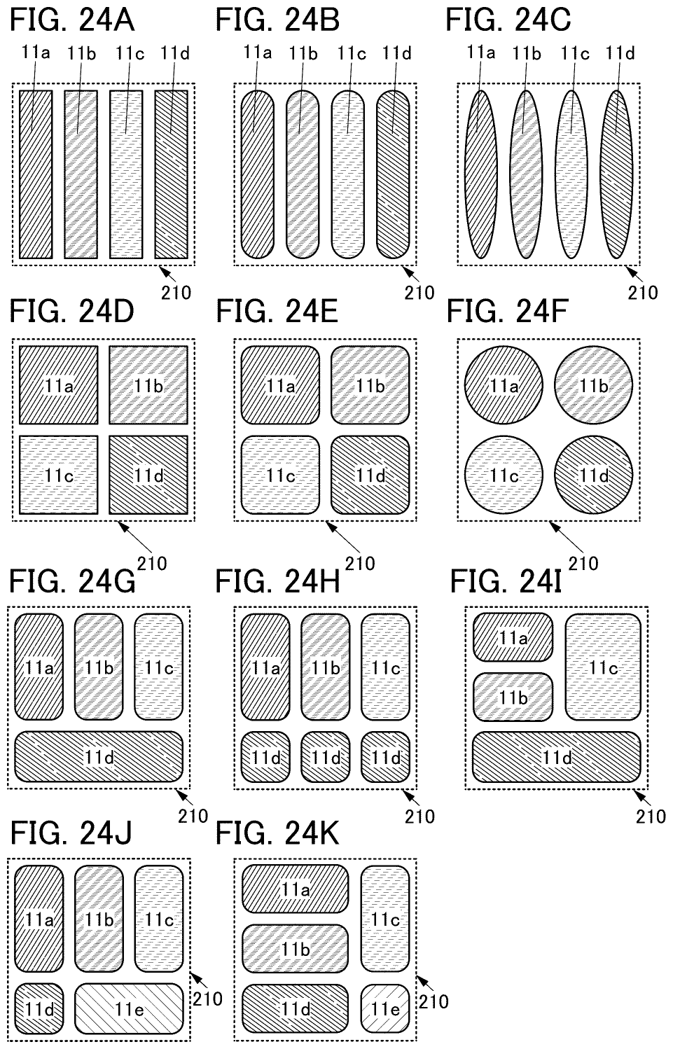

In this embodiment, a display apparatus of one embodiment of the present invention is described with reference to FIG. 23A to FIG. 24K.

A pixel layout is described. There is no particular limitation on the arrangement of subpixels, and any of a variety of methods can be employed. Examples of the arrangement of subpixels include stripe arrangement, S-stripe arrangement, matrix arrangement, delta arrangement, Bayer arrangement, and PenTile arrangement.

Examples of a planar shape of the subpixel include polygons such as a triangle, a tetragon (including a rectangle and a square), and a pentagon; polygons with rounded corners; an ellipse; and a circle. The planar shape of the subpixel corresponds to a planar shape of a light-emitting region of a light-emitting device or a light-receiving region of a light-receiving device.

A pixel 210 illustrated in FIG. 23A employs S-stripe arrangement. The pixel 210 is composed of three kinds of subpixels: a subpixel 11a, a subpixel 11b, and a subpixel 11c. The subpixel 11a, the subpixel 11b, and the subpixel 11c emit light of different colors. The subpixel 11a, the subpixel 11b, and the subpixel 11c are subpixels of three colors of red (R), green (G), and blue (B) or subpixels of three colors of yellow (Y), cyan (C), and magenta (M), for example. The number of colors of subpixels is not limited to three and may be four or more. As the subpixels of four colors, subpixels of four colors of R, G, B, and white (W), subpixels of four colors of R, G, B, and Y, or four subpixels of R, G, B, and infrared light (IR) can be given, for example.

Each subpixel includes a pixel circuit that controls a light-emitting device. The pixel circuits are not necessarily placed in the ranges of the subpixels illustrated in FIG. 23A and may be placed outside the subpixels. For example, transistors included in a pixel circuit of the subpixel 11a may be positioned within the range of the subpixel 11a illustrated in FIG. 23A, or some or all of the transistors may be positioned outside the range of the subpixel 11a.

Although the subpixel 11a, the subpixel 11b, and the subpixel 11c have the same or substantially the same aperture ratio (also referred to as size or size of a light-emitting region) in FIG. 23A, one embodiment of the present invention is not limited thereto. The aperture ratio of each of the subpixel 11a, the subpixel 11b, and the subpixel 11c can be determined as appropriate. The subpixel 11a, the subpixel 11b, and the subpixel 11c may have different aperture ratios, or two or more of the subpixel 11a, the subpixel 11b, and the subpixel 11c may have the same or substantially the same aperture ratio.

The pixel 210 illustrated in FIG. 23B employs S-stripe arrangement. The pixel 210 illustrated in FIG. 23B is composed of three types of subpixels: the subpixel 11a, the subpixel 11b, and the subpixel 11c; two subpixels (the subpixel 11a and the subpixel 11b) are included in the left column (first column); and one subpixel (the subpixel 11c) is included in the right column (second column).

The pixel 210 illustrated in FIG. 23C includes the subpixel 11a whose planar shape is a rough trapezoid with rounded corners, the subpixel 11b whose planar shape is a rough triangle with rounded corners, and the subpixel 11c whose planar shape is a rough tetragon or a rough hexagon with rounded corners. The subpixel 11a has a smaller light-emitting area than the subpixel 11b. In this manner, the shapes and sizes of the subpixels can be determined independently. For example, the size of a subpixel including a light-emitting device with higher reliability can be smaller.

Pixel 210a and pixel 210b illustrated in FIG. 23D employ PenTile arrangement. FIG. 23D illustrates an example in which the pixels 210a including the subpixel 11a and the subpixel 11b and the pixels 210b including the subpixel 11b and the subpixel 11c are alternately arranged.

The pixel 210a and the pixel 210b illustrated in FIG. 23E to FIG. 23G employ delta arrangement. The pixel 210a includes two subpixels (the subpixel 11a and the subpixel 11b) in the upper row (first row) and one subpixel (the subpixel 11c) in the lower row (second row). The pixel 210b includes one subpixel (the subpixel 11c) in the upper row (first row) and two subpixels (the subpixel 11a and the subpixel 11b) in the lower row (second row).

FIG. 23E illustrates an example in which each subpixel has a rough tetragonal planar shape with rounded corners, FIG. 23F illustrates an example in which each subpixel has a circular planar shape, and FIG. 23G illustrates an example in which each subpixel has a rough hexagonal planar shape with rounded corners.

In FIG. 23G, subpixels are placed in respective hexagonal regions that are arranged densely. Focusing on one of the subpixels, the subpixel is placed so as to be surrounded by six subpixels. The subpixels are arranged such that subpixels that emit light of the same color are not adjacent to each other. For example, focusing on the subpixel 11a, three subpixels 11b and three subpixels 11c are arranged to surround the subpixel 11a, so that the subpixel 11a, the subpixel 11b, and the subpixel 11c are alternately arranged.

FIG. 23H illustrates an example in which subpixels of different colors are arranged in a zigzag manner. Specifically, the positions of the top sides of two subpixels arranged in the column direction (e.g., the subpixel 11a and the subpixel 11b, or the subpixel 11b and the subpixel 11c) are not aligned in a plan view.

For example, in each pixel illustrated in FIG. 23A to FIG. 23H, it is preferable that the subpixel 11a be a subpixel R emitting red light, the subpixel 11b be a subpixel G emitting green light, and the subpixel 11c be a subpixel B emitting blue light. Note that the structure of the subpixels is not limited to this, and the colors and arrangement order of the subpixels can be determined as appropriate. For example, the subpixel 11b may be the subpixel R emitting red light and the subpixel 11a may be the subpixel G emitting green light.

In a photolithography method, as a pattern to be processed becomes finer, the influence of light diffraction becomes more difficult to ignore; therefore, the fidelity in transferring a photomask pattern by light exposure is degraded, and it becomes difficult to process a resist mask into a desired shape. Thus, a pattern with rounded corners is likely to be formed even with a rectangular photomask pattern. Consequently, the planar shape of a subpixel may be a polygon with rounded corners, an ellipse, a circle, or the like.

Note that to obtain a desired planar shape of the subpixel, a technique of correcting a mask pattern in advance so that a transferred pattern agrees with a design pattern (OPC (Optical Proximity Correction) technique) may be used. Specifically, with the OPC technique, a pattern for correction is added to a corner portion or the like of a figure on a mask pattern.

As illustrated in FIG. 24A to FIG. 24I, the pixel can include four types of subpixels.

The pixels 210 illustrated in FIG. 24A to FIG. 24C employ stripe arrangement.

FIG. 24A illustrates an example in which each subpixel has a rectangular planar shape, FIG. 24B illustrates an example in which each subpixel has a planar shape formed by combining two half circles and a rectangle, and FIG. 24C illustrates an example in which each subpixel has an elliptical planar shape.

The pixels 210 illustrated in FIG. 24D to FIG. 24F employ matrix arrangement.

FIG. 24D illustrates an example in which each subpixel has a square planar shape, FIG. 24E illustrates an example in which each subpixel has a rough square planar shape with rounded corners, and FIG. 24F illustrates an example in which each subpixel has a circular planar shape.

FIG. 24G and FIG. 24H each illustrate an example in which one pixel 210 is composed of two rows and three columns.

The pixel 210 illustrated in FIG. 24G includes three subpixels (the subpixel 11a, the subpixel 11b, and the subpixel 11c) in the upper row (first row) and one subpixel (a subpixel 11d) in the lower row (second row). In other words, the pixel 210 includes the subpixel 11a in the left column (first column), the subpixel 11b in the center column (second column), the subpixel 11c in the right column (third column), and the subpixel 11d across these three columns.

The pixel 210 illustrated in FIG. 24H includes three subpixels (the subpixel 11a, the subpixel 11b, and the subpixel 11c) in the upper row (first row) and three subpixels 11d in the lower row (second row). In other words, the pixel 210 includes the subpixel 11a and the subpixel 11d in the left column (first column), the subpixel 11b and the subpixel 11d in the center column (second column), and the subpixel 11c and the subpixel 11d in the right column (third column). Matching the positions of the subpixels in the upper row and the lower row as illustrated in FIG. 24H enables efficient removal of dust and the like that would be produced in the manufacturing process. Thus, a display apparatus with high display quality can be provided.

FIG. 24I illustrates an example in which one pixel 210 is composed of three rows and two columns.

The pixel 210 illustrated in FIG. 24I includes the subpixel 11a in the upper row (first row), the subpixel 11b in the center row (second row), the subpixel 11c across the first and second rows, and one subpixel (the subpixel 11d) in the lower row (third row). In other words, the pixel 210 includes the subpixel 11a and the subpixel 11b in the left column (first column), the subpixel 11c in the right column (second column), and the subpixel 11d across these two columns.

The pixel 210 illustrated in FIG. 24A to FIG. 24I are each composed of four subpixels: the subpixel 11a, the subpixel 11b, the subpixel 11c, and the subpixel 11d.

The subpixel 11a, the subpixel 11b, the subpixel 11c, and the subpixel 11d can include light-emitting devices that emit light of different colors. The subpixel 11a, the subpixel 11b, the subpixel 11c, and the subpixel 11d are subpixels of four colors of R, G, B, and white (W), subpixels of four colors of R, G, B, and Y, or subpixels of four colors of R, G, B, and infrared light (IR), for example.

In the pixels 210 illustrated in FIG. 24A to FIG. 24I, it is preferable that the subpixel 11a be the subpixel R emitting red light, the subpixel 11b be the subpixel G emitting green light, the subpixel 11c be the subpixel B emitting blue light, and the subpixel 11d be any of a subpixel W emitting white light, a subpixel Y emitting yellow light, and a subpixel IR emitting near-infrared light, for example. In the case of such a structure, stripe arrangement is employed as the layout of R, G, and B in the pixels 210 illustrated in FIG. 24G and FIG. 24H, leading to higher display quality. In addition, what is called S-stripe arrangement is employed as the layout of R, G, and B in the pixel 210 illustrated in FIG. 24I, leading to higher display quality.

The pixel 210 may include a subpixel including a light-receiving device.

In the pixels 210 illustrated in FIG. 24A to FIG. 24I, any one of the subpixel 11a to the subpixel 11d may be a subpixel including a light-receiving device.

In the pixels 210 illustrated in FIG. 24A to FIG. 24I, for example, it is preferable that the subpixel 11a be the subpixel R emitting red light, the subpixel 11b be the subpixel G emitting green light, the subpixel 11c be the subpixel B emitting blue light, and the subpixel 11d be a subpixel S including a light-receiving device. In the case of such a structure, stripe arrangement is employed as the layout of R, G, and B in the pixels 210 illustrated in FIG. 24G and FIG. 24H, leading to higher display quality. In addition, what is called S-stripe arrangement is employed as the layout of R, G, and B in the pixel 210 illustrated in FIG. 24I, leading to higher display quality.

There is no particular limitation on the wavelength of light detected by the subpixel S including a light-receiving device. The subpixel S can have a structure in which one or both of visible light and infrared light are detected.

As illustrated in FIG. 24J and FIG. 24K, the pixel can include five types of subpixels.

FIG. 24J illustrates an example in which one pixel 210 is composed of two rows and three columns.

The pixel 210 illustrated in FIG. 24J includes three subpixels (the subpixel 11a, the subpixel 11b, and the subpixel 11c) in the upper row (first row) and two subpixels (the subpixel 11d and a subpixel 11e) in the lower row (second row). In other words, the pixel 210 includes the subpixel 11a and the subpixel 11d in the left column (first column), the subpixel 11b in the center column (second column), the subpixel 11c in the right column (third column), and the subpixel 11e across the second and third columns.

FIG. 24K illustrates an example in which one pixel 210 is composed of three rows and two columns.

The pixel 210 illustrated in FIG. 24K includes the subpixel 11a in the upper row (first row), the subpixel 11b in the center row (second row), the subpixel 11c across the first and second rows, and two subpixels (the subpixel 11d and the subpixel 11e) in the lower row (third row). In other words, the pixel 210 includes the subpixel 11a, the subpixel 11b, and the subpixel 11d in the left column (first column), and the subpixel 11c and the subpixel 11e in the right column (second column).

In the pixels 210 illustrated in FIG. 24J and FIG. 24K, for example, it is preferable that the subpixel 11a be the subpixel R emitting red light, the subpixel 11b be the subpixel G emitting green light, and the subpixel 11c be the subpixel B emitting blue light. In the case of such a structure, stripe arrangement is employed as the layout of R, G, and B in the pixel 210 illustrated in FIG. 24J, leading to higher display quality. In addition, what is called S-stripe arrangement is employed as the layout of R, G, and B in the pixel 210 illustrated in FIG. 24K, leading to higher display quality.

In the pixels 210 illustrated in FIG. 24J and FIG. 24K, for example, it is preferable to use the subpixel S including a light-receiving device as at least one of the subpixel 11d and the subpixel 11e. In the case where light-receiving devices are used in both the subpixel 11d and the subpixel 11e, the light-receiving devices may have different structures. For example, the wavelength ranges of detected light may be different at least partly. Specifically, one of the subpixel 11d and the subpixel 11e may include a light-receiving device mainly detecting visible light and the other may include a light-receiving device mainly detecting infrared light.

In the pixels 210 illustrated in FIG. 24J and FIG. 24K, it is preferable that, for example, the subpixel S including a light-receiving device be used as one of the subpixel 11d and the subpixel 11e and a subpixel including a light-emitting device that can be used as a light source be used as the other. For example, it is preferable that one of the subpixel 11d and the subpixel 11e be the subpixel IR emitting infrared light and the other be the subpixel S including a light-receiving device detecting infrared light.

In a pixel including the subpixel R, the subpixel G, the subpixel B, the subpixel IR, and the subpixel S, while an image is displayed using the subpixel R, the subpixel G, and the subpixel B, reflected light of infrared light emitted by the subpixel IR that is used as a light source can be detected by the subpixel S.

As described above, the pixel composed of the subpixels each including the light-emitting device can employ any of a variety of layouts in the display apparatus of one embodiment of the present invention. The display apparatus of one embodiment of the present invention can have a structure in which the pixel includes both a light-emitting device and a light-receiving device. Also in this case, any of a variety of layouts can be employed.

This embodiment can be combined with any of the other embodiments or an example as appropriate.

### Embodiment 4

In this embodiment, light-emitting devices that can be used for the display apparatus of one embodiment of the present invention will be described.

### [Light-Emitting Device]

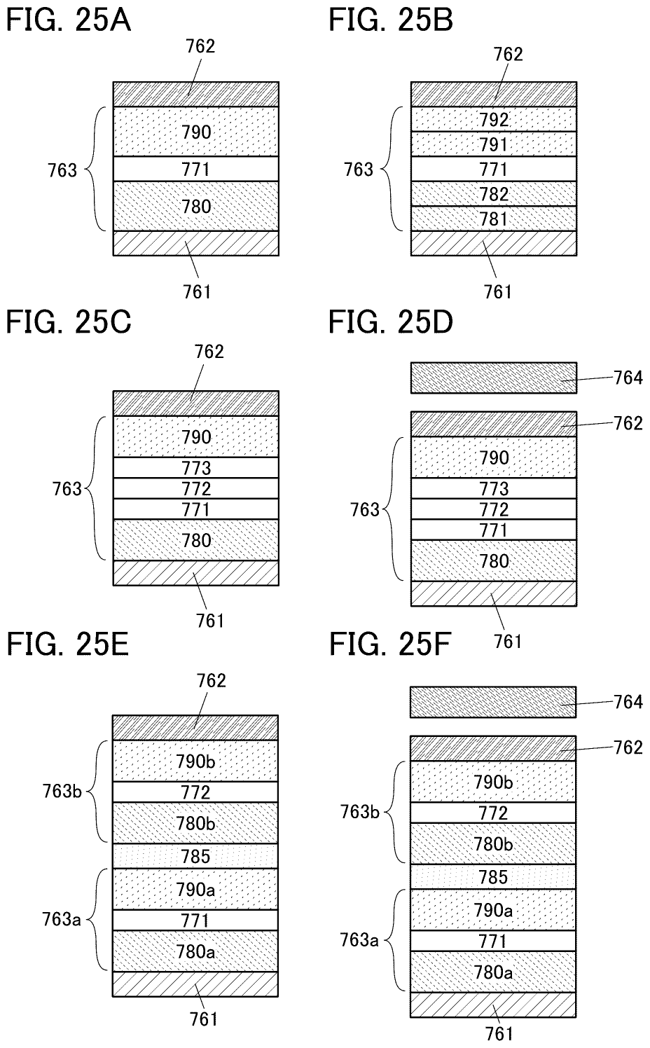

As illustrated in FIG. 25A, the light-emitting device includes an EL layer 763 between a pair of electrodes (a lower electrode 761 and an upper electrode 762). The EL layer 763 can be formed of a plurality of layers such as a layer 780, a light-emitting layer 771, and a layer 790. The light-emitting layer 771 contains at least a light-emitting substance (also referred to as a light-emitting material).

In the case where the lower electrode 761 is an anode and the upper electrode 762 is a cathode, the layer 780 includes one or more of a layer containing a material having a high hole-injection property (a hole-injection layer), a layer containing a material having a high hole-transport property (a hole-transport layer), and a layer containing a material having a high electron-blocking property (an electron-blocking layer). Furthermore, the layer 790 includes one or more of a layer containing a material having a high electron-injection property (an electron-injection layer), a layer containing a material having a high electron-transport property (an electron-transport layer), and a layer containing a material having a high hole-blocking property (a hole-blocking layer). In the case where the lower electrode 761 is a cathode and the upper electrode 762 is an anode, the structures of the layer 780 and the layer 790 are replaced with each other.

The structure including the layer 780, the light-emitting layer 771, and the layer 790, which is provided between the pair of electrodes, can function as a single light-emitting unit, and the structure in FIG. 25A is referred to as a single structure in this specification.

FIG. 25B is a modification example of the EL layer 763 included in the light-emitting device illustrated in FIG. 25A. Specifically, the light-emitting device illustrated in FIG. 25B includes a layer 781 over the lower electrode 761, a layer 782 over the layer 781, the light-emitting layer 771 over the layer 782, a layer 791 over the light-emitting layer 771, a layer 792 over the layer 791, and the upper electrode 762 over the layer 792.

In the case where the lower electrode 761 is an anode and the upper electrode 762 is a cathode, the layer 781 can be a hole-injection layer, the layer 782 can be a hole-transport layer, the layer 791 can be an electron-transport layer, and the layer 792 can be an electron-injection layer, for example. In the case where the lower electrode 761 is a cathode and the upper electrode 762 is an anode, the layer 781 can be an electron-injection layer, the layer 782 can be an electron-transport layer, the layer 791 can be a hole-transport layer, and the layer 792 can be a hole-injection layer. With such a layered structure, carriers can be efficiently injected to the light-emitting layer 771, and the efficiency of the recombination of carriers in the light-emitting layer 771 can be enhanced.

Note that structures in which a plurality of light-emitting layers (the light-emitting layer 771, a light-emitting layer 772, and a light-emitting layer 773) are provided between the layer 780 and the layer 790 as illustrated in FIG. 25C and FIG. 25D are other variations of the single structure. Although FIG. 25C and FIG. 25D illustrate the examples where three light-emitting layers are included, the light-emitting layer in the light-emitting device with a single structure may include two or four or more light-emitting layers. In addition, the light-emitting device with a single structure may include a buffer layer between two light-emitting layers. A carrier-transport layer (a hole-transport layer or an electron-transport layer) can be used as the buffer layer, for example.

A structure where a plurality of light-emitting units (a light-emitting unit 763a and a light-emitting unit 763b) are connected in series with a charge-generation layer 785 (also referred to as an intermediate layer) therebetween as illustrated in FIG. 25E and FIG. 25F is referred to as a tandem structure in this specification. Note that a tandem structure may be referred to as a stack structure. The tandem structure enables a light-emitting device capable of high-luminance light emission. Furthermore, the tandem structure can reduce the amount of current needed for obtaining the same luminance as compared with a single structure, and thus can improve the reliability.

Note that FIG. 25D and FIG. 25F illustrate examples where the display apparatus includes a layer 764 overlapping with the light-emitting device. FIG. 25D illustrates an example where the layer 764 overlaps with the light-emitting device illustrated in FIG. 25C, and FIG. 25F illustrates an example where the layer 764 overlaps with the light-emitting device illustrated in FIG. 25E. In FIG. 25D and FIG. 25F, a conductive film transmitting visible light is used for the upper electrode 762 to extract light to the upper electrode 762 side.

One or both of a color conversion layer and a color filter (a coloring layer) can be used as the layer 764.

In FIG. 25C and FIG. 25D, light-emitting substances that emit light of the same color, or moreover, the same light-emitting substance may be used for the light-emitting layer 771, the light-emitting layer 772, and the light-emitting layer 773. For example, a light-emitting substance that emits blue light may be used for the light-emitting layer 771, the light-emitting layer 772, and the light-emitting layer 773. In a subpixel that emits blue light, blue light emitted from the light-emitting device can be extracted. In a subpixel that emits red light and a subpixel that emits green light, by providing a color conversion layer as the layer 764 illustrated in FIG. 25D, blue light emitted from the light-emitting device can be converted into light with a longer wavelength, and red light or green light can be extracted. As the layer 764, both a color conversion layer and a coloring layer are preferably used. In some cases, part of light emitted from the light-emitting device is transmitted through the color conversion layer without being converted. When light transmitted through the color conversion layer is extracted through the coloring layer, light other than light of the desired color can be absorbed by the coloring layer, and color purity of light emitted from a subpixel can be improved.

In FIG. 25C and FIG. 25D, light-emitting substances that emit light of different colors may be used for the light-emitting layer 771, the light-emitting layer 772, and the light-emitting layer 773. In the case where the light-emitting layer 771, the light-emitting layer 772, and the light-emitting layer 773 emit light of complementary colors, the light emitted from the light-emitting layer 771, the light emitted from the light-emitting layer 772, and the light emitted from the light-emitting layer 773 are mixed and thus white light emission can be obtained as a whole. The light-emitting device with a single structure preferably includes a light-emitting layer containing a light-emitting substance emitting blue light and a light-emitting layer containing a light-emitting substance emitting visible light with a longer wavelength than blue light, for example.

A color filter may be provided as the layer 764 illustrated in FIG. 25D. When white light passes through the color filter, light of a desired color can be obtained.

In the case where the light-emitting device with a single structure includes three light-emitting layers, for example, a light-emitting layer containing a light-emitting substance emitting red (R) light, a light-emitting layer containing a light-emitting substance emitting green (G) light, and a light-emitting layer containing a light-emitting substance emitting blue (B) light are preferably included. The stacking order of the light-emitting layers can be RGB from an anode side or RBG from an anode side, for example. In that case, a buffer layer may be provided between R and G or between R and B.

For example, in the case where the light-emitting device with a single structure includes two light-emitting layers, the light-emitting device preferably includes a light-emitting layer containing a light-emitting substance that emits blue (B) light and a light-emitting layer containing a light-emitting substance that emits yellow (Y) light. Such a structure may be referred to as a BY single structure.

The light-emitting device that emits white light preferably contains two or more kinds of light-emitting substances. To obtain white light emission, two or more kinds of light-emitting substances are selected such that their emission colors are complementary colors. For example, when an emission color of a first light-emitting layer and an emission color of a second light-emitting layer are complementary colors, the light-emitting device can be configured to emit white light as a whole. The same applies to a light-emitting device including three or more light-emitting layers.

Also in FIG. 25C and FIG. 25D, the layer 780 and the layer 790 may each independently have a stacked-layer structure of two or more layers as illustrated in FIG. 25B.

In FIG. 25E and FIG. 25F, light-emitting substances that emit light of the same color, or moreover, the same light-emitting substance may be used for the light-emitting layer 771 and the light-emitting layer 772. For example, in light-emitting devices included in subpixels emitting light of different colors, a light-emitting substance that emits blue light may be used for each of the light-emitting layer 771 and the light-emitting layer 772. In a subpixel that emits blue light, blue light emitted from the light-emitting device can be extracted. In the subpixel that emits red light and the subpixel that emits green light, by providing a color conversion layer as the layer 764 illustrated in FIG. 25F, blue light emitted from the light-emitting device can be converted into light with a longer wavelength, and red light or green light can be extracted. As the layer 764, both a color conversion layer and a coloring layer are preferably used.

In the case where the light-emitting device having the structure illustrated in FIG. 25E or FIG. 25F is used for the subpixels emitting different colors, the subpixels may use different light-emitting substances. Specifically, in the light-emitting device included in the subpixel that emits red light, a light-emitting substance that emits red light may be used for each of the light-emitting layer 771 and the light-emitting layer 772. Similarly, in the light-emitting device included in the subpixel that emits green light, a light-emitting substance that emits green light may be used for each of the light-emitting layer 771 and the light-emitting layer 772. In the light-emitting device included in the subpixel that emits blue light, a light-emitting substance that emits blue light may be used for each of the light-emitting layer 771 and the light-emitting layer 772. A display apparatus with such a structure includes a light-emitting device with a tandem structure and can be regarded to have an SBS structure. Thus, the display apparatus can have both the advantage of a tandem structure and the advantage of an SBS structure. Accordingly, a light-emitting device capable of light emission at high luminance and having high reliability can be achieved.

In FIG. 25E and FIG. 25F, light-emitting substances of different emission colors may be used for the light-emitting layer 771 and the light-emitting layer 772. In the case where the light-emitting layer 771 and the light-emitting layer 772 emit light of complementary colors, the light is mixed and thus white light emission can be obtained as a whole. A color filter may be provided as the layer 764 illustrated in FIG. 25F. When white light passes through the color filter, light of a desired color can be obtained.

Although FIG. 25E and FIG. 25F illustrate examples where the light-emitting unit 763a includes one light-emitting layer 771 and the light-emitting unit 763b includes one light-emitting layer 772, one embodiment of the present invention is not limited thereto. Each of the light-emitting unit 763a and the light-emitting unit 763b may include two or more light-emitting layers.

Although FIG. 25E and FIG. 25F illustrate the light-emitting device including two light-emitting units, one embodiment of the present invention is not limited thereto. The light-emitting device may include three or more light-emitting units. Note that a structure including two light-emitting units and a structure including three light-emitting units may be referred to as a two-unit tandem structure and a three-unit tandem structure, respectively.

In FIG. 25E and FIG. 25F, the light-emitting unit 763a includes a layer 780a, the light-emitting layer 771, and a layer 790a, and the light-emitting unit 763b includes a layer 780b, the light-emitting layer 772, and a layer 790b.

In the case where the lower electrode 761 is an anode and the upper electrode 762 is a cathode, the layer 780a and the layer 780b each include one or more of a hole-injection layer, a hole-transport layer, and an electron-blocking layer. The layer 790a and the layer 790b each include one or more of an electron-injection layer, an electron-transport layer, and a hole-blocking layer. In the case where the lower electrode 761 is a cathode and the upper electrode 762 is an anode, the structures of the layer 780a and the layer 790a are replaced with each other, and the structures of the layer 780b and the layer 790b are also replaced with each other.

In the case where the lower electrode 761 is an anode and the upper electrode 762 is a cathode, for example, the layer 780a includes a hole-injection layer and a hole-transport layer over the hole-injection layer, and may further include an electron-blocking layer over the hole-transport layer. The layer 790a includes an electron-transport layer, and may further include a hole-blocking layer between the light-emitting layer 771 and the electron-transport layer. The layer 780b includes a hole-transport layer, and may further include an electron-blocking layer over the hole-transport layer. The layer 790b includes an electron-transport layer and an electron-injection layer over the electron-transport layer, and may further include a hole-blocking layer between the light-emitting layer 772 and the electron-transport layer. In the case where the lower electrode 761 is a cathode and the upper electrode 762 is an anode, for example, the layer 780a includes an electron-injection layer and an electron-transport layer over the electron-injection layer, and may further include a hole-blocking layer over the electron-transport layer. The layer 790a includes a hole-transport layer, and may further include an electron-blocking layer between the light-emitting layer 771 and the hole-transport layer. The layer 780b includes an electron-transport layer, and may further include a hole-blocking layer over the electron-transport layer. The layer 790b includes a hole-transport layer and a hole-injection layer over the hole-transport layer, and may further include an electron-blocking layer between the light-emitting layer 772 and the hole-transport layer.

In the case of fabricating a light-emitting device with a tandem structure, two light-emitting units are stacked with the charge-generation layer 785 therebetween. The charge-generation layer 785 includes at least a charge-generation region. The charge-generation layer 785 has a function of injecting electrons into one of the two light-emitting units and injecting holes into the other when voltage is applied between the pair of electrodes.

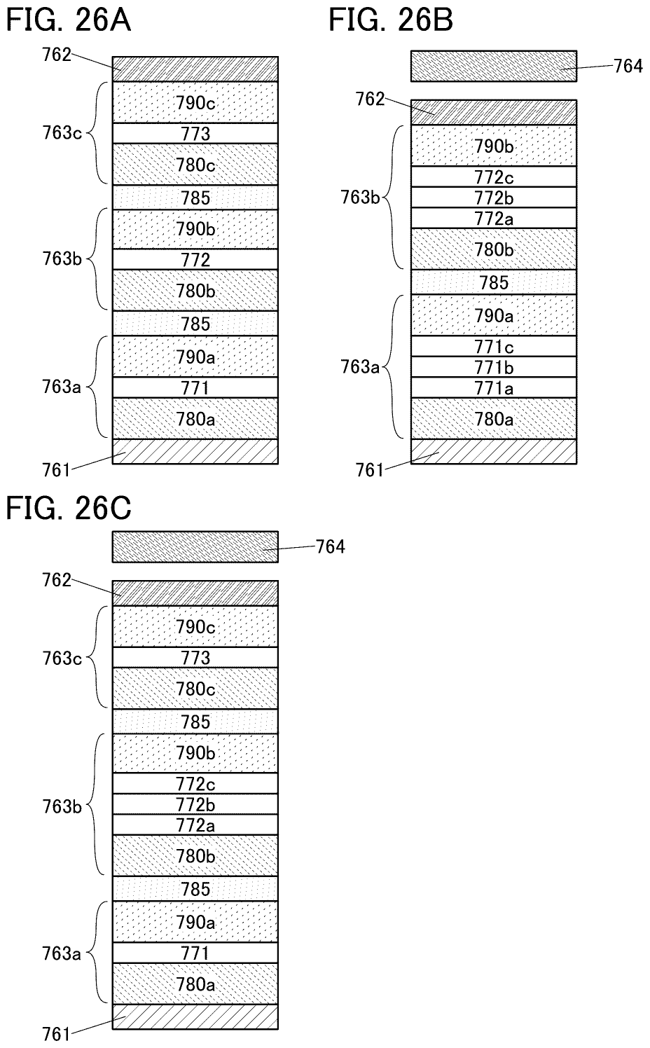

Structures illustrated in FIG. 26A to FIG. 26C can be given as examples of the light-emitting device with a tandem structure.

FIG. 26A illustrates a structure including three light-emitting units. In FIG. 26A, a plurality of light-emitting units (the light-emitting unit 763a, the light-emitting unit 763b, and a light-emitting unit 763c) are each connected in series through the charge-generation layers 785. The light-emitting unit 763a includes the layer 780a, the light-emitting layer 771, and the layer 790a. The light-emitting unit 763b includes the layer 780b, the light-emitting layer 772, and the layer 790b. The light-emitting unit 763c includes a layer 780c, the light-emitting layer 773, and a layer 790c. Note that the layer 780c can have a structure applicable to the layer 780a and the layer 780b, and the layer 790c can have a structure applicable to the layer 790a and the layer 790b.

In FIG. 26A, the light-emitting layer 771, the light-emitting layer 772, and the light-emitting layer 773 can contain light-emitting substances that emit light of the same color. Specifically, the light-emitting layer 771, the light-emitting layer 772, and the light-emitting layer 773 can each contain a red (R) light-emitting substance (a so-called three-unit tandem structure of R\R\R); the light-emitting layer 771, the light-emitting layer 772, and the light-emitting layer 773 can each contain a green (G) light-emitting substance (a so-called three-unit tandem structure of G\G\G); or the light-emitting layer 771, the light-emitting layer 772, and the light-emitting layer 773 can each contain a blue (B) light-emitting substance (a so-called three-unit tandem structure of B\B\B). Note that “alb” means that a light-emitting unit containing a light-emitting substance that emits light of b is provided over a light-emitting unit containing a light-emitting substance that emits light of a with a charge-generation layer therebetween, where a and b represent colors.

In FIG. 26A, light-emitting substances with different emission colors may be used for some or all of the light-emitting layer 771, the light-emitting layer 772, and the light-emitting layer 773. Examples of a combination of emission colors for the light-emitting layer 771, the light-emitting layer 772, and the light-emitting layer 773 include blue (B) for two of them and yellow (Y) for the other; and red (R) for one of them, green (G) for another, and blue (B) for the other.

Note that the structures of the light-emitting substances that emit light of the same color are not limited to the above structures. For example, a light-emitting device with a tandem structure may be employed in which light-emitting units each including a plurality of light-emitting layers are stacked as illustrated in FIG. 26B. FIG. 26B illustrates a structure in which two light-emitting units (the light-emitting unit 763a and the light-emitting unit 763b) are connected in series with the charge-generation layer 785 therebetween. The light-emitting unit 763a includes the layer 780a, a light-emitting layer 771a, a light-emitting layer 771b, a light-emitting layer 771c, and the layer 790a. The light-emitting unit 763b includes the layer 780b, a light-emitting layer 772a, a light-emitting layer 772b, a light-emitting layer 772c, and the layer 790b.

In FIG. 26B, the light-emitting unit 763a is configured to emit white (W) light by selecting light-emitting substances for the light-emitting layer 771a, the light-emitting layer 771b, and the light-emitting layer 771c so that their emission colors are complementary colors. Furthermore, the light-emitting unit 763b is configured to emit white (W) light by selecting light-emitting substances for the light-emitting layer 772a, the light-emitting layer 772b, and the light-emitting layer 772c so that their emission colors are complementary colors. That is, the structure illustrated in FIG. 26B is a two-unit tandem structure of WWW. Note that there is no particular limitation on the stacking order of the light-emitting substances having complementary emission colors. The practitioner can select the optimal stacking order as appropriate. Although not illustrated, a three-unit tandem structure of WWWWW or a tandem structure with four or more units may be employed.

In the case of a light-emitting device with a tandem structure, any of the following structure may be employed, for example: a two-unit tandem structure of BY or Y\B including a light-emitting unit that emits yellow (Y) light and a light-emitting unit that emits blue (B) light; a two-unit tandem structure of R·G\B or B\R·G including a light-emitting unit that emits red (R) and green (G) light and a light-emitting unit that emits blue (B) light; a three-unit tandem structure of BY\B including a light-emitting unit that emits blue (B) light, a light-emitting unit that emits yellow (Y) light, and a light-emitting unit that emits blue (B) light in this order; a three-unit tandem structure of BYG\B including a light-emitting unit that emits blue (B) light, a light-emitting unit that emits yellow-green (YG) light, and a light-emitting unit that emits blue (B) light in this order; and a three-unit tandem structure of B\G\B including a light-emitting unit that emits blue (B) light, a light-emitting unit that emits green (G) light, and a light-emitting unit that emits blue (B) light in this order. Note that “a·b” means that one light-emitting unit contains a light-emitting substance that emits light of a and a light-emitting substance that emits light of b.

As illustrated in FIG. 26C, a light-emitting unit including one light-emitting layer and a light-emitting unit including a plurality of light-emitting layers may be used in combination.

Specifically, in the structure illustrated in FIG. 26C, a plurality of light-emitting units (the light-emitting unit 763a, the light-emitting unit 763b, and the light-emitting unit 763c) are each connected in series through the charge-generation layers 785. The light-emitting unit 763a includes the layer 780a, the light-emitting layer 771, and the layer 790a. The light-emitting unit 763b includes the layer 780b, the light-emitting layer 772a, the light-emitting layer 772b, the light-emitting layer 772c, and the layer 790b. The light-emitting unit 763c includes the layer 780c, the light-emitting layer 773, and the layer 790c.

As the structure illustrated in FIG. 26C, for example, a three-unit tandem structure of B\R·G·YG\B in which the light-emitting unit 763a is a light-emitting unit that emits blue (B) light, the light-emitting unit 763b is a light-emitting unit that emits red (R), green (G), and yellow-green (YG) light, and the light-emitting unit 763c is a light-emitting unit that emits blue (B) light can be employed.

Examples of the number of stacked light-emitting units and the order of colors from the anode side include a two-unit structure of B and Y, a two-unit structure of B and a light-emitting unit X, a three-unit structure of B, Y, and B, and a three-unit structure of B, X, and B. Examples of the number of light-emitting layers stacked in the light-emitting unit X and the order of colors from an anode side include a two-layer structure of R and Y, a two-layer structure of R and G, a two-layer structure of G and R, a three-layer structure of G, R, and G, and a three-layer structure of R, G, and R. Another layer may be provided between two light-emitting layers.

Next, materials that can be used for the light-emitting device will be described.

A conductive film transmitting visible light is used for the electrode through which light is extracted, which is either the lower electrode 761 or the upper electrode 762. A conductive film reflecting visible light is preferably used for the electrode through which light is not extracted. In the case where a display apparatus includes a light-emitting device emitting infrared light, it is preferable that a conductive film transmitting visible light and infrared light be used for the electrode through which light is extracted and that a conductive film reflecting visible light and infrared light be used for the electrode through which light is not extracted.

A conductive film transmitting visible light may be used also for an electrode through which no light is extracted. In this case, this electrode is preferably provided between the reflective layer and the EL layer 763. In other words, light emitted from the EL layer 763 may be reflected by the reflective layer to be extracted from the display apparatus.

As a material that forms the pair of electrodes of the light-emitting device, a metal, an alloy, an electrically conductive compound, a mixture thereof, and the like can be used as appropriate. Specific examples of the material include metals such as aluminum, magnesium, titanium, chromium, manganese, iron, cobalt, nickel, copper, gallium, zinc, indium, tin, molybdenum, tantalum, tungsten, palladium, gold, platinum, silver, yttrium, and neodymium, and an alloy containing any of these metals in appropriate combination. Other examples of the material include indium tin oxide (also referred to as In—Sn oxide or ITO), In—Si—Sn oxide (also referred to as ITSO), indium zinc oxide (In—Zn oxide), and In—W—Zn oxide. Other examples of the material include an alloy containing aluminum (aluminum alloy), such as an alloy of aluminum, nickel, and lanthanum (Al—Ni—La), and an alloy containing silver, such as an alloy of silver and magnesium and an alloy of silver, palladium, and copper (APC). Other example of the material include elements belonging to Group 1 or Group 2 of the periodic table, which are not exemplified above (e.g., lithium, cesium, calcium, and strontium), rare earth metals such as europium and ytterbium, an alloy containing any of these metals in appropriate combination, and graphene.

The light-emitting device preferably employs a microcavity structure. Therefore, one of the pair of electrodes of the light-emitting device preferably includes an electrode having properties of transmitting and reflecting visible light (transflective electrode), and the other preferably includes an electrode having a property of reflecting visible light (reflective electrode). When the light-emitting device has a microcavity structure, light obtained from the light-emitting layer can be resonated between the electrodes, whereby light emitted from the light-emitting device can be intensified.

The transparent electrode has a light transmittance higher than or equal to 40%. For example, an electrode having a visible light (light with a wavelength longer than or equal to 400 nm and shorter than 750 nm) transmittance higher than or equal to 40% is preferably used as the transparent electrode of the light-emitting device. The visible light reflectance of the transflective electrode is higher than or equal to 10% and lower than or equal to 95%, preferably higher than or equal to 30% and lower than or equal to 80%. The visible light reflectance of the reflective electrode is higher than or equal to 40% and lower than or equal to 100%, preferably higher than or equal to 70% and lower than or equal to 100%. These electrodes preferably have a resistivity of 1×10⁻² (2 cm or lower.

The light-emitting device includes at least a light-emitting layer. In addition, the light-emitting device may further include, as a layer other than the light-emitting layer, a layer containing a material with a high hole-injection property, a material with a high hole-transport property, a hole-blocking material, a material with a high electron-transport property, an electron-blocking material, a material with a high electron-injection property, a material with a bipolar property (a material with a high electron-transport property and a high hole-transport property), or the like. For example, the light-emitting device can include one or more of a hole-injection layer, a hole-transport layer, a hole-blocking layer, a charge-generation layer, an electron-blocking layer, an electron-transport layer, and an electron-injection layer in addition to the light-emitting layer.

Either a low molecular compound or a high molecular compound can be used for the light-emitting device, and an inorganic compound may also be included. Each layer included in the light-emitting device can be formed by a method such as an evaporation method (including a vacuum evaporation method), a transfer method, a printing method, an inkjet method, or a coating method.

The light-emitting layer contains one or more kinds of light-emitting substances. As the light-emitting substance, a substance whose emission color is blue, violet, bluish violet, green, yellowish green, yellow, orange, red, or the like is appropriately used. Alternatively, a substance that emits near-infrared light can be used as the light-emitting substance.

Examples of the light-emitting substance include a fluorescent material, a phosphorescent material, a TADF material, and a quantum dot material.

Examples of a fluorescent material include a pyrene derivative, an anthracene derivative, a triphenylene derivative, a fluorene derivative, a carbazole derivative, a dibenzothiophene derivative, a dibenzofuran derivative, a dibenzoquinoxaline derivative, a quinoxaline derivative, a pyridine derivative, a pyrimidine derivative, a phenanthrene derivative, and a naphthalene derivative.

Examples of a phosphorescent material include an organometallic complex (particularly an iridium complex) having a 4H-triazole skeleton, a 1H-triazole skeleton, an imidazole skeleton, a pyrimidine skeleton, a pyrazine skeleton, or a pyridine skeleton; an organometallic complex (particularly an iridium complex) having a phenylpyridine derivative including an electron-withdrawing group as a ligand; a platinum complex; and a rare earth metal complex.

The light-emitting layer may contain one or more kinds of organic compounds (e.g., a host material or an assist material) in addition to the light-emitting substance (a guest material). As one or more kinds of organic compounds, one or both of a material with a high hole-transport property (a hole-transport material) and a material with a high electron-transport property (an electron-transport material) can be used. As the hole-transport material, it is possible to use a material with a high hole-transport property which can be used for the hole-transport layer and will be described later. As the electron-transport material, it is possible to use a material having a high electron-transport property which can be used for the electron-transport layer and will be described later. Alternatively, as one or more kinds of organic compounds, a bipolar material or a TADF material may be used.

The light-emitting layer preferably includes a phosphorescent material and a combination of a hole-transport material and an electron-transport material that easily forms an exciplex, for example. Such a structure makes it possible to efficiently obtain light emission using ExTET (Exciplex-Triplet Energy Transfer), which is energy transfer from an exciplex to a light-emitting substance (a phosphorescent material). When a combination of materials is selected to form an exciplex that exhibits light emission whose wavelength overlaps with the wavelength of the lowest-energy-side absorption band of the light-emitting substance, energy can be transferred smoothly and light emission can be obtained efficiently. With the above structure, high efficiency, low-voltage driving, and a long lifetime of a light-emitting device can be achieved at the same time.

The hole-injection layer is a layer injecting holes from an anode to a hole-transport layer and containing a material with a high hole-injection property. Examples of the material with a high hole-injection property include an aromatic amine compound and a composite material containing a hole-transport material and an acceptor material (electron-accepting material).

As the hole-transport material, it is possible to use a material with a high hole-transport property which can be used for the hole-transport layer and will be described later.

As the acceptor material, an oxide of a metal belonging to any of Group 4 to Group 8 of the periodic table can be used, for example. Specifically, molybdenum oxide, vanadium oxide, niobium oxide, tantalum oxide, chromium oxide, tungsten oxide, manganese oxide, and rhenium oxide are given. Among these, molybdenum oxide is particularly preferable since it is stable in the air, has a low hygroscopic property, and is easy to handle. Alternatively, an organic acceptor material containing fluorine can be used. Alternatively, an organic acceptor material such as a quinodimethane derivative, a chloranil derivative, or a hexaazatriphenylene derivative can be used.

As the material having a high hole-injection property, a material that contains a hole-transport material and the above-described oxide of a metal belonging to Group 4 to Group 8 of the periodic table (typically, molybdenum oxide) may be used, for example.

The hole-transport layer is a layer transporting holes, which are injected from the anode by the hole-injection layer, to the light-emitting layer. The hole-transport layer is a layer containing a hole-transport material. As the hole-transport material, a substance having a hole mobility greater than or equal to 1×10⁻⁶ cm²/Vs is preferable. Note that other materials can also be used as long as they have a property of transporting more holes than electrons. As the hole-transport material, a material with a high hole-transport property such as a x-electron rich heteroaromatic compound (e.g., a carbazole derivative, a thiophene derivative, or a furan derivative) or an aromatic amine (a compound having an aromatic amine skeleton) is preferable.

The electron-blocking layer is provided in contact with the light-emitting layer. The electron-blocking layer is a layer having a hole-transport property and containing a material capable of blocking electrons. Any of the materials having an electron-blocking property among the above hole-transport materials can be used for the electron-blocking layer.

The electron-blocking layer has a hole-transport property, and thus can also be referred to as a hole-transport layer. A layer having an electron-blocking property among the hole-transport layers can also be referred to as an electron-blocking layer.

The electron-transport layer is a layer transporting electrons, which are injected from the cathode by the electron-injection layer, to the light-emitting layer. The electron-transport layer is a layer that contains an electron-transport material. As the electron-transport material, a substance having an electron mobility greater than or equal to 1×10⁻⁶ cm²/Vs is preferable. Note that other materials can also be used as long as they have a property of transporting more electrons than holes. As the electron-transport material, it is possible to use a material with a high electron-transport property, such as a metal complex having a quinoline skeleton, a metal complex having a benzoquinoline skeleton, a metal complex having an oxazole skeleton, a metal complex having a thiazole skeleton, an oxadiazole derivative, a triazole derivative, an imidazole derivative, an oxazole derivative, a thiazole derivative, a phenanthroline derivative, a quinoline derivative having a quinoline ligand, a benzoquinoline derivative, a quinoxaline derivative, a dibenzoquinoxaline derivative, a pyridine derivative, a bipyridine derivative, a pyrimidine derivative, or a π-electron deficient heteroaromatic compound including a nitrogen-containing heteroaromatic compound.

The hole-blocking layer is provided in contact with the light-emitting layer. The hole-blocking layer is a layer having an electron-transport property and containing a material that can block holes. Any of the materials having a hole-blocking property among the above electron-transport materials can be used for the hole-blocking layer.

The hole-blocking layer has an electron-transport property, and thus can also be referred to as an electron-transport layer. A layer having a hole-blocking property among the electron-transport layers can also be referred to as a hole-blocking layer.

The electron-injection layer is a layer injecting electrons from the cathode to the electron-transport layer and containing a material with a high electron-injection property. As the material with a high electron-injection property, an alkali metal, an alkaline earth metal, or a compound thereof can be used. As the material with a high electron-injection property, a composite material containing an electron-transport material and a donor material (an electron-donating material) can also be used.

The difference between the lowest unoccupied molecular orbital (LUMO) level of the material with a high electron-injection property and the work function value of the material used for the cathode is preferably small (specifically, less than or equal to 0.5 eV).

The electron-injection layer can be formed using an alkali metal, an alkaline earth metal, or a compound thereof, such as lithium, cesium, ytterbium, lithium fluoride (LiF), cesium fluoride (CsF), calcium fluoride (CaFx, where X is a given number), 8-(quinolinolato) lithium (abbreviation: Liq), 2-(2-pyridyl) phenolatolithium (abbreviation: LiPP), 2-(2-pyridyl)-3-pyridinolato lithium (abbreviation: LiPPy), 4-phenyl-2-(2-pyridyl) phenolatolithium (abbreviation: LiPPP), lithium oxide (LiOₓ), or cesium carbonate, for example. The electron-injection layer may have a stacked-layer structure of two or more layers. In the stacked-layer structure, for example, lithium fluoride can be used for the first layer and ytterbium can be used for the second layer.

The electron-injection layer may contain an electron-transport material. For example, a compound having an unshared electron pair and an electron deficient heteroaromatic ring can be used as the electron-transport material. Specifically, it is possible to use a compound having at least one of a pyridine ring, a diazine ring (a pyrimidine ring, a pyrazine ring, and a pyridazine ring), and a triazine ring.

Note that the LUMO level of the organic compound having an unshared electron pair is preferably greater than or equal to −3.6 eV and less than or equal to −2.3 eV. In general, the highest occupied molecular orbital (HOMO) level and the LUMO level of an organic compound can be estimated by CV (cyclic voltammetry), photoelectron spectroscopy, optical absorption spectroscopy, inverse photoelectron spectroscopy, or the like.

For example, 4,7-diphenyl-1,10-phenanthroline (abbreviation: BPhen), 2,9-di(naphthalen-2-yl)-4,7-diphenyl-1,10-phenanthroline (abbreviation: NBPhen), 2,2′-(1,3-phenylene)bis(9-phenyl-1,10-phenanthroline) (abbreviation: mPPhen2P), diquinoxalino[2,3-a: 2′,3′-c]phenazine (abbreviation: HATNA), 2,4,6-tris[3′-(pyridin-3-yl) biphenyl-3-yl]-1,3,5-triazine (abbreviation: TmPPPyTz), or the like can be used as the organic compound having an unshared electron pair. Note that NBPhen has a higher glass transition point (Tg) than BPhen and thus has high heat resistance.

As described above, the charge-generation layer includes at least a charge-generation region. The charge-generation region preferably contains an acceptor material, and for example, preferably contains a hole-transport material and an acceptor material which can be used for the above-described hole-injection layer.

The charge-generation layer preferably includes a layer containing a material with a high electron-injection property. The layer can also be referred to as an electron-injection buffer layer. The electron-injection buffer layer is preferably provided between the charge-generation region and the electron-transport layer. By provision of the electron-injection buffer layer, an injection barrier between the charge-generation region and the electron-transport layer can be lowered; thus, electrons generated in the charge-generation region can be easily injected into the electron-transport layer.

The electron-injection buffer layer preferably contains an alkali metal or an alkaline earth metal, and for example, can be configured to contain an alkali metal compound or an alkaline earth metal compound. Specifically, the electron-injection buffer layer preferably contains an inorganic compound containing an alkali metal and oxygen or an inorganic compound containing an alkaline earth metal and oxygen, further preferably contains an inorganic compound containing lithium and oxygen (e.g., lithium oxide (Li₂O)). Alternatively, a material that can be used for the electron-injection layer can be suitably used for the electron-injection buffer layer.

The charge-generation layer preferably includes a layer containing a material with a high electron-transport property. The layer can also be referred to as an electron-relay layer. The electron-relay layer is preferably provided between the charge-generation region and the electron-injection buffer layer. In the case where the charge-generation layer does not include an electron-injection buffer layer, the electron-relay layer is preferably provided between the charge-generation region and the electron-transport layer. The electron-relay layer has a function of preventing interaction between the charge-generation region and the electron-injection buffer layer (or the electron-transport layer) and smoothly transferring electrons.

A phthalocyanine-based material such as copper (II) phthalocyanine (abbreviation: CuPc) or a metal complex having a metal-oxygen bond and an aromatic ligand is preferably used for the electron-relay layer.

Note that the charge-generation region, the electron-injection buffer layer, and the electron-relay layer cannot be clearly distinguished from one another in some cases on the basis of the cross-sectional shapes, properties, or the like.

Note that the charge-generation layer may contain a donor material instead of an acceptor material. For example, the charge-generation layer may include a layer containing an electron-transport material and a donor material, which can be used for the electron-injection layer.

When the light-emitting units are stacked, provision of a charge-generation layer between two light-emitting units can inhibit an increase in drive voltage.

This embodiment can be combined with any of the other embodiments or an example as appropriate.

### Embodiment 5

In this embodiment, a light-receiving device that can be used for the display apparatus of one embodiment of the present invention and a display apparatus having a light detection function will be described.

### [Light-Receiving Device]

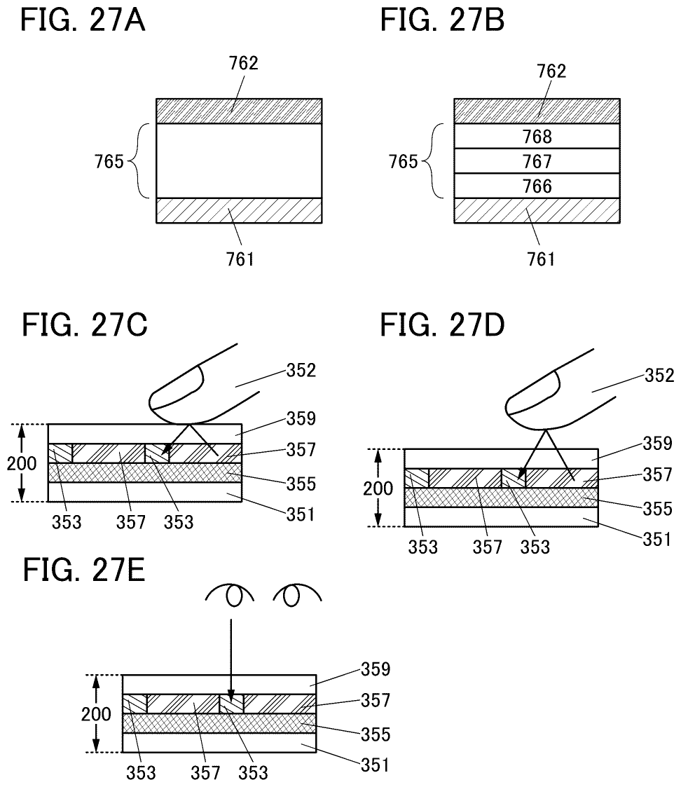

As illustrated in FIG. 27A, the light-receiving device includes a layer 765 between a pair of electrodes (the lower electrode 761 and the upper electrode 762). The layer 765 includes at least one active layer, and may further include another layer.

FIG. 27B is a modification example of the layer 765 included in the light-receiving device illustrated in FIG. 27A. Specifically, the light-receiving device illustrated in FIG. 27B includes a layer 766 over the lower electrode 761, an active layer 767 over the layer 766, a layer 768 over the active layer 767, and the upper electrode 762 over the layer 768.

The active layer 767 functions as a photoelectric conversion layer.

In the case where the lower electrode 761 is an anode and the upper electrode 762 is a cathode, the layer 766 includes one or both of a hole-transport layer and an electron-blocking layer. The layer 768 includes one or both of an electron-transport layer and a hole-blocking layer. In the case where the lower electrode 761 is a cathode and the upper electrode 762 is an anode, the structures of the layer 766 and the layer 768 are replaced with each other.

Next, materials that can be used for the light-receiving device will be described.

Either a low molecular compound or a high molecular compound can be used for the light-receiving device, and an inorganic compound may also be included. Each layer included in the light-receiving device can be formed by a method such as an evaporation method (including a vacuum evaporation method), a transfer method, a printing method, an inkjet method, or a coating method.

The active layer included in the light-receiving device includes a semiconductor. Examples of the semiconductor include an inorganic semiconductor such as silicon and an organic semiconductor including an organic compound. This embodiment describes an example in which an organic semiconductor is used as the semiconductor included in the active layer. The use of an organic semiconductor is preferable because the light-emitting layer and the active layer can be formed by the same method (e.g., a vacuum evaporation method) and thus the same manufacturing apparatus can be used.

Examples of an n-type semiconductor material included in the active layer include electron-accepting organic semiconductor materials such as fullerene (e.g., C₆₀ and C₇₀) and fullerene derivatives. Examples of the fullerene derivative include [6,6]-Phenyl-C₇₁-butyric acid methyl ester (abbreviation: PC70BM), [6,6]-Phenyl-C61-butyric acid methyl ester (abbreviation: PC60BM), and 1′,1″,4′,4″-Tetrahydro-di[1,4]methanonaphthaleno[1,2:2′,3′,56,60:2″,3″][5,6]fullerene-C60 (abbreviation: ICBA).

Other examples of an n-type semiconductor material include perylenetetracarboxylic acid derivatives such as N,N′-dimethyl-3,4,9,10-perylenetetracarboxylic diimide (abbreviation: Me-PTCDI) and 2,2′-(5,5′-(thieno[3,2-b]thiophene-2,5-diyl) bis(thiophene-5,2-diyl)) bis(methan-1-yl-1-ylidene)dimalononitrile (abbreviation: FT2TDMN).

Other examples of an n-type semiconductor material include a metal complex having a quinoline skeleton, a metal complex having a benzoquinoline skeleton, a metal complex having an oxazole skeleton, a metal complex having a thiazole skeleton, an oxadiazole derivative, a triazole derivative, an imidazole derivative, an oxazole derivative, a thiazole derivative, a phenanthroline derivative, a quinoline derivative, a benzoquinoline derivative, a quinoxaline derivative, a dibenzoquinoxaline derivative, a pyridine derivative, a bipyridine derivative, a pyrimidine derivative, a naphthalene derivative, an anthracene derivative, a coumarin derivative, a rhodamine derivative, a triazine derivative, and a quinone derivative.

Examples of a p-type semiconductor material contained in the active layer include electron-donating organic semiconductor materials such as copper (II) phthalocyanine (CuPc), tetraphenyldibenzoperiflanthene (DBP), zinc phthalocyanine (ZnPc), tin phthalocyanine (SnPc), quinacridone, and rubrene.

Other examples of a p-type semiconductor material include a carbazole derivative, a thiophene derivative, a furan derivative, and a compound having an aromatic amine skeleton. Other examples of a p-type semiconductor material include a naphthalene derivative, an anthracene derivative, a pyrene derivative, a triphenylene derivative, a fluorene derivative, a pyrrole derivative, a benzofuran derivative, a benzothiophene derivative, an indole derivative, a dibenzofuran derivative, a dibenzothiophene derivative, an indolocarbazole derivative, a porphyrin derivative, a phthalocyanine derivative, a naphthalocyanine derivative, a quinacridone derivative, a rubrene derivative, a tetracene derivative, a polyphenylene vinylene derivative, a polyparaphenylene derivative, a polyfluorene derivative, a polyvinylcarbazole derivative, and a polythiophene derivative.

The HOMO level of the electron-donating organic semiconductor material is preferably shallower (higher) than the HOMO level of the electron-accepting organic semiconductor material. The LUMO level of the electron-donating organic semiconductor material is preferably shallower (higher) than the LUMO level of the electron-accepting organic semiconductor material.

Fullerene having a spherical shape is preferably used as the electron-accepting organic semiconductor material, and an organic semiconductor material having a substantially planar shape is preferably used as the electron-donating organic semiconductor material. Molecules of similar shapes tend to aggregate, and aggregated molecules of similar kinds, which have molecular orbital energy levels close to each other, can increase the carrier-transport property.

For the active layer, a high molecular compound such as Poly[[4,8-bis[5-(2-ethylhexyl)-2-thienyl]benzo[1,2-b: 4,5-b′]dithiophene-2,6-diyl]-2,5-thiophenediyl[5,7-bis(2-ethylhexyl)-4,8-dioxo-4H,8H-benzo[1,2-c: 4,5-c′]dithiophene-1,3-diyl]] polymer (abbreviation: PBDB-T) or a PBDB-T derivative, which functions as a donor, can be used. For example, a method in which an acceptor material is dispersed to PBDB-T or a PBDB-T derivative can be used.

For example, the active layer is preferably formed by co-evaporation of an n-type semiconductor and a p-type semiconductor. Alternatively, the active layer may be formed by stacking an n-type semiconductor and a p-type semiconductor.

The active layer may include three or more kinds of materials. For example, a third material may be mixed in addition to an n-type semiconductor material and a p-type semiconductor material in order to extend the absorption wavelength range. The third material may be a low molecular compound or a high molecular compound.

In addition to the active layer, the light-receiving device may further include a layer containing a material with a high hole-transport property, a material with a high electron-transport property, a material with a bipolar property (a material with a high electron-transport property and a high hole-transport property), or the like. Without limitation to the above, the light-receiving device may further include a layer containing a material with a high hole-injection property, a hole-blocking material, a material with a high electron-injection property, an electron-blocking material, or the like. Layers other than the active layer included in the light-receiving device can be formed using a material that can be used for the light-emitting device.

As the hole-transport material or the electron-blocking material, a high molecular compound such as poly(3,4-ethylenedioxythiophene)/poly(styrenesulfonic acid) (PEDOT/PSS), or an inorganic compound such as molybdenum oxide or copper iodide (CuI) can be used, for example. As the electron-transport material or the hole-blocking material, an inorganic compound such as zinc oxide (ZnO), or an organic compound such as polyethylenimine ethoxylate (PEIE) can be used. The light-receiving device may include a mixed film of PEIE and ZnO, for example.

### [Display Apparatus Having Light Detection Function]

In the display apparatus of one embodiment of the present invention, the light-emitting devices are arranged in a matrix in a display portion, and an image can be displayed on the display portion. Furthermore, the light-receiving devices are arranged in a matrix in the display portion, and the display portion has one or both of an image capturing function and a sensing function in addition to an image displaying function. The display portion can be used as an image sensor or a touch sensor. That is, by detecting light with the display portion, an image can be captured or the approach or contact of a target (e.g., a finger, a hand, or a pen) can be detected.

Furthermore, in the display apparatus of one embodiment of the present invention, the light-emitting devices can be used as a light source of the sensor. In the display apparatus of one embodiment of the present invention, when an object reflects (or scatters) light emitted by the light-emitting device included in the display portion, the light-receiving device can detect reflected light (or scattered light); thus, image capturing or touch detection is possible even in a dark place.

Accordingly, a light-receiving portion and a light source do not need to be provided separately from the display apparatus; hence, the number of components of an electronic device can be reduced. For example, a biometric authentication device, a capacitive touch panel for scroll operation, or the like provided in the electronic device is not necessarily provided separately. Thus, with the use of the display apparatus of one embodiment of the present invention, the electronic device can be provided with reduced manufacturing cost.

Specifically, the display apparatus of one embodiment of the present invention includes a light-emitting device and a light-receiving device in a pixel. In the display apparatus of one embodiment of the present invention, an organic EL device is used as the light-emitting device, and an organic photodiode is used as the light-receiving device. The organic EL device and the organic photodiode can be formed over one substrate. Thus, the organic photodiode can be incorporated in the display apparatus that includes the organic EL device.

In the display apparatus including light-emitting devices and a light-receiving device in each pixel, the pixel has a light-receiving function; thus, the display apparatus can detect a contact or approach of an object while displaying an image. For example, all the subpixels included in the display apparatus can display an image; alternatively, some of the subpixels can emit light as a light source, others of the subpixels can perform light detection, and the rest of the subpixels can display an image.

In the case where the light-receiving device is used as an image sensor, the display apparatus can capture an image with the use of the light-receiving device. For example, the display apparatus of this embodiment can be used as a scanner.

For example, image capturing for personal authentication with the use of a fingerprint, a palm print, the iris, the shape of a blood vessel (including the shape of a vein and the shape of an artery), a face, or the like can be performed using the image sensor.

For example, an image of the periphery, surface, or inside (e.g., fundus) of an eye of a user of a wearable device can be captured using the image sensor. Therefore, the wearable device can have a function of detecting one or more selected from blinking, movement of an iris, and movement of an eyelid of the user.

The light-receiving device can be used for a touch sensor (also referred to as a direct touch sensor), a near touch sensor (also referred to as a hover sensor, a hover touch sensor, a contactless sensor, or a touchless sensor), or the like.

Here, the touch sensor or the near touch sensor can detect the approach or contact of an object (e.g., a finger, a hand, or a pen).

The touch sensor can detect an object when the display apparatus and the object come in direct contact with each other. The near touch sensor can detect an object even when the object is not in contact with the display apparatus. For example, the display apparatus is preferably capable of detecting an object when the distance between the display apparatus and the object is greater than or equal to 0.1 mm and less than or equal to 300 mm, preferably greater than or equal to 3 mm and less than or equal to 50 mm. With this structure, the display apparatus can be operated without direct contact of an object. In other words, the display apparatus can be operated in a contactless (touchless) manner. With the above structure, the display apparatus can have a reduced risk of being dirty or damaged, or can be operated without the object directly touching a dirt (e.g., dust or a virus) attached to the display apparatus.

The refresh rate can be variable in the display apparatus of one embodiment of the present invention. For example, the refresh rate is adjusted (adjusted in the range from 1 Hz to 240 Hz, for example) in accordance with contents displayed on the display apparatus, whereby power consumption can be reduced. The driving frequency of the touch sensor or the near touch sensor may be changed in accordance with the refresh rate. For example, when the refresh rate of the display apparatus is 120 Hz, the driving frequency of the touch sensor or the near touch sensor can be higher than 120 Hz (can typically be 240 Hz). With this structure, low power consumption can be achieved, and the response speed of the touch sensor or the near touch sensor can be increased.

The display apparatus 200 illustrated in FIG. 27C to FIG. 27E includes a layer 353 including a light-receiving device, a functional layer 355, and a layer 357 including a light-emitting device, between a substrate 351 and a substrate 359.

The functional layer 355 includes a circuit for driving a light-receiving device and a circuit for driving a light-emitting device. One or more of a switch, a transistor, a capacitor, a resistor, a wiring, a terminal, and the like can be provided in the functional layer 355. Note that in the case where the light-emitting device and the light-receiving device are driven by a passive-matrix method, a structure including neither a switch nor a transistor may be employed. As the transistor included in the functional layer 355, any of the transistors described in Embodiment 1 can be suitably used.

For example, after light emitted by the light-emitting device in the layer 357 including the light-emitting device is reflected by a finger 352 in contact with the display apparatus 200 as illustrated in FIG. 27C, the light-receiving device in the layer 353 including the light-receiving device detects the reflected light. Thus, the contact of the finger 352 with the display apparatus 200 can be detected.

Alternatively, the display apparatus may have a function of detecting an object that is approaching (not in contact with) the display apparatus as illustrated in FIG. 27D and FIG. 27E or capturing an image of such an object. FIG. 27D illustrates an example in which a human finger is detected, and FIG. 27E illustrates an example in which information on the periphery, surface, or inside of the human eye (e.g., the number of blinks, movement of an eyeball, and movement of an eyelid) is detected.

This embodiment can be combined with any of the other embodiments or an example as appropriate.

### Embodiment 6

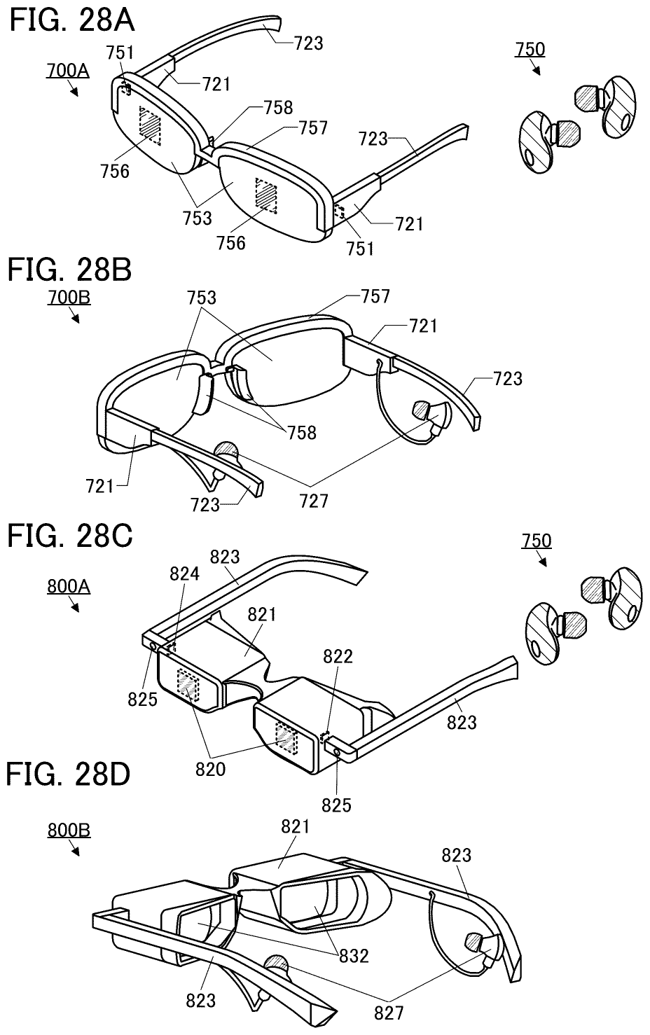

In this embodiment, electronic devices of embodiments of the present invention will be described with reference to FIG. 28A to FIG. 30G.

Electronic devices of this embodiment each include the display apparatus of one embodiment of the present invention in a display portion. The display apparatus of one embodiment of the present invention can be easily increased in resolution and definition. Thus, the display apparatus of one embodiment of the present invention can be used for a display portion of a variety of electronic devices.

Examples of the electronic devices include a digital camera, a digital video camera, a digital photo frame, a mobile phone, a portable game console, a portable information terminal, and an audio reproducing device, in addition to electronic devices with a relatively large screen, such as a television device, a desktop or laptop personal computer, a monitor of a computer or the like, digital signage, and a large game machine such as a pachinko machine.

In particular, the display apparatus of one embodiment of the present invention can have high resolution, and thus can be suitably used for an electronic device including a relatively small display portion. Examples of such an electronic device include watch-type and bracelet-type information terminals (wearable devices) and wearable devices capable of being worn on a head, such as a VR device like a head-mounted display, a glasses-type AR device, and an MR device.

The resolution of the display apparatus of one embodiment of the present invention is preferably as high as HD (number of pixels: 1280×720), FHD (number of pixels: 1920×1080), WQHD (number of pixels: 2560×1440), WQXGA (number of pixels: 2560×1600), 4K (number of pixels: 3840×2160), or 8K (number of pixels: 7680×4320). In particular, the resolution is preferably 4K, 8K, or higher. The pixel density (definition) of the display apparatus of one embodiment of the present invention is preferably higher than or equal to 100 ppi, further preferably higher than or equal to 300 ppi, still further preferably higher than or equal to 500 ppi, yet still further preferably higher than or equal to 1000 ppi, yet still further preferably higher than or equal to 2000 ppi, yet still further preferably higher than or equal to 3000 ppi, yet still further preferably higher than or equal to 5000 ppi, yet still further preferably higher than or equal to 7000 ppi. With the use of such a display apparatus with one or both of high resolution and high definition, an electronic device for portable use or home use can have higher realistic sensation, sense of depth, and the like. There is no particular limitation on the screen ratio (aspect ratio) of the display apparatus of one embodiment of the present invention. For example, the display apparatus is compatible with a variety of screen ratios such as 1:1 (a square), 4:3, 16:9, and 16:10.

The electronic device in this embodiment may include a sensor (a sensor having a function of sensing, detecting, or measuring force, displacement, position, speed, acceleration, angular velocity, rotational frequency, distance, light, liquid, magnetism, temperature, a chemical substance, sound, time, hardness, electric field, current, voltage, electric power, radiation, flow rate, humidity, gradient, oscillation, a smell, or infrared rays).

The electronic device in this embodiment can have a variety of functions. For example, the electronic device can have a function of displaying a variety of information (a still image, a moving image, a text image, and the like) on the display portion, a touch panel function, a function of displaying a calendar, date, time, and the like, a function of executing a variety of software (programs), a wireless communication function, and a function of reading out a program or data stored in a recording medium.

Examples of a wearable device capable of being worn on a head are described with reference to FIG. 28A to FIG. 28D. These wearable devices have at least one of a function of displaying AR contents, a function of displaying VR contents, a function of displaying SR contents, and a function of displaying MR contents. The electronic device having a function of displaying contents of at least one of AR, VR, SR, MR, and the like enables a user to feel a higher sense of immersion.

An electronic device 700A illustrated in FIG. 28A and an electronic device 700B illustrated in FIG. 28B each include a pair of display panels 751, a pair of housings 721, a communication portion (not illustrated), a pair of wearing portions 723, a control portion (not illustrated), an image capturing portion (not illustrated), a pair of optical members 753, a frame 757, and a pair of nose pads 758.

The display apparatus of one embodiment of the present invention can be used for the display panels 751. Thus, the electronic device can perform display with extremely high resolution.

The electronic device 700A and the electronic device 700B can each project images displayed on the display panels 751 onto display regions 756 of the optical members 753. Since the optical members 753 have a light-transmitting property, a user can see images displayed on the display regions, which are superimposed on transmission images seen through the optical members 753. Accordingly, the electronic device 700A and the electronic device 700B are electronic devices capable of AR display.

In each of the electronic device 700A and the electronic device 700B, a camera capable of capturing images of the front side may be provided as the image capturing portion. Furthermore, when the electronic device 700A and the electronic device 700B are each provided with an acceleration sensor such as a gyroscope sensor, the orientation of the user's head can be sensed and an image corresponding to the orientation can be displayed on the display regions 756.

The communication portion includes a wireless communication device, and a video signal and the like can be supplied by the wireless communication device. Note that instead of the wireless communication device or in addition to the wireless communication device, a connector to which a cable for supplying a video signal and a power supply potential can be connected may be provided.

The electronic device 700A and the electronic device 700B are each provided with a battery so that they can be charged wirelessly and/or by wire.

A touch sensor module may be provided in the housing 721. The touch sensor module has a function of detecting touch on the outer surface of the housing 721. A tap operation or a slide operation, for example, by the user can be detected with the touch sensor module, whereby a variety of processing can be executed. For example, processing such as a pause or a restart of a moving image can be executed by a tap operation, and processing such as fast forward and fast rewind can be executed by a slide operation. The touch sensor module is provided in each of the two housings 721, whereby the range of the operation can be increased.

A variety of touch sensors can be used for the touch sensor module. For example, any of touch sensors of various types such as a capacitive type, a resistive type, an infrared type, an electromagnetic induction type, a surface acoustic wave type, and an optical type can be employed. In particular, a capacitive sensor or an optical sensor is preferably used for the touch sensor module.

In the case of using an optical touch sensor, a photoelectric conversion device (also referred to as a photoelectric conversion element) can be used as a light-receiving device. One or both of an inorganic semiconductor and an organic semiconductor can be used for an active layer of the photoelectric conversion device.

An electronic device 800A illustrated in FIG. 28C and an electronic device 800B illustrated in FIG. 28D each include a pair of display portions 820, a housing 821, a communication portion 822, a pair of wearing portions 823, a control portion 824, a pair of image capturing portions 825, and a pair of lenses 832.

The display apparatus of one embodiment of the present invention can be used for the display portions 820. Thus, the electronic device can perform display with extremely high definition. This enables a user to feel high sense of immersion.

The display portions 820 are positioned inside the housing 821 so as to be seen through the lenses 832. When the pair of display portions 820 display different images, three-dimensional display using parallax can be performed.

The electronic device 800A and the electronic device 800B can be regarded as electronic devices for VR. The user who wears the electronic device 800A or the electronic device 800B can see images displayed on the display portions 820 through the lenses 832.

The electronic device 800A and the electronic device 800B each preferably include a mechanism for adjusting the lateral positions of the lenses 832 and the display portions 820 so that the lenses 832 and the display portions 820 are positioned optimally in accordance with the positions of the user's eyes. Moreover, the electronic device 800A and the electronic device 800B each preferably include a mechanism for adjusting focus by changing the distance between the lenses 832 and the display portions 820.

The electronic device 800A or the electronic device 800B can be mounted on the user's head with the wearing portions 823. FIG. 28C and the like illustrate examples where the wearing portion 823 has a shape like a temple (also referred to as a joint) of glasses; however, one embodiment of the present invention is not limited thereto. The wearing portion 823 can have any shape with which the user can wear the electronic device, for example, a shape of a helmet or a band.

The image capturing portion 825 has a function of obtaining information on the external environment. Data obtained by the image capturing portion 825 can be output to the display portion 820. An image sensor can be used for the image capturing portion 825. Moreover, a plurality of cameras may be provided so as to cover a plurality of fields of view, such as a telescope field of view and a wide field of view.

Although an example of including the image capturing portion 825 is described here, a range sensor (hereinafter, also referred to as a sensing portion) that is capable of measuring a distance from an object may be provided. That is, the image capturing portion 825 is one embodiment of the sensing portion. As the sensing portion, an image sensor or a distance image sensor such as LIDAR (Light Detection And Ranging) can be used, for example. With the use of images obtained by the camera and images obtained by the distance image sensor, more pieces of information can be obtained and a gesture operation with higher accuracy is possible.

The electronic device 800A may include a vibration mechanism to function as bone-conduction earphones. For example, a structure including the vibration mechanism can be employed for any one or more of the display portion 820, the housing 821, and the wearing portion 823. Thus, without additionally requiring an audio device such as headphones, earphones, or a speaker, the user can enjoy video and sound only by wearing the electronic device 800A.

The electronic device 800A and the electronic device 800B may each include an input terminal. To the input terminal, a cable for supplying a video signal from a video output device or the like, electric power for charging a battery provided in the electronic device, and the like can be connected.

The electronic device of one embodiment of the present invention may have a function of performing wireless communication with earphones 750. The earphones 750 include a communication portion (not illustrated) and have a wireless communication function. The earphones 750 can receive information (e.g., audio data) from the electronic device with the wireless communication function. For example, the electronic device 700A illustrated in FIG. 28A has a function of transmitting information to the earphones 750 with the wireless communication function. As another example, the electronic device 800A illustrated in FIG. 28C has a function of transmitting information to the earphones 750 with the wireless communication function.

The electronic device may include an earphone portion. The electronic device 700B illustrated in FIG. 28B includes earphone portions 727. For example, the earphone portion 727 and the control portion can be connected to each other by wire. Part of a wiring that connects the earphone portion 727 and the control portion may be positioned inside the housing 721 or the wearing portion 723.

Similarly, the electronic device 800B illustrated in FIG. 28D includes earphone portions 827. For example, the earphone portion 827 and the control portion 824 can be connected to each other by wire. Part of a wiring that connects the earphone portion 827 and the control portion 824 may be positioned inside the housing 821 or the wearing portion 823. Alternatively, the earphone portions 827 and the wearing portions 823 may include magnets. This is preferable because the earphone portions 827 can be fixed to the wearing portions 823 with magnetic force and thus can be easily housed.

The electronic device may include an audio output terminal to which earphones, headphones, or the like can be connected. The electronic device may include one or both of an audio input terminal and an audio input mechanism. As the audio input mechanism, a sound collecting device such as a microphone can be used, for example. The electronic device may have a function of what is called a headset by including the audio input mechanism.

As described above, the electronic device of one embodiment of the present invention can be suitably applied to both the glasses-type device (e.g., the electronic device 700A and the electronic device 700B) and the goggles-type device (e.g., the electronic device 800A and the electronic device 800B).

The electronic device of one embodiment of the present invention can transmit information to earphones by wire or wirelessly.

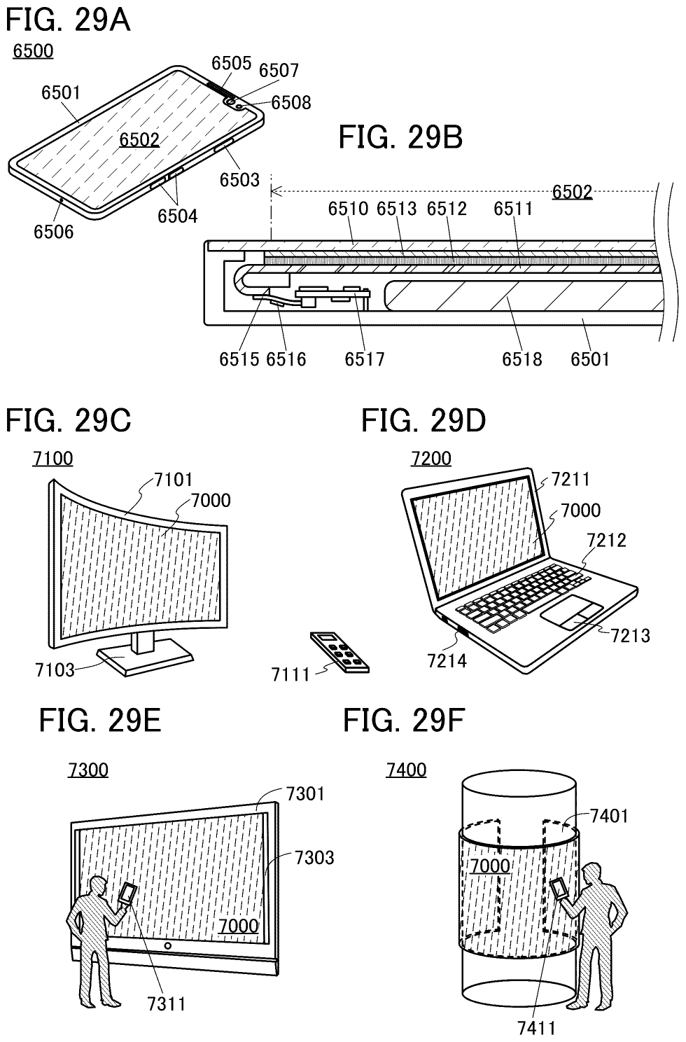

An electronic device 6500 illustrated in FIG. 29A is a portable information terminal that can be used as a smartphone.

The electronic device 6500 includes a housing 6501, a display portion 6502, a power button 6503, buttons 6504, a speaker 6505, a microphone 6506, a camera 6507, a light source 6508, and the like. The display portion 6502 has a touch panel function.

The display apparatus of one embodiment of the present invention can be used for the display portion 6502.

FIG. 29B is a schematic cross-sectional view including an end portion of the housing 6501 on the microphone 6506 side.

A protection member 6510 having a light-transmitting property is provided on a display surface side of the housing 6501, and a display panel 6511, an optical member 6512, a touch sensor panel 6513, a printed circuit board 6517, a battery 6518, and the like are placed in a space surrounded by the housing 6501 and the protection member 6510.

The display panel 6511, the optical member 6512, and the touch sensor panel 6513 are fixed to the protection member 6510 with an adhesive layer (not illustrated).

Part of the display panel 6511 is folded back in a region outside the display portion 6502, and an FPC 6515 is connected to the part that is folded back. An IC 6516 is mounted on the FPC 6515. The FPC 6515 is connected to a terminal provided on the printed circuit board 6517.

A flexible display apparatus of one embodiment of the present invention can be used for the display panel 6511. Thus, an extremely lightweight electronic device can be obtained. Since the display panel 6511 is extremely thin, the battery 6518 with high capacity can be mounted while the thickness of the electronic device is reduced. Moreover, part of the display panel 6511 is folded back so that a connection portion with the FPC 6515 is provided on the back side of the display portion 6502, whereby an electronic device with a narrow bezel can be obtained.

FIG. 29C illustrates an example of a television device. In a television device 7100, a display portion 7000 is incorporated in a housing 7101. Here, a structure in which the housing 7101 is supported by a stand 7103 is illustrated.

The display apparatus of one embodiment of the present invention can be used for the display portion 7000.

Operation of the television device 7100 illustrated in FIG. 29C can be performed with an operation switch provided in the housing 7101 and a separate remote control 7111. Alternatively, the display portion 7000 may include a touch sensor, and the television device 7100 may be operated by touch on the display portion 7000 with a finger or the like. The remote control 7111 may include a display portion for displaying information output from the remote control 7111. With operation keys or a touch panel provided in the remote control 7111, channels and volume can be controlled and videos displayed on the display portion 7000 can be controlled.

Note that the television device 7100 has a structure in which a receiver, a modem, and the like are provided. A general television broadcast can be received with the receiver. When the television device is connected to a communication network by wire or wirelessly via the modem, one-way (from a transmitter to a receiver) or two-way (between a transmitter and a receiver or between receivers, for example) information communication can be performed.

FIG. 29D illustrates an example of a laptop personal computer. A laptop personal computer 7200 includes a housing 7211, a keyboard 7212, a pointing device 7213, an external connection port 7214, and the like. In the housing 7211, the display portion 7000 is incorporated.

The display apparatus of one embodiment of the present invention can be used for the display portion 7000.

FIG. 29E and FIG. 29F illustrate examples of digital signage.

Digital signage 7300 illustrated in FIG. 29E includes a housing 7301, the display portion 7000, a speaker 7303, and the like. The digital signage 7300 can also include an LED lamp, an operation key (including a power switch or an operation switch), a connection terminal, a variety of sensors, a microphone, and the like.

FIG. 29F is digital signage 7400 attached to a cylindrical pillar 7401. The digital signage 7400 includes the display portion 7000 provided along a curved surface of the pillar 7401.

The display apparatus of one embodiment of the present invention can be used for the display portion 7000 in each of FIG. 29E and FIG. 29F.

A larger area of the display portion 7000 can increase the amount of information that can be provided at a time. The larger the display portion 7000 attracts more attention, so that the effectiveness of the advertisement can be increased, for example.

A touch panel is preferably used in the display portion 7000, in which case intuitive operation by a user is possible in addition to display of an image or a moving image on the display portion 7000. Moreover, for an application for providing information such as route information or traffic information, usability can be enhanced by intuitive operation.

As illustrated in FIG. 29E and FIG. 29F, it is preferable that the digital signage 7300 or the digital signage 7400 can work with an information terminal 7311 or an information terminal 7411 such as a smartphone a user has through wireless communication. For example, information of an advertisement displayed on the display portion 7000 can be displayed on a screen of the information terminal 7311 or the information terminal 7411. By operating the information terminal 7311 or the information terminal 7411, display on the display portion 7000 can be switched.

It is possible to make the digital signage 7300 or the digital signage 7400 execute a game with use of the screen of the information terminal 7311 or the information terminal 7411 as an operation means (controller). Thus, an unspecified number of users can join in and enjoy the game concurrently.

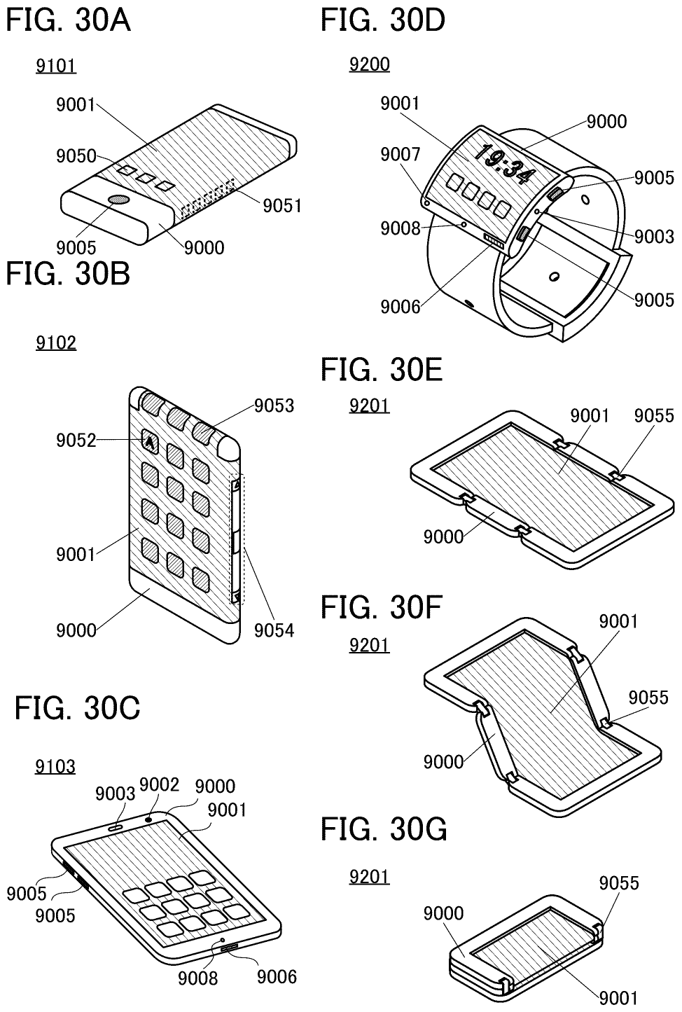

Electronic devices illustrated in FIG. 30A to FIG. 30G each include a housing 9000, a display portion 9001, a speaker 9003, an operation key 9005 (including a power switch or an operation switch), a connection terminal 9006, a sensor 9007 (a sensor having a function of sensing, detecting, or measuring force, displacement, position, speed, acceleration, angular velocity, rotational frequency, distance, light, liquid, magnetism, temperature, a chemical substance, sound, time, hardness, electric field, current, voltage, electric power, radiation, flow rate, humidity, gradient, oscillation, a smell, or infrared rays), a microphone 9008, and the like.

The display apparatus of one embodiment of the present invention can be used for the display portion 9001 in each of FIG. 30A and FIG. 30G.

The electronic devices illustrated in FIG. 30A to FIG. 30G have a variety of functions. For example, the electronic devices can have a function of displaying a variety of information (a still image, a moving image, a text image, and the like) on the display portion, a touch panel function, a function of displaying a calendar, date, time, and the like, a function of controlling processing with the use of a variety of software (programs), a wireless communication function, and a function of reading out and processing a program or data stored in a recording medium. Note that the functions of the electronic devices are not limited thereto, and the electronic devices can have a variety of functions. The electronic devices may each include a plurality of display portions. The electronic devices may each be provided with a camera or the like and have a function of taking a still image or a moving image and storing the taken image in a storage medium (an external storage medium or a storage medium incorporated in the camera), a function of displaying the taken image on the display portion, or the like.

The electronic devices illustrated in FIG. 30A to FIG. 30G are described in detail below.

FIG. 30A is a perspective view illustrating a portable information terminal 9101. For example, the portable information terminal 9101 can be used as a smartphone. Note that the portable information terminal 9101 may be provided with the speaker 9003, the connection terminal 9006, the sensor 9007, or the like. The portable information terminal 9101 can display characters and image information on its plurality of surfaces. FIG. 30A illustrates an example in which three icons 9050 are displayed. Furthermore, information 9051 indicated by dashed rectangles can be displayed on another surface of the display portion 9001. Examples of the information 9051 include notification of reception of an e-mail, an SNS message, or an incoming call, the title and sender of an e-mail, an SNS message, or the like, the date, the time, remaining battery, and the radio field intensity. Alternatively, the icon 9050 or the like may be displayed at the position where the information 9051 is displayed.

FIG. 30B is a perspective view illustrating a portable information terminal 9102. The portable information terminal 9102 has a function of displaying information on three or more surfaces of the display portion 9001. Here, an example in which information 9052, information 9053, and information 9054 are displayed on different surfaces is illustrated. For example, a user can check the information 9053 displayed such that it can be seen from above the portable information terminal 9102, with the portable information terminal 9102 put in a breast pocket of their clothes. The user can see the display without taking out the portable information terminal 9102 from the pocket and decide whether to answer the call, for example.

FIG. 30C is a perspective view illustrating a tablet terminal 9103. The tablet terminal 9103 is capable of executing a variety of applications such as mobile phone calls, e-mailing, viewing and editing texts, music reproduction, Internet communication, and a computer game. The tablet terminal 9103 includes the display portion 9001, a camera 9002, the microphone 9008, and the speaker 9003 on the front surface of the housing 9000; the operation keys 9005 as buttons for operation on the left side surface of the housing 9000; and the connection terminal 9006 on the bottom surface of the housing 9000.

FIG. 30D is a perspective view illustrating a watch-type portable information terminal 9200. For example, the portable information terminal 9200 can be used as a Smartwatch (registered trademark). The display surface of the display portion 9001 is curved, and an image can be displayed on the curved display surface. Furthermore, intercommunication between the portable information terminal 9200 and, for example, a headset capable of wireless communication enables hands-free calling. With the connection terminal 9006, the portable information terminal 9200 can perform mutual data transmission with another information terminal and charging. Note that the charging operation may be performed by wireless power feeding.

FIG. 30E to FIG. 30G are perspective views illustrating a foldable portable information terminal 9201. FIG. 30E is a perspective view of an opened state of the portable information terminal 9201, FIG. 30G is a perspective view of a folded state thereof, and FIG. 30F is a perspective view of a state in the middle of change from one of FIG. 30E and FIG. 30G to the other. The portable information terminal 9201 is highly portable in the folded state and is highly browsable in the opened state because of a seamless large display region. The display portion 9001 of the portable information terminal 9201 is supported by three housings 9000 joined together by hinges 9055. The display portion 9001 can be folded with a radius of curvature greater than or equal to 0.1 mm and less than or equal to 150 mm, for example.

This embodiment can be combined with any of the other embodiments or an example as appropriate.

### Example

In this example, a semiconductor device was fabricated, and the electrical characteristics of transistors included in the semiconductor device were evaluated.

In this example, Sample A, which is the semiconductor device of one embodiment of the present invention, was fabricated. The description of the semiconductor device 10 in FIG. 1A and FIG. 1B can be referred to for the structure of Sample A. Furthermore, the description of the method for fabricating the semiconductor device 10 in <Fabrication method example> in Embodiment 1 can be referred to for the method for fabricating Sample A.

### Fabrication of Sample

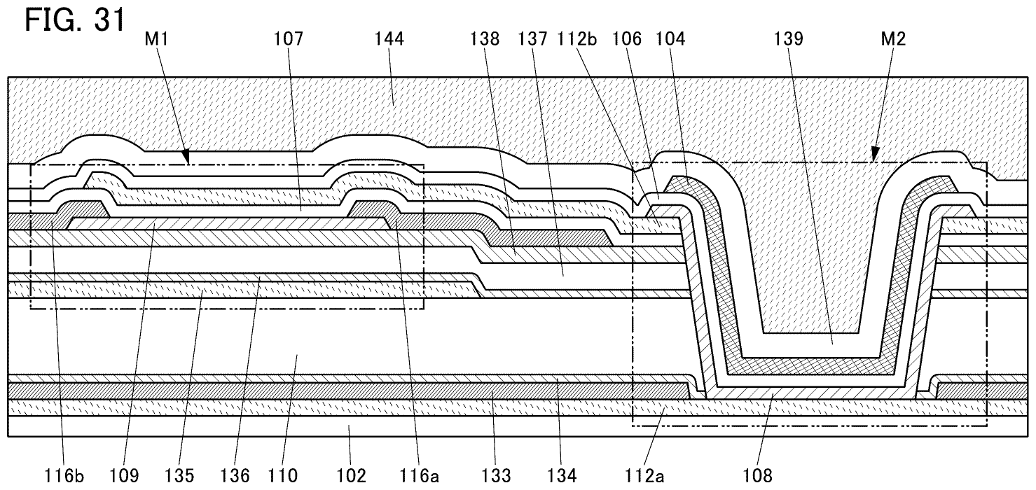

FIG. 31 is a cross-sectional view of Sample A fabricated in this example. Description of the components illustrated in FIG. 31, which are similar to those in the above embodiments, will be omitted.

Sample A fabricated in this example includes a conductive layer 133 over the conductive layer 112a. An opening is provided in the conductive layer 133, and the transistor M2 is provided in a region overlapping with the opening. An insulating layer 134 is provided in contact with a top surface and a side surface of the conductive layer 133 and part of the top surface of the conductive layer 112a.

The conductive layer 133 is formed of a material whose electric resistance is lower than that of the conductive layer 112a. The conductive layer 112a in contact with the conductive layer 133 functions as the one of the source electrode and the drain electrode of the transistor M2 and also as a wiring.

Over the insulating layer 110, an island-shaped conductive layer 135 is provided to include a region overlapping with the conductive layer 112b which functions as the gate electrode of the transistor M1 and a region overlapping with the semiconductor layer 109 which functions as the semiconductor device where the channel of the transistor M1 is formed. An insulating layer 136 is provided to cover a top surface and a side surface of the conductive layer 135 and the top surface of the insulating layer 110. An insulating layer 137 is provided over the insulating layer 136, and an insulating layer 138 is provided over the insulating layer 137.

In the transistor M1 included in Sample A, the conductive layer 135 has a function of a second gate electrode (also referred to as a back gate electrode or a bottom gate electrode), and the insulating layer 136, the insulating layer 137, and the insulating layer 138 have a function of a second gate insulating layer.

An insulating layer 139 is provided over the transistor M1 and the transistor M2 included in Sample A to cover the transistors, and a planarization layer 144 is provided over the insulating layer 139. The insulating layer 139 is provided along top surfaces of the transistor M1 and the transistor M2, and the planarization layer 144 is provided to cover the unevenness of the insulating layer 139 so that the top surface becomes substantially flat.

Fabrication conditions of Sample A are specifically described below.

First, a 50-nm-thick In—Sn—Si oxide (ITSO) film was formed over the substrate 102 by a sputtering method, and then processed to obtain the conductive layer 112a. As the substrate 102, a glass substrate was used.

Then, a 150-nm-thick tungsten film was formed over the conductive layer 112a by a sputtering method, and then processed to obtain the conductive layer 133.

Then, a 30-nm-thick silicon nitride film was formed over the conductive layer 112a and the conductive layer 133 by a PECVD method to obtain the insulating layer 134.

Then, a 800-nm-thick silicon oxynitride film was formed over the insulating layer 134 by a PECVD method to obtain the insulating layer 110.

Next, treatment for supplying oxygen to the insulating layer 110 was performed.

For oxygen supply to the insulating layer 110, first, a 5-nm-thick metal oxide film was formed over the insulating layer 110 by a sputtering method using a sputtering target with metal elements in an atomic ratio of In:Ga:Zn=4:2:4.1 in a 100% oxygen atmosphere.

Next, oxygen plasma treatment was performed on the insulating layer 110 through the metal oxide film. An ashing apparatus was used for this treatment. Note that the oxygen ion flow rate set in the treatment was 300 sccm, and the treatment was performed for 120 seconds with the lower electrode of the ashing apparatus heated to 100° C.

Then, the metal oxide film was removed.

Through the above series of steps, the treatment for supplying oxygen to the insulating layer 110 was performed.

Next, a 100-nm-thick In—Sn—Si oxide (ITSO) film was formed over the insulating layer 110 by a sputtering method, and then processed to obtain the conductive layer 135.

Then, a 30-nm-thick silicon nitride film was formed over the conductive layer 135 and the insulating layer 110 by a PECVD method to obtain the insulating layer 136.

Then, a 200-nm-thick silicon oxynitride film was formed over the insulating layer 136 by a PECVD method to obtain the insulating layer 137.

Next, treatment for supplying oxygen to the insulating layer 137 was performed. Note that this treatment employed the above method used to supply oxygen to the insulating layer 110.

Next, a stack of a 100-nm-thick silicon nitride film and a 5-nm-thick silicon oxynitride film were formed over the insulating layer 137 by a PECVD method to obtain the insulating layer 138.

Next, a 40-nm-thick metal oxide film was formed over the insulating layer 138. The metal oxide film was formed to be stacked by a sputtering method using a sputtering target with an atomic ratio of metal elements of In:Ga:Zn=1:1:1. Note that in the formation, the substrate temperature was room temperature and the oxygen flow rate ratio was 10%.

Then, heat treatment was performed at 350° C. in clean dry air for one hour. An oven apparatus was used for the heat treatment.

Then, the metal oxide film was processed to obtain the semiconductor layer 109.

Next, a 50-nm-thick tungsten film was formed over the semiconductor layer 109 and the insulating layer 138 by a sputtering method and processed to obtain the conductive layer 116a and the conductive layer 116b.

Then, a 50-nm-thick silicon oxynitride film was formed over the semiconductor layer 109, the conductive layer 116a, the conductive layer 116b, and the insulating layer 138 by a PECVD method to obtain the insulating layer 107.

Then, heat treatment was performed at 300° C. in clean dry air for one hour. An oven apparatus was used for the heat treatment.

Then, a 100-nm-thick In—Sn—Si oxide (ITSO) film was formed over the insulating layer 107 by a sputtering method to obtain the film to be the conductive layer 112b later.

Then, the In—Sn—Si oxide (ITSO) film to be the conductive layer 112b later and the insulating layer 107, the insulating layer 138, the insulating layer 137, the insulating layer 136, the insulating layer 110, and the insulating layer 134 were processed, whereby an opening was formed in a region where the transistor M2 was to be formed later. The opening was formed by a dry etching method. In the plan view, the opening is circular.

Then, the In—Sn—Si oxide (ITSO) film to be the conductive layer 112b later was processed to obtain the conductive layer 112b.

In this manner, the transistor M1 was formed.

Then, a 20-nm-thick metal oxide film was formed to cover the top surface of the transistor M1 and the inner wall of the above-described opening (part of the top surface of the conductive layer 112a, a side surface of the insulating layer 134, the side surface of the insulating layer 110, a side surface of the insulating layer 136, a side surface of the insulating layer 137, a side surface of the insulating layer 138, the side surface of the insulating layer 107, and the side surface of the conductive layer 112b). The metal oxide film was formed by a sputtering method using a sputtering target with metal elements in an atomic ratio of In:Ga:Zn=4:2:3. Note that in the formation, the substrate temperature was 130° C. and the oxygen flow rate ratio was 10%.

Then, heat treatment was performed at 350° C. in clean dry air for one hour. An oven apparatus was used for the heat treatment.

Then, the metal oxide film was processed to obtain the semiconductor layer 108.

Then, a 100-nm-thick silicon oxynitride film was formed over the semiconductor layer 108, the conductive layer 112b, and the insulating layer 107 by a PECVD method to obtain the insulating layer 106.

Then, over the insulating layer 106, a 50-nm-thick titanium film, a 200-nm-thick aluminum film, and a 50-nm-thick titanium film were formed and stacked by a sputtering method, and then processed to obtain the conductive layer 104.

In this manner, the transistor M2 was formed.

Then, a 300-nm-thick silicon nitride oxide film was formed over the conductive layer 104 and the insulating layer 106 by a PECVD method to obtain the insulating layer 139.

Then, heat treatment was performed at 300° C. in clean dry air for one hour. An oven apparatus was used for the heat treatment.

Then, a 1.0 μm-thick acrylic resin film was formed over the insulating layer 139 to obtain the planarization layer 144.

Then, heat treatment was performed at 250° C. in a nitrogen atmosphere for one hour. An oven apparatus was used for the heat treatment.

Then, a 100-nm-thick molybdenum film was formed over the planarization layer 144 by a sputtering method and processed to obtain a measurement PAD (not illustrated) for measurement of electrical characteristics of the transistor M1 and the transistor M2 described later.

Then, heat treatment was performed at 200° C. in a nitrogen atmosphere for one hour. An oven apparatus was used for the heat treatment.

Through the above process, Sample A was obtained.

### Cross-Sectional Observation

Next, the sample was thinned by focused ion beam (FIB) and cross sections were observed with a scanning transmission electron microscope by scanning transmission electron microscopy (STEM).

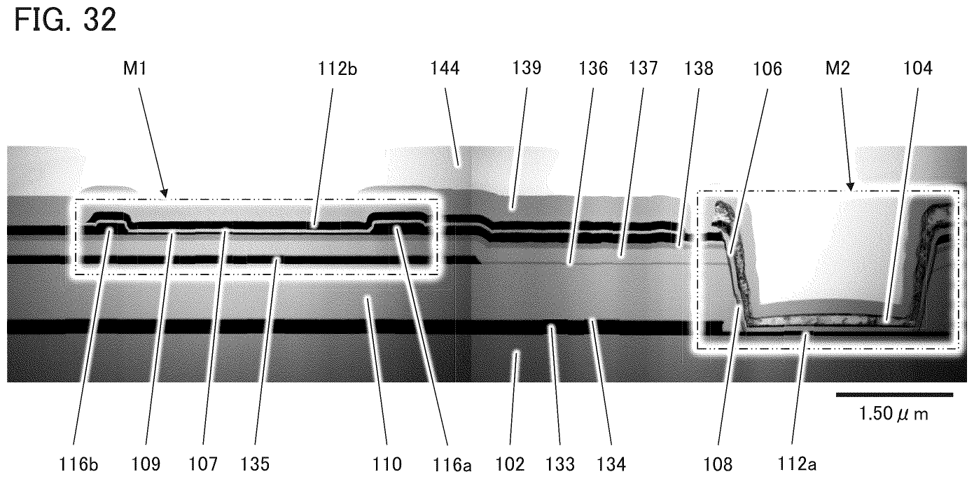

A STEM image of a cross section of Sample A is shown in FIG. 32. FIG. 32 is an image of transmitted electrons (TE) at a magnification of 20000 times.

As shown in FIG. 32, it can be seen that Sample A has a shape corresponding to the shape in the cross-sectional view in FIG. 31 as planned.

### Id-Vg Characteristics

Next, Id-Vg characteristics of the transistor M1 and the transistor M2 in Sample A fabricated above were measured.

For measuring the Id-Vg characteristics of the transistors, voltage applied to the gate electrode (hereinafter also referred to as gate voltage (Vg)) was applied from −10 V to +10 V in increments of 0.25 V. A voltage applied to the source electrode (hereinafter also referred to as source voltage (Vs)) was 0 V (common), and a voltage applied to the drain electrode (hereinafter also referred to as drain voltage (Vd)) was 0.1 V and 5.1 V.

The transistor M1 with a channel length of 3.0 μm and a channel width of 3.0 μm was used for the measurement. The transistor M2, in which the width (diameter) of the opening 141 in FIG. 1A is 2.0 μm (with a channel width of 6.3 μm and a channel length of 1.17 μm), was used for the measurement. The numbers of transistors M1 and transistors M2 subjected to the measurement were each 6.

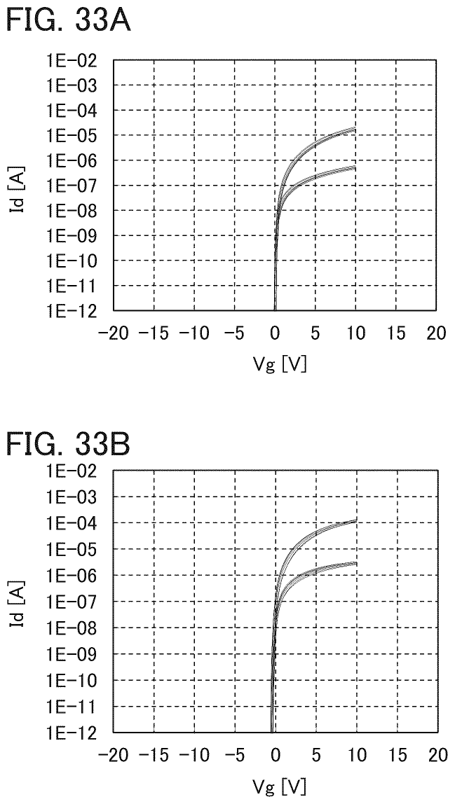

FIG. 33A shows Id-Vg characteristics of the transistor M1, and FIG. 33B show Id-Vg characteristics of the transistor M2. In FIG. 33A and FIG. 33B, the horizontal axis represents the gate voltage (Vg) and the vertical axis represents the drain current (Id). FIG. 33A and FIG. 33B each show superimposed Id-Vg characteristics of the 6 transistors.

FIG. 33A and FIG. 33B reveal that the transistor M1 and the transistor M2 each have switching characteristics with a high on/off ratio. It is also confirmed that the on-state current of the transistor M2 is higher than that of the transistor M1.

At least part of the structure, the method, and the like described in this example can be implemented in appropriate combination with any of the embodiments described in this specification.

### REFERENCE NUMERALS

10A: semiconductor device, 10B: semiconductor device, 10C: semiconductor device, 10D: semiconductor device, 10E: semiconductor device, 10F: semiconductor device, 10G: semiconductor device, 10H: semiconductor device, 10I: semiconductor device, 10J: semiconductor device, 10K: semiconductor device, 10: semiconductor device, 11a: subpixel, 11b: subpixel, 11c: subpixel, 11d: subpixel, 11e: subpixel, 51A: pixel circuit, 51B: pixel circuit, 51C: pixel circuit, 51D: pixel circuit, 51: pixel circuit, 52A: transistor, 52B: transistor, 52C: transistor, 52D: transistor, 53A: capacitor, 53: capacitor, 61: light-emitting device, 102: substrate, 103: conductive layer, 104f: conductive film, 104: conductive layer, 106: insulating layer, 107: insulating layer, 108f: metal oxide film, 108: semiconductor layer, 109f: metal oxide film, 109: semiconductor layer, 110a: insulating layer, 110b: insulating layer, 110c: insulating layer, 110: insulating layer, 111B: pixel electrode, 111G: pixel electrode, 111R: pixel electrode, 111S: pixel electrode, 111: pixel electrode, 112a: conductive layer, 112b: conductive layer, 112c: conductive layer, 112d: conductive layer, 112e: conductive layer, 112f: conductive film, 113B: layer, 113G: layer, 113R: layer, 113S: layer, 113W: layer, 113: layer, 114: common layer, 115: common electrode, 116a: conductive layer, 116b: conductive layer, 116f: conductive film, 117: light-blocking layer, 118B: mask layer, 118G: mask layer, 118R: mask layer, 118S: mask layer, 118: mask layer, 119B: mask layer, 119G: mask layer, 119R: mask layer, 119S: mask layer, 119: mask layer, 123: conductive layer, 124B: conductive layer, 124G: conductive layer, 124R: conductive layer, 124S: conductive layer, 125: insulating layer, 126B: conductive layer, 126G: conductive layer, 126R: conductive layer, 126S: conductive layer, 127: insulating layer, 128: layer, 129B: conductive layer, 129G: conductive layer, 129R: conductive layer, 129S: conductive layer, 130B: light-emitting device, 130G: light-emitting device, 130R: light-emitting device, 130: light-emitting device, 131: protective layer, 132B: coloring layer, 132G: coloring layer, 132R: coloring layer, 133: conductive layer, 134: insulating layer, 135: conductive layer, 136: insulating layer, 137: insulating layer, 138: insulating layer, 139: insulating layer, 140: connection portion, 141: opening, 142: adhesive layer, 144: planarization layer, 150: light-receiving device, 151: substrate, 152: substrate, 153: insulating layer, 160: oxygen, 162: display portion, 164: circuit, 165: wiring, 166: conductive layer, 172: FPC, 173: IC, 200A: display apparatus, 200B: display apparatus, 200C: display apparatus, 200D: display apparatus, 200E: display apparatus, 200F: display apparatus, 200: display apparatus, 201: transistor, 204: connection portion, 205B: transistor, 205G: transistor, 205R: transistor, 205S: transistor, 205: transistor, 206B: transistor, 206G: transistor, 206R: transistor, 206S: transistor, 206: transistor, 210a: pixel, 210b: pixel, 210: pixel, 218: insulating layer, 230: pixel, 235: insulating layer, 237: insulating layer, 239: insulating layer, 242: connection layer, 351: substrate, 352: finger, 353: layer, 355: functional layer, 357: layer, 359: substrate, 700A: electronic device, 700B: electronic device, 721: housing, 723: wearing portion, 727: earphone portion, 750: earphone, 751: display panel, 753: optical member, 756: display region, 757: frame, 758: nose pad, 761: lower electrode, 762: upper electrode, 763a: light-emitting unit, 763b: light-emitting unit, 763c: light-emitting unit, 763: EL layer, 764: layer, 765: layer, 766: layer, 767: active layer, 768: layer, 771a: light-emitting layer, 771b: light-emitting layer, 771c: light-emitting layer, 771: light-emitting layer, 772a: light-emitting layer, 772b: light-emitting layer, 772c: light-emitting layer, 772: light-emitting layer, 773: light-emitting layer, 780a: layer, 780b: layer, 780c: layer, 780: layer, 781: layer, 782: layer, 785: charge-generation layer, 790a: layer, 790b: layer, 790c: layer, 790: layer, 791: layer, 792: layer, 800A: electronic device, 800B: electronic device, 820: display portion, 821: housing, 822: communication portion, 823: wearing portion, 824: control portion, 825: image capturing portion, 827: earphone portion, 832: lens, 6500: electronic device, 6501: housing, 6502: display portion, 6503: power button, 6504: button, 6505: speaker, 6506: microphone, 6507: camera, 6508: light source, 6510: protection member, 6511: display panel, 6512: optical member, 6513: touch sensor panel, 6515: FPC, 6516: IC, 6517: printed circuit board, 6518: battery, 7000: display portion, 7100: television device, 7101: housing, 7103: stand, 7111: remote control, 7200: laptop personal computer, 7211: housing, 7212: keyboard, 7213: pointing device, 7214: external connection port, 7300: digital signage, 7301: housing, 7303: speaker, 7311: information terminal, 7400: digital signage, 7401: pillar, 7411: information terminal, 9000: housing, 9001: display portion, 9002: camera, 9003: speaker, 9005: operation key, 9006: connection terminal, 9007: sensor, 9008: microphone, 9050: icon, 9051: information, 9052: information, 9053: information, 9054: information, 9055: hinge, 9101: portable information terminal, 9102: portable information terminal, 9103: tablet terminal, 9200: portable information terminal, 9201: portable information terminal

1. A semiconductor device comprising a first transistor, a second transistor, and an insulating layer,
wherein the first transistor comprises a first conductive layer, a second conductive layer, a first semiconductor layer, a first gate insulating layer, and a first gate electrode,
wherein the second transistor comprises a third conductive layer, a fourth conductive layer, a second semiconductor layer, a second gate insulating layer, and the second conductive layer,
wherein the insulating layer, the second gate insulating layer, and the second conductive layer comprise an opening reaching the first conductive layer,
wherein the insulating layer is in contact with a top surface of the first conductive layer and a bottom surface of the second semiconductor layer,
wherein the first conductive layer is configured to be one of a source electrode and a drain electrode of the first transistor,
wherein the second conductive layer is configured to be the other of the source electrode and the drain electrode of the first transistor,
wherein the second conductive layer is configured to be a second gate electrode of the second transistor,
wherein the third conductive layer is configured to be one of a source electrode and a drain electrode of the second transistor,
wherein the fourth conductive layer is configured to be the other of the source electrode and the drain electrode of the second transistor,
wherein the first semiconductor layer is provided to cover an inner wall of the opening,
wherein the first semiconductor layer is in contact with a top surface of the second conductive layer,
wherein the first gate electrode overlaps with the first semiconductor layer with the first gate insulating layer therebetween,
wherein the second conductive layer is provided over the second semiconductor layer with the second gate insulating layer therebetween,
wherein the third conductive layer is in contact with a side surface and a top surface of a first side end portion of the second semiconductor layer, and
wherein the fourth conductive layer is in contact with a side surface and a top surface of a second side end portion of the second semiconductor layer opposite to the first side end portion.

2. The semiconductor device according to claim 1,
wherein the first semiconductor layer and the second semiconductor layer each comprise an oxide semiconductor.

3. A semiconductor device comprising a first transistor, a second transistor, and an insulating layer,
wherein the first transistor comprises a first conductive layer, a second conductive layer, a first semiconductor layer, a gate insulating layer, and a first gate electrode,
wherein the second transistor comprises the second conductive layer, a third conductive layer, a second semiconductor layer, the gate insulating layer, and a second gate electrode,
wherein the insulating layer and the second conductive layer comprise an opening reaching the first conductive layer,
wherein the insulating layer is in contact with a top surface of the first conductive layer and a bottom surface of the second semiconductor layer,
wherein the first semiconductor layer is provided to cover an inner wall of the opening,
wherein the first semiconductor layer is in contact with a top surface of the second conductive layer,
wherein the first conductive layer is configured to be one of a source electrode and a drain electrode of the first transistor,
wherein the second conductive layer is configured to be the other of the source electrode and the drain electrode of the first transistor,
wherein the second conductive layer is configured to be one of a source electrode and a drain electrode of the second transistor,
wherein the third conductive layer is configured to be the other of the source electrode and the drain electrode of the second transistor,
wherein the first gate electrode overlaps with the first semiconductor layer with the gate insulating layer therebetween,
wherein the second conductive layer is in contact with a side surface and a top surface of a first side end portion of the second semiconductor layer,
wherein the third conductive layer is in contact with a side surface and a top surface of a second side end portion of the second semiconductor layer opposite to the first side end portion, and
wherein the second gate electrode is provided over the second semiconductor layer with the gate insulating layer therebetween.

4. The semiconductor device according to claim 3,
wherein the first semiconductor layer and the second semiconductor layer each comprise an oxide semiconductor.

5. A method for fabricating a semiconductor device comprising:
forming a first conductive film;
forming a first conductive layer by processing the first conductive film;
forming a first insulating layer over the first conductive layer;
forming a first metal oxide film over the first insulating layer;
forming a first semiconductor layer by processing the first metal oxide film;
forming a second conductive film over the first semiconductor layer;
forming a second conductive layer and a third conductive layer each covering a side surface and part of a top surface of the first semiconductor layer by processing the second conductive film;
forming a second insulating layer over the first semiconductor layer, the second conductive layer, the third conductive layer, and the first insulating layer;
forming a third conductive film over the second insulating layer;
forming an opening in the third conductive film, the second insulating layer, and the first insulating layer by processing the third conductive film, the second insulating layer, and the first insulating layer;
forming a fourth conductive layer by processing the third conductive film;
forming a second metal oxide film to cover a top surface of the first conductive layer, an inner wall of the opening, a top surface of the fourth conductive layer, and part of a top surface of the second insulating layer;
forming a second semiconductor layer by processing the second metal oxide film to comprise a region overlapping with the inner wall of the opening;
forming a third insulating layer over the second semiconductor layer, the fourth conductive layer, and the second insulating layer;
forming a fourth conductive film over the third insulating layer; and
forming a fifth conductive layer by processing the fourth conductive film to comprise a region overlapping with the opening.

6. The method for fabricating the semiconductor device according to claim 5,
wherein treatment for supplying oxygen to the first insulating layer is performed after the formation of the first insulating layer.
